(19) United States
(12) Patent Application Publication
(10) Pub. No.: US 2026/0016755 A1
(43) Pub. Date: Jan. 15, 2026

(54) IMAGING EUV OPTICAL UNIT FOR IMAGING AN OBJECT FIELD INTO AN IMAGE FIELD

(71) Applicant: Carl Zeiss SMT GmbH, Oberkochen (DE)

(72) Inventor: Susanne BEDER, Aalen (DE)

(21) Appl. No.: 19/338,068

(22) Filed: Sep. 24, 2025

Related U.S. Application Data
(63) Continuation of application No. PCT/EP2024/058979, filed on Apr. 3, 2024.

(30) Foreign Application Priority Data
Apr. 6, 2023 (DE) 10 2023 203 225.2

(51) Int. Cl. G03F 7/00; G02B 5/08; G21K 1/06

(52) U.S. Cl. CPC G03F 7/70233; G02B 5/0891; G03F 7/70033; G03F 7/702; G03F 7/70316; G21K 1/067

(57) ABSTRACT

An imaging EUV optical unit serves for imaging an object field into an image field. A plurality of mirrors serve for guiding EUV imaging light at a wavelength of shorter than 30 nm along an imaging beam path from the object field towards the image field. An overall transmission of the plurality of mirrors for the EUV imaging light is greater than 5%. The image field of the imaging optical unit has a maximum extent of more than 26 mm in an image plane. This can yield an imaging EUV optical unit with improved usability for an EUV projection exposure apparatus.

### CROSS-REFERENCE TO RELATED APPLICATIONS

The present application is a continuation of, and claims benefit under 35 USC 120 to, international application No. PCT/EP2024/058979, filed Apr. 3, 2024, which claims benefit under 35 USC 119 of German Application No. 10 2023 203 225.2, filed Apr. 6, 2023. The entire disclosure of each of these applications is incorporated by reference herein.

### FIELD

The disclosure relates to an imaging EUV optical unit for imaging an object field into an image field. Further, the disclosure relates to an optical system having such an imaging optical unit, a projection exposure apparatus having such an optical system, a method for producing a micro- or nanostructured component using such a projection exposure apparatus, and a micro- or nanostructured component produced by the method.

### BACKGROUND

Projection optical units of the type set forth at the outset are known from WO 2018/010 960 A1, DE 10 2015 209 827 A1, DE 10 2012 212 753 A1, US 2010/0149509 A1, U.S. Pat. No. 4,964,706, DE 10 2016 218 996 A1 and DE 10 2019 202 759 A1.

### SUMMARY

The present disclosure seeks to develop an imaging EUV optical unit with an improved usability thereof for an EUV projection exposure apparatus.

In an aspect, the disclosure provides an imaging EUV optical unit for imaging an object field into an image field. The imaging EUV optical unit has a plurality of mirrors for guiding EUV imaging light at a wavelength of shorter than 30 nm along an imaging beam path from the object field towards the image field. An overall transmission of the plurality of mirrors for the EUV imaging light is greater than 5%. The image field of the imaging optical unit has a maximum extent of more than 50 mm in an image plane.

According to the disclosure, it was recognized that it is possible to design an imaging EUV optical unit to have both a high transmission and a large maximum image field extent in comparison certain known systems. For example, this makes it possible to simultaneously expose two fields to be exposed located adjacent to one another in the maximum image field extension direction, i.e. two exposure fields, on a substrate arranged in the image field. This can result in a corresponding increase of throughput for a projection exposure apparatus using the imaging EUV optical unit. The maximum extent of the image field in the image plane is given by the maximum image field extent in the image plane, within which the image field meets a specified imaging quality criterion.

In embodiments, an image-side numerical aperture of the imaging EUV optical unit is no more than 0.5. The image-side numerical aperture can be, for example, less than 0.5, such as no more than 0.4, optionally 0.33.

In embodiments, an overall mirror surface, which represents the sum of all used mirror surfaces of the plurality of mirrors, i.e. of all mirrors of the imaging EUV optical unit used for guiding imaging light, is less than 1.5 m², less than 1.25 m², less than 1.0 m², less than 0.8 m², less than 0.76 m², less than 0.75 m², 0.71 m², less than 0.7 m², 0.69 m².

The imaging EUV optical unit may comprise more than four mirrors (more than six mirrors, eight mirrors) for guiding the EUV imaging light.

For a given EUV used light source power, an EUV overall transmission of more than 5% can allow an increased EUV throughput to the image field, and hence can result in an improved exposure power. Alternatively, for a given exposure power on the image field, it is possible to use a reduced power source.

In embodiments, the overall transmission of the imaging EUV optical unit is greater than 10%, greater than 11%, greater than 12%, greater than 13%, greater than 14%, greater than 15%. On account of the number of mirrors and an individual EUV transmission of a mirror that guides the imaging light, which is regularly no more than 80%, the overall transmission is regularly less than 20%.

When specifying the overall transmission, all mirrors of the imaging EUV optical unit in the imaging beam path used for the guidance are considered.

The maximum image field extent can be an integer multiple of an exposure field extent in the maximum image field extension direction.

In embodiments, the imaging EUV optical unit has different imaging scales in two imaging light planes which contain two perpendicular image field extension directions. Such anamorphic embodiments were found to be advantageous, especially for optimizing a guidance of the illumination and imaging light in the region of a reflective object. Examples of anamorphic projection optical units are disclosed by U.S. Pat. No. 9,366,968 B2.

In embodiments, a displacement direction imaging scale in one of the two imaging light planes, which contains an object displacement direction of an object to be imaged, the absolute value of which is at least 1.1-times as large as a cross dimension imaging scale in the other one of the two imaging light planes, is perpendicular to the object displacement direction. Such imaging scale ratios have particularly proven their worth. For example, it is then possible to work with an object of standard width on the object side, despite the large image field. In terms of absolute value, the displacement direction imaging scale can for example be twice as large as the cross dimension imaging scale. In the case of the absolute value comparison, the imaging scale is specified as a reduction factor.

In embodiments, at least one intermediate image in at least one imaging light plan contains an image field extension direction. Such embodiments can allow mirror surfaces of mirrors to be designed to be smaller in the region of the intermediate image.

In embodiments, an image plane of the imaging optical unit in the imaging beam path in an imaging light plane, which contains an image field extension direction, is the first field plane downstream of an object plane of the imaging optical unit. In such embodiments, the imaging EUV optical unit does not have an intermediate image perpendicular to the meridional plane. There is an image flip in the sagittal plane perpendicular to the meridional plane. Thus, there may be a choristikonal-type imaging optical unit within the meaning of U.S. Pat. No. 10,656,400 B2, in which there are different numbers of intermediate images in mutually perpendicular imaging light planes.

In embodiments, the image field has a bent shape. An arcuate field, which may be embodied as a ring field, can enable an EUV optical unit with good imaging correction.

In embodiments, the image field has the shape of a double arch. A double arch image field may be well adapted to a symmetry of an exposure of two exposure fields arranged next to one another along the maximum image field extent. It is possible to provide a design of the double arch field in which the fields extent perpendicular to the maximum field extension direction is reduced in comparison with a simple arch which spans this entire maximum field extent.

In embodiments, the imaging EUV optical unit includes at least four NI mirrors and/or at least four GI mirrors. Providing such a number of mirrors in accordance has proven its worth in practice. It is possible to obtain advantageous combinations of image field correction and transmission.

In embodiments, the imaging EUV optical unit includes at least one pair of immediately consecutive GI mirrors in the beam path. Such immediately consecutive GI mirrors have proven their worth for guiding imaging light. The imaging EUV optical unit may comprise two such GI mirror pairs. There can be an addition or a subtraction of the deflection effects of the respective GI mirrors within a GI mirror pair.

In embodiments, the imaging EUV optical unit has an angle of incidence sequence NI, GI, NI of the first three mirrors in the imaging beam path. Such an angle of incidence sequence has proven its worth in practice.

In embodiments, the imaging EUV optical unit includes no more than three GI mirrors and/or no more than seven mirrors in the imaging beam path. Such embodiments can have a desirable throughput. A desirable input can occur when there are no more than seven mirrors overall.

The imaging optical unit may comprise exactly three GI mirrors. In this case, precisely two of these three GI mirrors may be designed as an immediately consecutive mirror pair. Such a mirror pair with two immediately consecutive GI mirrors can be designed such that the deflection effects of the two GI mirrors add, or else it may be designed such that the deflection effects of the two GI mirrors subtract.

The imaging optical unit may comprise exactly seven mirrors in the imaging beam path between the object field and the image field. In that case, an angle of incidence sequence can be as follows: NI, GI, NI, GI, GI, NI, NI.

In embodiments, an optical system has an illumination optical unit for illuminating the object field with the imaging light, and an imaging optical unit of the disclosure. In embodiments, a projection exposure apparatus includes such an optical system. In embodiments, a method for producing a structured component includes the following method steps: providing a reticle and a wafer; projecting a structure on the reticle onto a light-sensitive layer of the wafer using such a projection exposure apparatus; and
generating a microstructure and/or nanostructure on the wafer. Features of such optical systems, projection exposure apparatus, methods and/or components can correspond to those disclosed above with reference to the projection optical unit according to the disclosure.

The EUV light source of the projection exposure apparatus may be designed so as to result in a used wavelength of no more than 13.5 nm, of less than 13.5 nm, of less than 10 nm, of less than 8 nm, of less than 7 nm, and of 6.7 nm or 6.9 nm, for example. A used wavelength of less than 6.7 nm and, for example, of the order of 6 nm is also possible.

A semiconductor component can be, for example, a memory chip, which can be produced using the projection exposure apparatus.

### BRIEF DESCRIPTION OF THE DRAWINGS

Below, at least one exemplary embodiment of the disclosure is described on the basis of the drawings, in which:

FIG. 1 schematically shows a meridional section of a projection exposure apparatus for EUV projection lithography;

FIG. 2 shows, in a meridional section, an embodiment of an imaging optical unit which is used as a projection lens in the projection exposure apparatus according to FIG. 1, wherein an imaging beam path for chief rays and for an upper coma ray and a lower coma ray of two selected field points is depicted;

FIG. 3 shows a view of the imaging optical unit according to FIG. 2, as seen from the viewing direction III in FIG. 2;

FIG. 4 shows a plan view of a wafer to be exposed via the projection exposure apparatus, wherein individual exposure fields to be scanned, in the form of rectangles on the substrate to be exposed, are emphasised;

FIG. 5 shows an enlarged plan view of detail V in FIG. 4, wherein a scanning path of an image field, rectangular in this case, of the projection lens over the wafer is illustrated by way of example, a solid line depicting the scanning path during projection exposure times of the projection exposure apparatus and a dashed line depicting the scanning path during exposure pause times;

FIG. 6 shows, in an illustration similar to FIG. 5, the scanning path of an arch or ring field of a projection optical unit, an alternative in this respect, over the wafer section according to FIG. 5;

FIG. 7 shows, in an illustration similar to FIG. 5, the same wafer section and a scanning path when using a rectangular image field with, in comparison with FIG. 5, twice the field width perpendicular to the scanning direction;

FIG. 8 shows, in an illustration similar to FIG. 7, a scanning path when using a further alternative projection optical unit, distinguished in that it has an arch or ring field with twice the image field width perpendicular to the scanning direction in comparison with FIG. 6, for example;

FIG. 9 shows, in an illustration similar to FIG. 7, a scanning path when using a double arch image field of a projection optical unit, a further alternative in this respect, once again with twice the image field width in comparison with FIG. 6, wherein the double arch image field can be understood to be a placement of two arch or ring fields according to FIG. 6 next to one another perpendicular to the scanning direction;

FIGS. 10 and 11 show, in an illustration similar to FIGS. 2 and 3, a further embodiment of an imaging optical unit which usable as a projection lens in the projection exposure apparatus according to FIG. 1;

FIGS. 12 and 13 show, in an illustration similar to FIGS. 2 and 3, a further embodiment of an imaging optical unit which usable as a projection lens in the projection exposure apparatus according to FIG. 1;

FIGS. 14 and 15 show, in an illustration similar to FIGS. 2 and 3, a further embodiment of an imaging optical unit which usable as a projection lens in the projection exposure apparatus according to FIG. 1;

FIGS. 16 and 17 show, in an illustration similar to FIGS. 2 and 3, a further embodiment of an imaging optical unit which usable as a projection lens in the projection exposure apparatus according to FIG. 1;

FIGS. 18 and 19 show, in an illustration similar to FIGS. 2 and 3, a further embodiment of an imaging optical unit which usable as a projection lens in the projection exposure apparatus according to FIG. 1;

### DETAILED DESCRIPTION

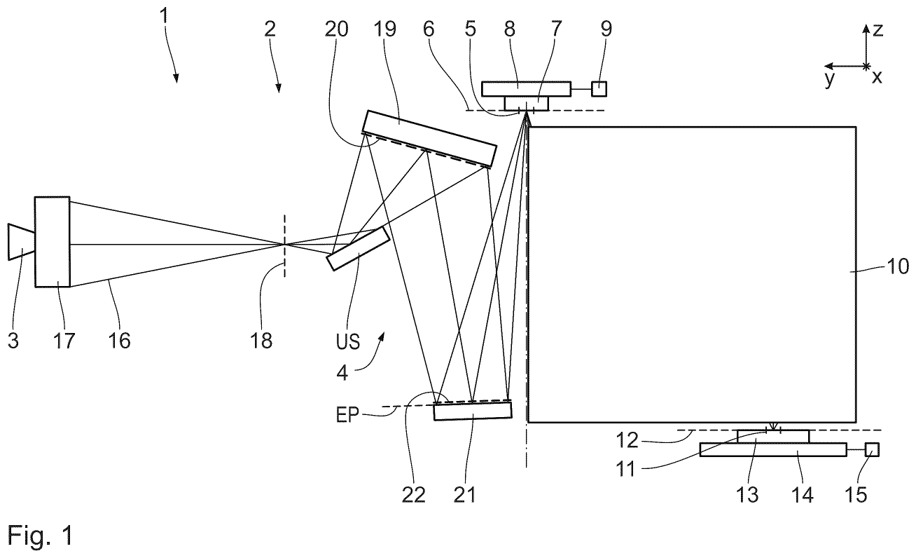

In the following text, certain components of a microlithographic projection exposure apparatus 1 are described first by way of example with reference to FIG. 1. The description of the basic structure of the projection exposure apparatus 1 and its components should not be construed as limiting here.

One embodiment of an illumination system 2 of the projection exposure apparatus 1 has, in addition to a light or radiation source 3, an illumination optical unit 4 for illuminating an object field 5 in an object plane 6. In an alternative embodiment, the light source 3 can also be provided as a module separate from the rest of the illumination system. In this case, the illumination system does not comprise the light source 3.

A reticle 7 arranged in the object field 5 is exposed. The reticle 7 is held by a reticle holder 8. The reticle holder 8 is displaceable by way of a reticle displacement drive 9, in particular in a scanning direction.

The projection exposure apparatus 1 comprises a projection optical unit or imaging optical unit 10. The projection optical unit 10 serves for imaging the object field 5 into an image field 11 in an image plane 12. The image plane 12 extends parallel to the object plane 6. Alternatively, an angle that differs from 0° between the object plane 6 and the image plane 12 is also possible.

A Cartesian xyz-coordinate system is shown in FIG. 1 for explanation purposes. The x-direction runs perpendicular to the plane of the drawing into the latter. The y-direction runs horizontally and the z-direction runs vertically. The scanning direction runs in the y-direction in FIG. 1. The z-direction runs perpendicularly to the image plane 12.

A structure on the reticle 7 is imaged onto a light-sensitive layer of a wafer 13 arranged in the region of the image field 11 in the image plane 12. The wafer 13 is held by a wafer holder 14. The wafer holder 14 is displaceable by way of a wafer displacement drive 15, in particular in the y-direction. The displacement, firstly, of the reticle 7 by way of the reticle displacement drive 9 and, secondly, of the wafer 13 by way of the wafer displacement drive 15 can be implemented so as to be synchronized with one another.

The radiation source 3 is an EUV radiation source. The radiation source 3 emits EUV radiation 16 in particular, which is also referred to below as used radiation or illumination radiation. In particular, the used radiation has a wavelength in the range of between 5 nm and 30 nm. The radiation source 3 can be a plasma source, for example an LPP (laser produced plasma) source or a GDPP (gas discharge produced plasma) source. It may also be a synchrotron-based radiation source. The radiation source 3 may be a free electron laser (FEL).

The illumination radiation 16 emerging from the radiation source 3 is focused by a collector 17. The collector 17 may be a collector with one or more ellipsoidal and/or hyperboloidal reflection surfaces. The illumination radiation 16 can be incident on the at least one reflection surface of the collector 17 with grazing incidence (GI), that is to say at angles of incidence of greater than 45°, or with normal incidence (NI), that is to say at angles of incidence of less than 45°. The collector 17 may be structured and/or coated on the one hand for optimizing its reflectivity for the used radiation and on the other hand for suppressing stray light.

The illumination radiation 16 propagates through an intermediate focus in an intermediate focal plane 18 downstream of the collector 17. The intermediate focal plane 18 can represent a separation between a radiation source module, comprising the radiation source 3 and the collector 17, and the illumination optical unit 4.

The illumination optical unit 4 comprises a first facet mirror 19. If the first facet mirror 19 is arranged in a plane of the illumination optical unit 4 which is optically conjugate to the object plane 6, then this facet mirror is also referred to as a field facet mirror. The first facet mirror 19 comprises a multiplicity of individual first facets 20, which are also referred to below as field facets. Only a few of these facets are illustrated in FIG. 1 in exemplary fashion.

The first facets 20 may be embodied as macroscopic facets, in particular as rectangular facets or as facets with an arcuate edge contour or an edge contour of part of a circle. The first facets 20 may be embodied as plane facets or alternatively as facets with convex or concave curvature.

As known for example from DE 10 2008 009 600 A1, the first facets 20 themselves may also be composed in each case of a multiplicity of individual mirrors, in particular a multiplicity of micromirrors. The first facet mirror 19 may in particular be formed as a microelectromechanical system (MEMS system). For details, reference is made to DE 10 2008 009 600 A1.

A deflection mirror US, which may be embodied as a plane mirror but which may alternatively also have a beam shaping effect, is located in the beam path of the illumination optical unit 4, between the intermediate focus in the intermediate focal plane 18 and the first facet mirror 19. Depending on the arrangement of the light source 3 in particular, it may also be possible to dispense with the deflection mirror US.

In the beam path of the illumination optical unit 4, a second facet mirror 21 is arranged downstream of the first facet mirror 19. If the second facet mirror 21 is arranged in a pupil plane EP of the illumination optical unit 4, it is also referred to as a pupil facet mirror. The second facet mirror 21 may also be arranged at a distance from a pupil plane of the illumination optical unit 4. In this case, the combination of the first facet mirror 19 and the second facet mirror 21 is also referred to as a specular reflector. Specular reflectors are known from US 2006/0132747 A1, EP 1 614 008 B1, and U.S. Pat. No. 6,573,978.

The second facet mirror 21 comprises a plurality of second facets 22. In the case of a pupil facet mirror, the second facets 22 are also referred to as pupil facets.

The second facets 22 may likewise be macroscopic facets, which may for example have a round, rectangular or else hexagonal boundary, or may alternatively be facets composed of micromirrors. In this regard, reference is likewise made to DE 10 2008 009 600 A1.

The second facets 22 may have plane reflection surfaces or alternatively reflection surfaces with convex or concave curvature.

The illumination optical unit 4 consequently forms a doubly faceted system. This fundamental principle is also referred to as a fly's eye condenser (fly's eye integrator).

It may be advantageous to arrange the second facet mirror 21 not exactly in a plane that is optically conjugate to a pupil plane of the projection optical unit 10. In particular, the pupil facet mirror 21 can be arranged so as to be tilted relative to a pupil plane of the projection optical unit 10, as is described, for example, in DE 10 2017 220 586 A1.

The individual first facets 20 are imaged into the object field 5 with the aid of the second facet mirror 21 and optionally with the aid of an imaging optical assembly in the form of a transfer optical unit, which is not depicted in FIG. 1.

The transfer optical unit may have exactly one mirror, or alternatively have two or more mirrors, which are arranged one behind the other in the beam path of the illumination optical unit 4. The transfer optical unit may in particular comprise one or two normal-incidence mirrors (NI mirrors) and/or one or two grazing-incidence mirrors (GI mirrors). The illumination optical unit 4 has exactly three mirrors in the embodiment shown in FIG. 1, that is to say downstream of the collector 17, specifically the deflection mirror US, the first facet mirror 19, and the second facet mirror 21.

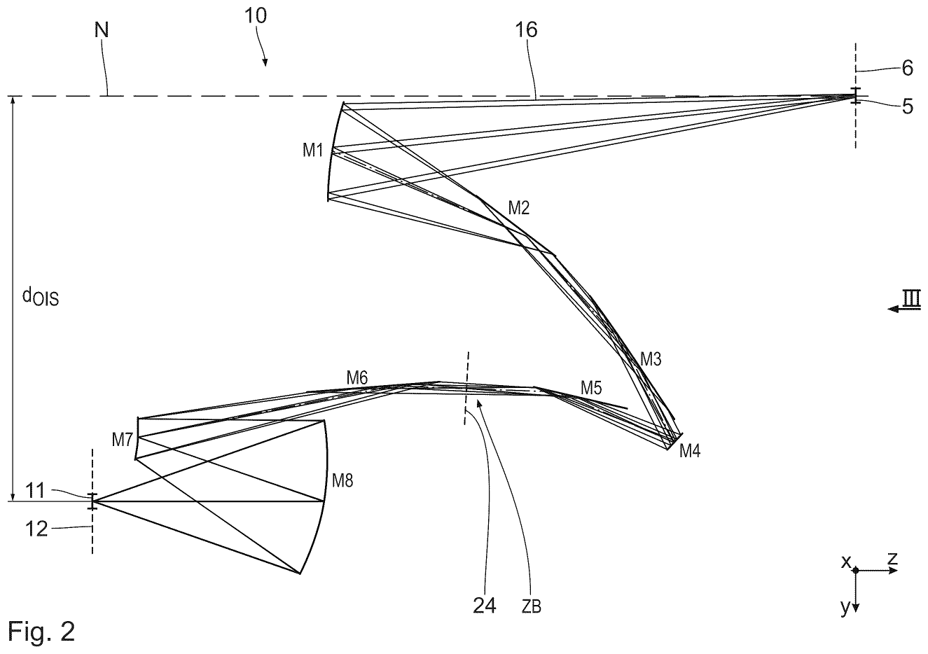

To the extent that the transfer optical unit downstream of the second facet mirror 21 is dispensed with, the second facet mirror 21 is the last beam shaping mirror or else indeed the last mirror for the illumination radiation 16 in the beam path upstream of the object field 5. An example of an illumination optical unit 4 without a transfer optical unit is disclosed in FIG. 2 of WO 2019/096654 A1.

The imaging of the first facets 20 into the object plane 6 via the second facets 22 or using the second facets 22 and a transfer optical unit is often only approximate imaging.

The projection optical unit 10 comprises a plurality of mirrors, namely eight mirrors M1 to M8 (cf. FIG. 2), which are consecutively numbered in accordance with their order in the beam path of the projection exposure apparatus 1.

In the example illustrated in FIG. 2, the projection optical unit 10 comprises eight mirrors M1 to M8. Alternatives with four, five, six or any other number of mirrors Mi are likewise possible.

The projection optical unit 10 is a non-obscured optical unit. None of the mirrors M1 to M8 includes a passage opening for the illumination radiation 16.

The projection optical unit 10 has an image-side numerical aperture of 0.33. Depending on the embodiment of the projection optical unit 10, the image-side numerical aperture may range between 0.25 and 0.4, for example. Depending on the embodiment, the image-side numerical aperture of the projection optical unit 10 may also adopt different values.

Reflection surfaces of the mirrors Mi are embodied as free-form surfaces without an axis of rotational symmetry. Alternatively, the reflection surfaces of the mirrors Mi can be designed as aspherical surfaces with exactly one axis of rotational symmetry of the reflection surface shape. Just like the mirrors of the illumination optical unit 4, the mirrors Mi may have highly reflective coatings for the illumination radiation 16. These coatings can be designed as multilayer coatings, for example with alternating layers of molybdenum and silicon. A ruthenium coating is also possible, in particular for coating mirrors for grazing incidence (GI mirrors).

The projection optical unit 10 leads to a reduction in size with a ratio of 2:1 in the x-direction, that is to say in a direction perpendicular to the scanning direction y. An imaging scale βₓ in the x-direction is −2.00. This imaging scale βₓ is also referred to as cross dimension imaging scale.

In the scanning direction y, the projection optical unit 10 leads to a reduction in size of 4:1, but without an image flip in this case (β_{y}=+4.00). This imaging scale β_{y} is also referred to as displacement direction imaging scale.

The imaging scales described here are the reduction factors of the projection optical unit 10 when imaging the object field 5 into the image field 11.

Thus, the projection optical unit 10 has a displacement direction imaging scale in the scanning direction y in the imaging light plane yz which, in terms of absolute value, is twice as large as a cross dimension imaging scale, present in the cross scanning direction x, in another imaging the light plane xz perpendicular to the scanning direction y, i.e. the object displacement direction. This ratio between the displacement direction imaging scale and the cross dimension imaging scale can be in the range of between 1.1 and 5 and can be 2, for example.

The projection optical unit 10 has an anamorphic design. It has different imaging scales βₓ, β_{y} in the x- and y-directions. The two imaging scales βₓ, β_{y} of the projection optical unit 10 can be (βₓ, β_{y})=(+/−2, /+−4 or +/−8), such as (βₓ, β_{y})=(+/−2, +/−4) or (+/−4, +/−8).

Other imaging scales are likewise possible. Imaging scales with the same sign are also possible in the x- and y-directions.

When an anamorphic projection optical unit is used, it is possible to achieve smaller chief ray angles of the illumination light beam at the reticle 7 while avoiding unwanted shadowing effects.

The projection optical unit 10 can also have an isomorphic configuration, i.e. the same imaging scales βₓ, β_{y} in terms of absolute value in the x- and y-directions.

The image field 11 of the projection optical unit 10 is rectangular and has an x-extent of 52 mm and a y-extent of 1.8 mm. Thus, perpendicular to a scanning direction y of the projection exposure apparatus 1 designed as a scanner, the image field has a field extent which is twice the y-extent of a typical exposure field 23 to be scanned.

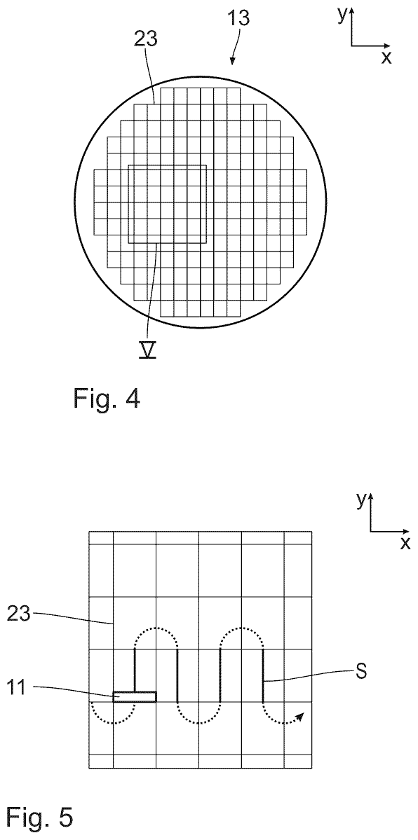

This is explained in detail below on the basis of FIGS. 4 to 7 and in particular on the basis of FIGS. 4 and 7.

FIG. 4 shows a plan view of the wafer 13 with rectangular exposure fields 23 which are arranged thereon in raster fashion and are to be scanned relative to the image field 11. Each of the exposure fields 23 has a typical extent of 26 mm in the x-direction and a typical extent of 32 mm in the y-direction. The wafer 13 has a standard diameter of 300 mm.

FIG. 5 shows an exemplary scanning path S over a section of the wafer 13 when using an image field 11 of a variant of the projection optical unit 10 with a standard image field extent in the x-direction of 26 mm, which corresponds to the x-extent of the exposure field 23. A solid line is used in FIG. 5 to depict those portions of the scanning path S of the image field 11 relative to the wafer 13 in which a projection exposure is carried out by the projection exposure apparatus 1. During these scanning path portions running in a straight line in the y-direction, i.e. the scanning direction, the image field 11 is scanned over the entire respective exposure field 23, with the result that the entire exposure field 23 is exposed.

FIG. 5 shows, by way of example, the scanning path S for exposing exactly one row of exposure field 23 situated next to one another on the wafer 13. As a result of a corresponding lengthening of the exposure portions of the scanning path S, i.e. the portions of the scanning path S drawn in a solid line and running straight along the y-direction, it is also possible to expose a plurality of rows of exposure fields 23, which are adjacent to one another in the y-direction, on the wafer 13.

Dashed lines in FIG. 5 depict connection portions of the scanning path S in each case connecting adjacent exposure portions, i.e. these lines depict portions of the relative movement of the image field 11 with respect to the wafer 13 during which the wafer 13 is not exposed. In the depicted example, the connection portions each have the shape of a 180° arch.

As a rule, the relative movement of the image field 11 with respect to the wafer 13 is generated by way of an actuator-based displacement of the wafer 13 relative to the projection optical unit 10 in the y-direction or in the x-direction.

In the embodiment according to FIG. 5, in which the image field width is the same as the exposure field width (26 mm), exactly one exposure field 23 or one column portion with exposure fields 23 adjacent to one another within a column is exposed in each scanning step of the projection exposure apparatus 1.

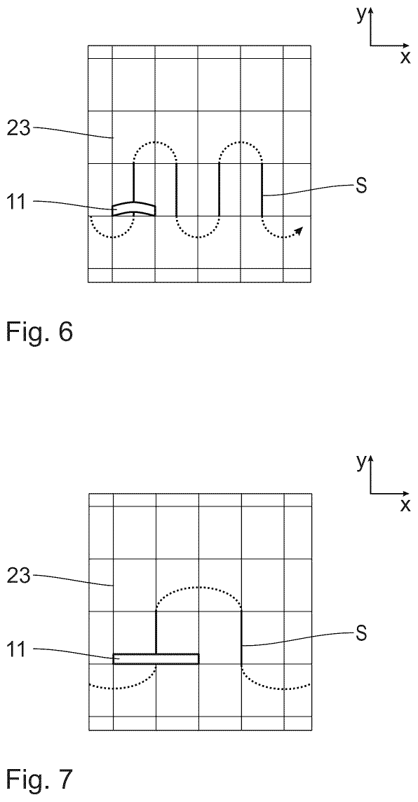

FIG. 6 shows a scanning path S corresponding to that in FIG. 5 when use is made of a variant of the projection optical unit 10 with an arcuate or ring field-shaped image field 11, once again with a standard extent of 26 mm in the x-direction, i.e. with a width exactly corresponding to the width of the exposure field 23. What was explained above in the context of FIG. 5 applies here accordingly.

FIG. 7 shows a scanning path S when use is made of the image field 11 of the projection optical unit 10 according to FIG. 2, i.e. the rectangular image field 11 with an x-extent corresponding to twice the x-direction of the respective exposure field 23. Two adjacent exposure fields 23 in the x-direction are scanned and exposed simultaneously along a respective exposure portion of the scanning path S using this twice as wide image field 11 of the projection optical unit 10 according to FIG. 2. Thus, in each scanning step, a projection exposure apparatus having the projection optical unit 10 according to FIG. 2 with the twice as wide image field 11 has twice the exposure throughput of exposed exposure fields 23 in comparison with the projection optical units with the single width image field 11 according to FIGS. 5 and 6. In particular, a number of unproductive connection portions (dashed lines) can be approximately halved in relation to the exposure fields 23 exposed in each exposure portion.

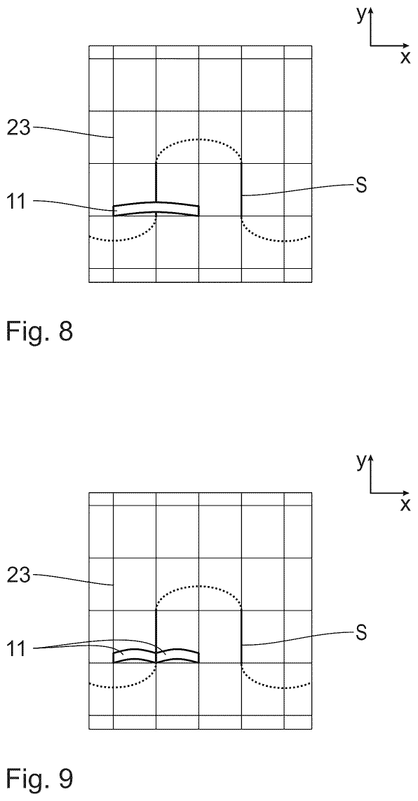

As an alternative to a rectangular image field 11 with twice the width, it is also possible to use an arcuate or partial ring-shaped image field 11 with twice the width, as depicted in FIG. 8. Such an arcuate or partial ring field-shaped image field 11 emerges in a variant of the projection optical unit 10.

In yet a further alternative to a rectangular image field 11 of twice the width, use can also be made of a double arch image field 11, as illustrated in FIG. 9. Such a double arch image field 11 according to FIG. 9 can be understood to be a placement next to one another in the x-direction of two arcuate or partial ring-shaped image fields 11 according to FIG. 6 with a single width. Such a double arch image field 11 according to FIG. 9 emerges in a further variant of the projection optical unit 10.

In each case one of the pupil facets 22 is assigned to exactly one of the field facets 20 for forming in each case an illumination channel for illuminating the object field 5. In particular, this can yield illumination according to the Köhler principle. The far field is decomposed into a multiplicity of object fields 5 with the aid of the field facets 20. The field facets 20 generate a plurality of images of the intermediate focus on the pupil facets 22 respectively assigned thereto.

By way of an assigned pupil facet 22, the field facets 20 are imaged in each case onto the reticle 7 in a manner superposed on one another for the purposes of illuminating the object field 5. The illumination of the object field 5 is in particular as homogeneous as possible. It can have a uniformity error of less than 2%. The field uniformity may be achieved by way of the overlay of different illumination channels.

The illumination of the entrance pupil of the projection optical unit 10 can be defined geometrically by way of an arrangement of the used pupil facets 22. The intensity distribution in the entrance pupil of the projection optical unit 10 can be set by selecting the illumination channels, in particular the subset of the pupil facets which guide light. This intensity distribution is also referred to as illumination setting or illumination pupil filling.

A likewise preferred pupil uniformity in the region of portions of an illumination pupil of the illumination optical unit 4 which are illuminated in a defined manner can be achieved by a redistribution of the illumination channels.

The projection optical unit 10 is telecentric on the image side.

Further aspects and details of the illumination of the object field 5 and in particular of the entrance pupil of the projection optical unit 10 are described below.

The projection optical unit 10 may have in particular a homocentric entrance pupil. In this case, the pupil facet mirror 21 can be arranged in the region of the entrance pupil of the projection optical unit 10 then arranged in the beam path upstream of the object field 5. In an alternative, the projection optical unit 10 can also have a telecentric embodiment on the object side. An arrangement plane of the pupil facet mirror 21 can be imaged into the entrance pupil with the aid of further components of the illumination optical unit 4 should the entrance pupil of the projection optical unit 10 be inaccessible.

The entrance pupil of the projection optical unit 10 regularly cannot be exactly illuminated using the pupil facet mirror 21. In the case of imaging of the projection optical unit 10 which telecentrically images the centre of the pupil facet mirror 21 onto the wafer 13, the aperture rays often do not intersect at a single point. However, it is possible to find an area in which the distance of the aperture rays determined in pairs becomes minimal. This area represents the entrance pupil or an area in real space that is conjugate thereto. In particular, this area has a finite curvature.

It may be the case that the projection optical unit 10 has different poses of the entrance pupil for the tangential beam path and for the sagittal beam path. In this case, an imaging element, in particular an optical component part of the transfer optical unit, should be provided between the second facet mirror 21 and the reticle 7. With the aid of this optical element, the different poses of the tangential entrance pupil and sagittal entrance pupil can be taken into account.

In the arrangement of the components of the illumination optical unit 4 illustrated in FIG. 1, the pupil facet mirror 21 is arranged so as to be tilted with respect to the object plane 5. The second facet mirror 21 is furthermore arranged so as to be tilted with respect to an arrangement plane defined by the first facet mirror 19.

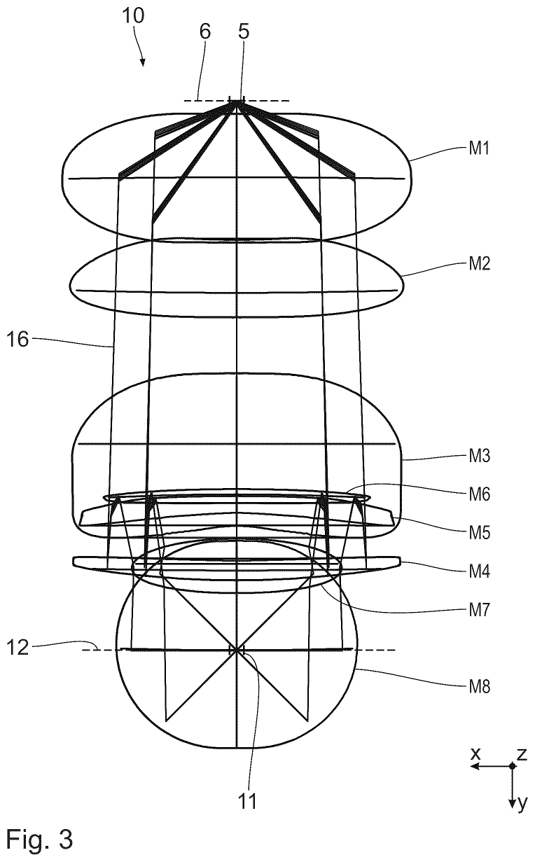

Further details relating to the projection optical unit 10 are described hereinafter on the basis of FIGS. 2 and 3.

The projection optical unit 10 has four NI mirrors (mirrors for normal incidence; normal incidence mirrors), namely the mirrors M1, M4, M7 and M8 in the imaging beam path of the projection optical unit 10. The imaging light 16 is applied to these NI mirrors M1, M4, M7, M8 at angles of incidence of less than 45°. The maximum angle of incidence of the imaging light 16 incident on the respective NI mirror, can be less than 40°, can be less than 35°, can be less than 30°, can be less than 25°, can be less than 20°, can be less than 15° and can also be less than 10°.

The other mirrors M2, M3, M5 and M6 of the projection optical unit 10 are GI mirrors (mirrors for grazing incidence, grazing incidence mirrors). For these mirrors M2, M3, M5 and M6, there are angles of incidence of the illumination light 16 on the mirrors of greater than 45° in each case. The minimum angle of incidence, which is incident on the respective GI mirror, can be greater than 50°, can be greater than 55°, can be greater than 60°, can be greater than 65°, can be greater than 70°, can be greater than 75° and can also be greater than 80°.

Information concerning reflection at a GI mirror (grazing incidence mirror) can be found in WO 2012/126867 A. Further information concerning the reflectivity of NI mirrors (normal incidence mirrors) can be found in DE 101 55 711 A.

More than four NI mirrors and/or fewer or more than four GI mirrors may also be present, depending on the embodiment of the projection optical unit 10.

The deflection effects of the mirrors M2 and M3 on the one hand, and M5 and M6 on the other hand add up. The projection optical unit 10 according to FIG. 2 thus has two GI mirror pairs with GI mirrors which in each case add in terms of their deflection effect.

The four NI mirrors M1, M4, M7 and M8 each have a subtractive deflection effect relative to one another, with the result that the imaging beam path is guided over these four NI mirrors M1, M4, M7 and M8 in a manner substantially along a zigzag course between the object field 5 and the image field 11.

None of the mirrors M1 to M8 has a passage opening and the mirrors are used in a reflective manner in a continuous region without gaps in each case.

FIG. 2 illustrates the calculated reflection surfaces of the mirrors M1 to M8. The used reflection surfaces of the mirrors M1 to M8 are carried in a known manner by mirror bodies (not shown). Without giving consideration to a polishing overrun edge, the projection optical unit 10 has an overall mirror surface of 0.71 m².

The object plane 6 and the image plane 12 extend parallel to one another to a good approximation.

The reflection surface of the antepenultimate mirror M6 in the imaging beam path faces the last mirror M8. As a consequence, the imaging beam path is guided around the last mirror M8. Between the mirror M4 and the mirror M7, the imaging beam path of the imaging light 16 is guided around the mirror M8 with the aid of the two GI mirrors M5 and M6.

The number of intermediate image planes in the x-direction and in the y-direction in the beam path between the object field 5 and the image field 11 differ in the case of the projection optical unit 10. In the yz-plane, the projection optical unit 10 has an intermediate image ZB in the form of a caustic in the region of an intermediate image arrangement plane 24 in the imaging beam path between the mirrors M5 and M6, as shown by the meridional section according to FIG. 2. The intermediate image ZB is present in the meridional plane of the projection optical unit 10, i.e. in a plane containing a chief ray of a central field point of the projection optical unit 10.

In the imaging direction perpendicular thereto with the imaging scale βₓ=−2.00, the projection optical unit 10 has no intermediate image, as may be gathered from the view according to FIG. 3. The image plane 12 is the first field plane after the object plane 6 in the xz-main plane of the projection optical unit 10 perpendicular to the meridional plane, i.e. in the imaging beam path of the projection optical unit 10 perpendicular to the yz-meridional plane. Thus, the projection optical unit 10 does not have an intermediate image perpendicular to the meridional plane. Thus, there is an image flip perpendicular to the meridional plane.

Examples of projection optical units with different numbers of such intermediate images in the x- and y-directions or in mutually perpendicular imaging light planes are known from US 2018/10656400 B2. Alternatively, the projection optical unit 10 may also be designed without an intermediate image or with the same number of intermediate images in the x- and y-directions.

The object field 5 and the image field 11 are offset from one another in the y-direction by a distance d_{OIS} (object-image offset). The object-image offset d_{OIS} is measured between a central field point of the object field 5 and a central field point of the image field 11 in a manner perpendicular to a normal N of the image plane 12. The object-image offset d_{OIS} is 910 mm.

An overall transmission of the projection optical unit 10, which emerges as a product of the EUV reflectivities of the mirrors M1 to M8 for the illumination light 16 along the imaging beam path through the projection optical unit 10, has a value of 10.2% in the projection optical unit 10 according to FIG. 2. On average, each individual one of the mirrors M1 to M8 thus has a reflectivity of more than 75%.

Thus, the overall transmission of the mirrors M1 to M8, i.e. the overall transmission of the projection optical unit 10, is greater than 5%. The overall transmission of the projection optical unit 10 can be greater than 6%, can be greater than 7%, can be greater than 8%, can be greater than 9% and can also be greater than 10%. On account of the number of mirrors and an individual EUV transmission of a mirror that guides the imaging light, which is regularly no more than 80%, the overall transmission is regularly less than 15%.

In the yz-plane, a first pupil plane of the projection optical unit 10 is located in the beam path of the imaging light in the region of the reflection of the imaging light 16 at the mirror M2. A second pupil plane in the yz-plane is located at the same location as the pupil plane in the xz-plane perpendicular thereto, at a location in the imaging beam path between the mirrors M7 and M8. An aperture can be limited in the case of the projection optical unit 10 by way of an aperture stop, which bounds the imaging beam path on the edge side, in particular, and which may be attached between the mirrors M7 and M8. If desired, an inner obscuration may also be defined by way of this stop with the aid of an appropriate stop portion. In the case of the projection optical unit 10, the aperture stop is present in the form of a plurality of stop portions arranged separately from one another in particular. For example, such a concept with a plurality of stop portions is known from U.S. Pat. No. 10,527,832. In the case of the projection optical unit 10, these stop portions are partially arranged in the beam path of the illumination light 16 between the mirrors M7 and M8 and at the location of the mirror M7.

A distance between the object plane 6 and the image plane 12 is 1708 mm in the case of the projection optical unit 10.

The mirrors M1 to M8 carry a coating that optimizes the reflectivity of the mirrors M1 to M8 for the imaging light 16. For the GI mirrors in particular, this may be a lanthanum coating, a boron coating or a boron coating with an uppermost layer of lanthanum, or else a ruthenium coating. Other coating materials may also be used, in particular lanthanum nitride and/or B₄C. In the mirrors M2, M3, M5 and M6 for grazing incidence, use can be made of a coating with e.g. one ply of boron or lanthanum. The highly reflecting layers, in particular of the mirrors M1, M4, M7 and M8 for normal incidence, can be configured as multi-ply layers, wherein successive layers can be manufactured from different materials. Alternating material layers can also be used. A typical multi-ply layer can have fifty bilayers, respectively made of a layer of boron and a layer of lanthanum. Layers containing lanthanum nitride and/or boron, in particular B₄C, may also be used.

Table 1, below, summarizes parameters of the projection optical unit 10. In addition to the data already explained above, Table 1 also specifies values for an angle of a chief ray of a central field point with respect to the z-axis and a usable étendue of the projection optical unit and a mean wavefront aberration RMS.

Table 1 for FIG. 2

| Wavelength | 13.5 | nm |
|---|---|---|
| Image-side numerical aperture | 0.33 | |
| Image field size in the x- and y-directions | 52 mm x 1.80 mm | |
| βₓ | −2.00 (without intermediate | |
| | image) | |
| β_{y} | 4.00 (with intermediate | |
| | image) | |
| Chief ray angle | 6° | |
| Étendue | 10.19 | mm² |
| Mean wavefront aberration RMS | 6.6 | mλ |
| Overall transmission | 10.2% | |
| Position of the entrance pupil (x) | −1349 | mm |
| Position of the entrance pupil (y) | −1897 | mm |
| Object-image offset in the y-direction | 910 | mm |
| Distance between M7 and image plane | 94 | mm |
| Distance between the object plane and | 1708 | mm |

| | |
|---|---|
| image plane | |
| Tilt between the object and | 0° |
| Image plane | |
| Installation space cuboid | (586 × 1056 × 1224) mm |

The z-extent of the installation space cuboid denotes the maximum z-distance between the used optical surfaces, i.e. the maximum z-distance between used optical surface portions of firstly the mirror M4 and secondly the mirror M7 in the example of the projection optical unit 10.

Tables 2a, 2b below summarize the parameters “maximum angle of incidence”, “extent of the reflection surface in the x-direction”, “extent of the reflection surface in the y-direction” and “maximum mirror diameter” for the mirrors M1 to M8 of the projection optical unit 10.

Table 2a for FIG. 2

| | M1 | M2 | M3 | M4 |
|---|---|---|---|---|
| Maximum angle of incidence [°] | 17.9 | 83.9 | 85.7 | 21.6 |
| Minimum angle of incidence [°] | 12.4 | 71.7 | 81.3 | 17.8 |
| Extent of the reflection surface | 586.5 | 561.2 | 553.5 | 550.7 |
| in the x-direction [mm] | | | | |
| Extent of the reflection surface | 215.0 | 214.5 | 336.4 | 49.8 |
| in the y-direction [mm] | | | | |
| Maximum mirror diameter [mm] | 586.6 | 561.3 | 570.6 | 550.9 |

Table 2b for FIG. 2

| | M5 | M6 | M7 | M8 |
|---|---|---|---|---|
| Maximum angle of incidence [°] | 82.0 | 86.3 | 25.3 | 14.3 |
| Minimum angle of incidence [°] | 77.1 | 79.9 | 4.0 | 7.8 |
| Extent of the reflection surface | 530.5 | 449.9 | 342.3 | 393.8 |
| in the x-direction [mm] | | | | |
| Extent of the reflection surface | 218.5 | 292.3 | 89.7 | 353.4 |
| in the y-direction [mm] | | | | |
| Maximum mirror diameter [mm] | 534.3 | 451.4 | 342.3 | 394.1 |

The illustrated mirror surfaces of the mirrors M1 to M8 do not have a polishing overrun edge. The actual used mirror surfaces of the mirrors M1 to M8 comprise the reflection surfaces actually used for reflecting the imaging light 16 and a polishing overrun edge with a radius of approximately 20 mm. Thus, an overhang in the form of the polishing overrun edge of at least 10 mm, and generally 20 mm, is present between the reflection mirror surface and a no longer polished region of the mirror surface.

An overall mirror surface, which represents a sum of the actually used reflection mirror surfaces of the mirrors M1 to M8 without a polishing overrun edge, is less than 1.5 m². A polishing overrun edge is included in this overall mirror surface. This overall mirror surface is 0.71 m² in the projection optical unit 10 according to FIG. 2. When the polishing overrun edge is taken into account, the overall mirror surface is 0.92 m².

The mirrors M1 to M8 are embodied as free-form surfaces which cannot be described by a rotationally symmetric function. Other embodiments of the projection optical unit 10, in which at least one of the mirrors M1 to M6 is embodied as a rotationally symmetric asphere, are also possible. It is also possible for all mirrors M1 to M6 to be embodied as such aspheres.

A free-form surface can be described by the following free-form surface equation (Equation 1):

$$Z = \frac{{c}_{x} {x}^{2} + {c}_{y} {y}^{2}}{1 + \sqrt{1 - ( 1 + {k}_{x} ) {( {c}_{x} x )}^{2} - ( 1 + {k}_{y} ) {( {c}_{y} y )}^{2}}} + {C}_{1} x + {C}_{2} y + {C}_{3} {x}^{2} + {C}_{4} xy + {C}_{5} {y}^{2} + {C}_{6} {x}^{3} + … + {C}_{9} {y}^{3} + {C}_{10} {x}^{4} + … + {C}_{12} {x}^{2} {y}^{2} + … + {C}_{14} {y}^{4} + {C}_{15} {x}^{5} + … + {C}_{20} {y}^{5} + {C}_{21} {x}^{6} + … + {C}_{24} {x}^{3} {y}^{3} + … + {C}_{27} {y}^{6} + … \qquad ( 1 )$$

The following applies to the parameters of this Equation (1):

Z is the sagittal height of the free-form surface at the point x, y, where x²+y²=r². Here, r is the distance from the reference axis of the free-form surface equation

$$( x = 0 ; y = 0 ) .$$

In the free-form surface Equation (1), C₁, C₂, C₃ . . . denote the coefficients of the free-form surface series expansion in powers of x and y.

In the case of a conical base area, cₓ, c_{y} is a constant corresponding to the vertex curvature of a corresponding asphere. Thus, cₓ=1/Rₓ (1/RDX) and c_{y}=1/R_{y} (1/RDY) applies. kₓ and k_{y} (CCX, CCY) each correspond to a conic constant of a corresponding asphere. Thus, Equation (1) describes a biconical free-form surface.

An alternative possible free-form surface can be produced from a rotationally symmetric reference surface. Such free-form surfaces for reflection surfaces of the mirrors of projection optical units of microlithographic projection exposure apparatuses are known from US 2007 0 058 269 A1.

Alternatively, free-form surfaces can also be described with the aid of two-dimensional spline surfaces. Examples for this are Bezier curves or non-uniform rational basis splines (NURBS). By way of example, two-dimensional spline surfaces can be described by a grid of points in an xy-plane and associated z-values, or by these points and gradients associated therewith. Depending on the respective type of the spline surface, the complete surface is obtained by interpolation between the grid points using for example polynomials or functions which have specific properties in respect of the continuity and differentiability thereof. Examples for this are analytical functions.

The optical design data of the reflection surfaces of the mirrors M1 to M8 of the projection optical unit 10 can be gathered from the further tables below.

Table 3 specifies coordinates of a surface origin of a respective mirror surface and of an area of the object field 5, in relation to a xyz-coordinate system of the image field 11.

The first column specifies the distance of the respective mirror or of the object field 5 from a coordinate origin in the centre of the image field 11 in the x-direction (first column), in the y-direction (second column) and in the z-direction (third column).

The additional columns of Table 3 (Table 3b) additionally specify tilt values of the respective surface of the mirror M1 to M8 or of the object field 5 in relation to the x-, y- and z-axis. In the embodiment according to FIG. 2, neither the object field 5 nor the image field 11 are tilted with respect to the x-axis and extend parallel to one another.

Table 4 tabulates, separately for the mirrors M1 to M8, the parameters RDX, RDY, CCX, CCY and, sorted according to the powers in x and y, the values of the coefficients C1, C2, C3 . . . of the free-form surface series expansion according to Equation (1) above.

Table 5 tabulates the reflectivities of the mirrors M1 to M8 and also the overall transmission of the projection optical unit 10, which is 10.2%.

Table 3a for FIG. 2

| | x-distance [mm] | y-distance [mm] | z-distance [mm] |
|---|---|---|---|
| Object field | 0 | 909.83 | 1707.79 |
| M1 | 0 | 786.67 | 536.09 |
| M2 | 0 | 594.34 | 970.93 |
| M3 | 0 | 343.25 | 1192.99 |
| M4 | 0 | 132.65 | 1301.61 |
| M5 | 0 | 245.35 | 1038.26 |
| M6 | 0 | 259.20 | 671.50 |
| Stop (AS) | 0 | 159.11 | 176.44 |
| M7 | 0 | 143.78 | 100.64 |
| M8 | 0 | 0 | 517.31 |
| Image field | 0 | 0 | 0 |

Table 3b for FIG. 2

| | Tilt about the x- | Tilt about the y- | Tilt about the z- |
|---|---|---|---|
| | axis [degrees] | axis [degrees] | axis [degrees] |
| Object field | 0 | 0 | 0 |
| M1 | 8.93 | 180 | 0 |
| M2 | −53.82 | 0 | 0 |
| M3 | −34.39 | 0 | 180 |
| M4 | 42.94 | 0 | 0 |
| M5 | −77.34 | 0 | 180 |
| M6 | 265.37 | 0 | 0 |
| Stop (AS) | −4.25 | 0 | 0 |
| M7 | 3.80 | 180 | 0 |
| M8 | 9.52 | 0 | 0 |
| Image field | 0 | 0 | 0 |

Table 4 for FIG. 2

| x**i * y**j | Coefficient |
|---|---|
| M1 | |
| RDX | −2462.637759 |
| RDY | −819.047838 |
| CCX | 0 |
| CCY | 0 |
| x**2*y**1 | 2.692373E−08 |
| x**0*y**3 | −9.417314E−08 |
| x**4*y**0 | −1.267909E−11 |
| x**2*y**2 | 1.363982E−12 |
| x**0*y**4 | −3.873943E−10 |
| x**4*y**1 | −1.055706E−14 |
| x**2*y**3 | −3.973854E−14 |
| x**0*y**5 | −1.408588E−12 |
| x**6*y**0 | −2.848868E−18 |
| x**4*y**2 | −1.240056E−17 |
| x**2*y**4 | 3.725850E−18 |
| x**0*y**6 | −3.390934E−15 |
| x**6*y**1 | −2.487913E−20 |
| x**4*y**3 | −1.635048E−19 |
| x**2*y**5 | −1.607185E−18 |
| x**0*y**7 | −1.690002E−17 |
| x**8*y**0 | 1.194113E−23 |
| x**6*y**2 | 3.893315E−23 |
| x**4*y**4 | 2.924892E−23 |
| x**2*y**6 | −3.395739E−21 |
| x**0*y**8 | −6.616734E−20 |
| x**8*y**1 | 3.046881E−25 |
| x**6*y**3 | 1.219826E−24 |
| x**4*y**5 | 1.061369E−24 |
| x**2*y**7 | −8.087005E−23 |
| x**0*y**9 | −4.012195E−22 |
| x**10*y**0 | −4.416328E−29 |
| x**8*y**2 | −2.743525E−27 |
| x**6*y**4 | 7.195423E−27 |
| x**4*y**6 | 2.368489E−26 |
| x**2*y**8 | −9.470655E−26 |
| x**0*y**10 | −2.321814E−25 |
| x**10*y**1 | −3.344501E−30 |
| x**8*y**3 | −3.274918E−29 |
| x**6*y**5 | −1.014836E−28 |
| x**4*y**7 | −9.195634E−29 |
| x**2*y**9 | 2.560695E−27 |
| x**0*y**11 | 5.491091E−27 |
| x**12*y**0 | −1.169794E−34 |
| x**10*y**2 | 4.467243E−32 |
| x**8*y**4 | −8.799709E−32 |
| x**6*y**6 | −8.231470E−31 |
| x**4*y**8 | −7.920568E−31 |
| x**2*y**10 | −1.445561E−29 |
| x**0*y**12 | −9.235084E−29 |
| x**12*y**1 | 1.210155E−35 |
| x**10*y**3 | 2.593903E−34 |
| x**8*y**5 | 4.994777E−34 |
| x**6*y**7 | 4.563670E−33 |
| x**4*y**9 | −3.037557E−33 |
| x**2*y**11 | −8.518347E−32 |
| x**0*y**13 | −3.971603E−31 |
| x**14*y**0 | 7.848081E−40 |
| x**12*y**2 | −2.554038E−37 |
| x**10*y**4 | 9.128537E−37 |
| x**8*y**6 | 1.720844E−36 |
| x**6*y**8 | 3.260220E−35 |
| x**4*y**10 | −1.170044E−34 |
| x**2*y**12 | −1.481590E−34 |
| x**0*y**14 | −4.139834E−34 |
| x**14*y**1 | 0.000000E+00 |
| x**12*y**3 | 0.000000E+00 |
| x**10*y**5 | 0.000000E+00 |
| x**8*y**7 | 0.000000E+00 |
| x**6*y**9 | 0.000000E+00 |
| x**4*y**11 | 0.000000E+00 |
| x**2*y**13 | 0.000000E+00 |
| x**0*y**15 | 0.000000E+00 |
| M2 | |
| RDX | 6700.164924 |
| RDY | 1238.128291 |
| CCX | 0 |
| CCY | 0 |
| x**2*y**1 | 8.112452E−08 |
| x**0*y**3 | −8.001421E−07 |
| x**4*y**0 | −8.695400E−12 |
| x**2*y**2 | −3.677678E−10 |
| x**0*y**4 | 1.932356E−09 |
| x**4*y**1 | 2.047393E−14 |
| x**2*y**3 | 1.372747E−12 |
| x**0*y**5 | −5.497187E−12 |
| x**6*y**0 | −6.750108E−19 |
| x**4*y**2 | 2.331052E−17 |
| x**2*y**4 | −6.596058E−15 |
| x**0*y**6 | 9.508850E−15 |
| x**6*y**1 | 1.233479E−19 |
| x**4*y**3 | −4.017223E−19 |
| x**2*y**5 | 3.635720E−17 |
| x**0*y**7 | 1.964780E−16 |
| x**8*y**0 | −2.601473E−22 |
| x**6*y**2 | −1.047704E−21 |
| x**4*y**4 | 3.859125E−21 |
| x**2*y**6 | −3.626612E−19 |
| x**0*y**8 | −3.792451E−18 |
| x**8*y**1 | −7.602741E−25 |
| x**6*y**3 | 2.128368E−24 |
| x**4*y**5 | 5.474492E−24 |
| x**2*y**7 | 3.325808E−21 |
| x**0*y**9 | 3.031579E−20 |
| x**10*y**0 | 2.675830E−27 |
| x**8*y**2 | 5.891752E−26 |
| x**6*y**4 | 5.895723E−26 |
| x**4*y**6 | 3.418369E−26 |
| x**2*y**8 | 2.602072E−24 |
| x**0*y**10 | −2.067257E−23 |
| x**10*y**1 | −1.541624E−29 |
| x**8*y**3 | −1.518126E−28 |
| x**6*y**5 | −2.036171E−28 |
| x**4*y**7 | −7.554587E−27 |
| x**2*y**9 | −3.603725E−25 |
| x**0*y**11 | −2.110812E−24 |
| x**12*y**0 | −1.843217E−32 |
| x**10*y**2 | −9.999299E−31 |
| x**8*y**4 | −3.078243E−30 |
| x**6*y**6 | −1.546693E−30 |
| x**4*y**8 | 8.404091E−29 |
| x**2*y**10 | 2.794298E−27 |
| x**0*y**12 | 2.366689E−26 |
| x**12*y**1 | 3.678802E−34 |
| x**10*y**3 | 4.282978E−33 |
| x**8*y**5 | 2.829741E−32 |
| x**6*y**7 | −7.867202E−32 |
| x**4*y**9 | −1.823632E−31 |
| x**2*y**11 | −4.549081E−30 |
| x**0*y**13 | −1.309504E−28 |
| x**14*y**0 | 6.684184E−38 |
| x**12*y**2 | 5.902911E−36 |
| x**10*y**4 | 2.451280E−35 |
| x**8*y**6 | 4.883581E−35 |
| x**6*y**8 | 8.873183E−34 |
| x**4*y**10 | −8.820582E−34 |
| x**2*y**12 | −3.160529E−32 |
| x**0*y**14 | 3.850792E−31 |
| x**14*y**1 | −1.818859E−39 |
| x**12*y**3 | −4.113233E−38 |
| x**10*y**5 | −2.305880E−37 |
| x**8*y**7 | −5.264692E−37 |
| x**6*y**9 | −2.684897E−36 |
| x**4*y**11 | 3.320725E−36 |
| x**2*y**13 | 1.107898E−34 |
| x**0*y**15 | −4.799712E−34 |
| M3 | |
| RDX | 77859.948588 |
| RDY | 53343.124552 |
| CCX | 0 |
| CCY | 0 |
| x**2*y**1 | −3.035442E−08 |
| x**0*y**3 | −1.614522E−08 |
| x**4*y**0 | −1.842140E−11 |
| x**2*y**2 | −8.230183E−12 |
| x**0*y**4 | 3.524483E−11 |
| x**4*y**1 | −3.332193E−14 |
| x**2*y**3 | −8.812911E−14 |
| x**0*y**5 | −1.686525E−13 |
| x**6*y**0 | −1.279620E−17 |
| x**4*y**2 | −9.010792E−17 |
| x**2*y**4 | −2.053759E−16 |
| x**0*y**6 | 4.334970E−16 |
| x**6*y**1 | 2.998903E−19 |
| x**4*y**3 | 3.416375E−21 |
| x**2*y**5 | −4.149066E−19 |
| x**0*y**7 | −2.328816E−18 |
| x**8*y**0 | 1.164712E−21 |
| x**6*y**2 | 1.852627E−21 |
| x**4*y**4 | −2.384084E−22 |
| x**2*y**6 | −1.902635E−21 |
| x**0*y**8 | 3.895369E−21 |
| x**8*y**1 | −8.110954E−24 |
| x**6*y**3 | 3.146141E−24 |
| x**4*y**5 | −1.842411E−24 |
| x**2*y**7 | 1.818658E−23 |
| x**0*y**9 | −3.941201E−23 |
| x**10*y**0 | −2.103632E−26 |
| x**8*y**2 | −7.924421E−26 |
| x**6*y**4 | −7.528684E−27 |
| x**4*y**6 | −1.345075E−25 |
| x**2*y**8 | −3.534607E−25 |
| x**0*y**10 | 3.410764E−25 |
| x**10*y**1 | 1.445735E−28 |
| x**8*y**3 | −1.367702E−28 |
| x**6*y**5 | 8.878689E−29 |
| x**4*y**7 | 6.570503E−29 |
| x**2*y**9 | −1.871767E−28 |
| x**0*y**11 | −7.010940E−28 |
| x**12*y**0 | 1.615324E−31 |
| x**10*y**2 | 1.351574E−30 |
| x**8*y**4 | 1.099683E−31 |
| x**6*y**6 | 1.823300E−30 |
| x**4*y**8 | 8.594251E−30 |
| x**2*y**10 | 1.140489E−29 |
| x**0*y**12 | −1.093087E−29 |
| x**12*y**1 | −1.301974E−33 |
| x**10*y**3 | 1.434573E−33 |
| x**8*y**5 | −2.969714E−33 |
| x**6*y**7 | −3.974887E−33 |
| x**4*y**9 | −3.193700E−32 |
| x**2*y**11 | 4.745416E−33 |
| x**0*y**13 | 1.367843E−32 |
| x**14*y**0 | −4.115207E−37 |
| x**12*y**2 | −7.898533E−36 |
| x**10*y**4 | −1.296665E−37 |
| x**8*y**6 | −1.463507E−35 |
| x**6*y**8 | −5.286296E−35 |
| x**4*y**10 | −1.726020E−34 |
| x**2*y**12 | −2.368857E−34 |
| x**0*y**14 | 3.241876E−34 |
| x**14*y**1 | 4.279323E−39 |
| x**12*y**3 | −4.162114E−40 |
| x**10*y**5 | 3.440886E−38 |
| x**8*y**7 | 5.143788E−38 |
| x**6*y**9 | 2.796277E−37 |
| x**4*y**11 | 5.596537E−37 |
| x**2*y**13 | 3.166833E−37 |
| x**0*y**15 | −1.147086E−36 |
| M4 | |
| RDX | −7129.343340 |
| RDY | −1051.108958 |
| CCX | 0 |
| CCY | 0 |
| x**2*y**1 | 3.916214E−08 |
| x**0*y**3 | 1.555675E−06 |
| x**4*y**0 | 2.530558E−11 |
| x**2*y**2 | 6.322424E−10 |
| x**0*y**4 | 1.993860E−08 |
| x**4*y**1 | 6.599044E−14 |
| x**2*y**3 | 8.201081E−12 |
| x**0*y**5 | 2.838184E−10 |
| x**6*y**0 | −8.002571E−18 |
| x**4*y**2 | 1.612459E−15 |
| x**2*y**4 | 1.917174E−13 |
| x**0*y**6 | 5.119264E−12 |
| x**6*y**1 | −3.445411E−19 |
| x**4*y**3 | 2.231786E−17 |
| x**2*y**5 | 3.796076E−15 |
| x**0*y**7 | 1.311788E−13 |
| x**8*y**0 | −1.713375E−22 |
| x**6*y**2 | −1.234942E−20 |
| x**4*y**4 | −3.094549E−19 |
| x**2*y**6 | 8.443284E−17 |
| x**0*y**8 | 5.120747E−15 |
| x**8*y**1 | 7.846835E−24 |
| x**6*y**3 | −6.129882E−22 |
| x**4*y**5 | −1.224715E−20 |
| x**2*y**7 | −1.781798E−19 |
| x**0*y**9 | −7.775146E−17 |
| x**10*y**0 | 3.053482E−27 |
| x**8*y**2 | 5.908078E−25 |
| x**6*y**4 | 3.780249E−23 |
| x**4*y**6 | 3.758186E−21 |
| x**2*y**8 | −7.607565E−20 |
| x**0*y**10 | −3.988717E−18 |
| x**10*y**1 | −1.420746E−28 |
| x**8*y**3 | 1.792039E−26 |
| x**6*y**5 | −3.028803E−25 |
| x**4*y**7 | 8.072258E−24 |
| x**2*y**9 | 6.416729E−21 |
| x**0*y**11 | 6.410913E−19 |
| x**12*y**0 | −1.804619E−32 |
| x**10*y**2 | −1.023108E−29 |
| x**8*y**4 | −7.107535E−28 |
| x**6*y**6 | −1.052452E−25 |
| x**4*y**8 | −3.738540E−24 |
| x**2*y**10 | 3.363709E−22 |
| x**0*y**12 | 9.062083E−21 |
| x**12*y**1 | 1.370024E−33 |
| x**10*y**3 | −2.048792E−31 |
| x**8*y**5 | 2.365765E−29 |
| x**6*y**7 | 1.894373E−27 |
| x**4*y**9 | 1.093857E−25 |
| x**2*y**11 | −1.666426E−23 |
| x**0*y**13 | −1.012185E−21 |
| x**14*y**0 | 3.714965E−39 |
| x**12*y**2 | 6.300325E−35 |
| x**10*y**4 | 5.761710E−33 |
| x**8*y**6 | 7.615654E−31 |
| x**6*y**8 | 1.262098E−29 |
| x**4*y**10 | 2.520976E−27 |
| x**2*y**12 | −3.918022E−25 |
| x**0*y**14 | −2.867403E−26 |
| x**14*y**1 | −5.616469E−39 |
| x**12*y**3 | 5.798685E−37 |
| x**10*y**5 | −2.965671E−34 |
| x**8*y**7 | −7.357082E−33 |
| x**6*y**9 | −1.915419E−30 |
| x**4*y**11 | 4.349703E−29 |
| x**2*y**13 | 1.578825E−26 |
| x**0*y**15 | 8.417219E−25 |
| M5 | |
| RDX | −165915.41972 |
| RDY | −9019.227961 |
| CCX | 0 |
| CCY | 0 |
| x**2*y**1 | −2.829748E−08 |
| x**0*y**3 | 8.096274E−09 |
| x**4*y**0 | 1.756828E−11 |
| x**2*y**2 | −1.920333E−10 |
| x**0*y**4 | −2.811280E−10 |
| x**4*y**1 | 6.172165E−14 |
| x**2*y**3 | 4.036560E−13 |
| x**0*y**5 | 6.753935E−13 |
| x**6*y**0 | 7.030808E−17 |
| x**4*y**2 | −4.780267E−16 |
| x**2*y**4 | −2.643119E−15 |
| x**0*y**6 | −5.649683E−15 |
| x**6*y**1 | 5.155860E−19 |
| x**4*y**3 | 1.644236E−18 |
| x**2*y**5 | 1.130813E−17 |
| x**0*y**7 | 1.492185E−17 |
| x**8*y**0 | 7.114268E−22 |
| x**6*y**2 | 6.968944E−22 |
| x**4*y**4 | −5.618073E−22 |
| x**2*y**6 | 3.612586E−20 |
| x**0*y**8 | 5.072106E−19 |
| x**8*y**1 | −7.344286E−24 |
| x**6*y**3 | 5.488076E−23 |
| x**4*y**5 | 1.125606E−22 |
| x**2*y**7 | −2.094430E−21 |
| x**0*y**9 | −5.641770E−21 |
| x**10*y**0 | −1.627828E−26 |
| x**8*y**2 | −1.462629E−25 |
| x**6*y**4 | −1.046300E−24 |
| x**4*y**6 | −5.365935E−24 |
| x**2*y**8 | 7.004938E−24 |
| x**0*y**10 | −6.614545E−23 |
| x**10*y**1 | 2.163232E−28 |
| x**8*y**3 | −9.290230E−28 |
| x**6*y**5 | 1.229082E−26 |
| x**4*y**7 | 3.665054E−26 |
| x**2*y**9 | 6.841021E−25 |
| x**0*y**11 | 1.327447E−24 |
| x**12*y**0 | 1.047884E−31 |
| x**10*y**2 | 3.234212E−30 |
| x**8*y**4 | 1.241373E−29 |
| x**6*y**6 | 2.562987E−28 |
| x**4*y**8 | −1.545381E−27 |
| x**2*y**10 | −9.215162E−27 |
| x**0*y**12 | −7.764865E−27 |
| x**12*y**1 | −3.470038E−33 |
| x**10*y**3 | 6.709049E−33 |
| x**8*y**5 | −6.248093E−31 |
| x**6*y**7 | −2.026121E−30 |
| x**4*y**9 | 1.923086E−29 |
| x**2*y**11 | 4.329641E−29 |
| x**0*y**13 | 1.932513E−29 |
| x**14*y**0 | 1.114796E−37 |
| x**12*y**2 | −1.938539E−35 |
| x**10*y**4 | 2.664421E−34 |
| x**8*y**6 | 3.491830E−33 |
| x**6*y**8 | 3.073737E−33 |
| x**4*y**10 | −9.138776E−32 |
| x**2*y**12 | −5.634549E−32 |
| x**0*y**14 | −3.217362E−32 |
| x**14*y**1 | 1.880193E−38 |
| x**12*y**3 | −1.159387E−37 |
| x**10*y**5 | −4.146998E−37 |
| x**8*y**7 | −6.972660E−36 |
| x**6*y**9 | 6.677080E−36 |
| x**4*y**11 | 1.526161E−34 |
| x**2*y**13 | −7.182275E−35 |
| x**0*y**15 | 7.890294E−35 |
| M6 | |
| RDX | −4309.736134 |
| RDY | 12026.446529 |
| CCX | 0 |
| CCY | 0 |
| x**2*y**1 | 8.315298E−08 |
| x**0*y**3 | −6.466757E−08 |
| x**4*y**0 | 2.795801E−11 |
| x**2*y**2 | −1.209123E−10 |
| x**0*y**4 | 1.688545E−10 |
| x**4*y**1 | −8.926932E−14 |
| x**2*y**3 | 2.437755E−13 |
| x**0*y**5 | −5.654665E−13 |
| x**6*y**0 | 3.164784E−17 |
| x**4*y**2 | 1.201054E−16 |
| x**2*y**4 | −1.178472E−15 |
| x**0*y**6 | 1.952053E−15 |
| x**6*y**1 | −1.959901E−19 |
| x**4*y**3 | −1.297881E−18 |
| x**2*y**5 | 4.347623E−18 |
| x**0*y**7 | −7.430008E−18 |
| x**8*y**0 | −7.290204E−22 |
| x**6*y**2 | −1.803563E−21 |
| x**4*y**4 | 3.383802E−21 |
| x**2*y**6 | −1.569256E−20 |
| x**0*y**8 | 3.451726E−20 |
| x**8*y**1 | 6.045376E−24 |
| x**6*y**3 | 2.178121E−23 |
| x**4*y**5 | 2.517071E−23 |
| x**2*y**7 | 1.344533E−22 |
| x**0*y**9 | −1.357114E−22 |
| x**10*y**0 | 1.925098E−26 |
| x**8*y**2 | 6.980050E−26 |
| x**6*y**4 | 1.694691E−25 |
| x**4*y**6 | −8.892450E−27 |
| x**2*y**8 | −1.292742E−24 |
| x**0*y**10 | −2.190312E−26 |
| x**10*y**1 | −8.242518E−29 |
| x**8*y**3 | −7.648515E−28 |
| x**6*y**5 | −1.712239E−27 |
| x**4*y**7 | −3.927015E−27 |
| x**2*y**9 | 3.960675E−27 |
| x**0*y**11 | 1.268256E−27 |
| x**12*y**0 | −2.213972E−31 |
| x**10*y**2 | −1.206883E−30 |
| x**8*y**4 | −4.824937E−30 |
| x**6*y**6 | −5.907253E−30 |
| x**4*y**8 | 3.972139E−29 |
| x**2*y**10 | 1.152814E−29 |
| x**0*y**12 | 2.302353E−29 |
| x**12*y**1 | 6.450467E−34 |
| x**10*y**3 | 2.064408E−32 |
| x**8*y**5 | 3.641799E−32 |
| x**6*y**7 | 7.901542E−32 |
| x**4*y**9 | −7.503361E−32 |
| x**2*y**11 | −1.605848E−32 |
| x**0*y**13 | −2.360716E−31 |
| x**14*y**0 | 9.494889E−37 |
| x**12*y**2 | 7.218056E−36 |
| x**10*y**4 | 3.960155E−35 |
| x**8*y**6 | 1.450379E−34 |
| x**6*y**8 | −4.038789E−34 |
| x**4*y**10 | −6.351111E−34 |
| x**2*y**12 | −4.904599E−34 |
| x**0*y**14 | 7.944333E−34 |
| x**14*y**1 | −3.087693E−39 |
| x**12*y**3 | −2.348729E−37 |
| x**10*y**5 | −4.422742E−37 |
| x**8*y**7 | −5.763713E−37 |
| x**6*y**9 | 1.159475E−36 |
| x**4*y**11 | 2.270275E−36 |
| x**2*y**13 | 1.407925E−36 |
| x**0*y**15 | −9.402376E−37 |
| M7 | |
| RDX | 7577.046353 |
| RDY | 383.725675 |
| CCX | 0 |
| CCY | 0 |
| x**2*y**1 | 6.768618E−07 |
| x**0*y**3 | 3.435350E−06 |
| x**4*y**0 | 2.765931E−10 |
| x**2*y**2 | 4.740509E−09 |
| x**0*y**4 | 2.493649E−08 |
| x**4*y**1 | 1.900542E−12 |
| x**2*y**3 | 3.372972E−11 |
| x**0*y**5 | 9.701566E−11 |
| x**6*y**0 | 5.415708E−16 |
| x**4*y**2 | 2.118186E−14 |
| x**2*y**4 | 2.050801E−13 |
| x**0*y**6 | 3.942514E−13 |
| x**6*y**1 | 6.390532E−18 |
| x**4*y**3 | 1.694250E−16 |
| x**2*y**5 | 1.145808E−15 |
| x**0*y**7 | 1.511450E−15 |
| x**8*y**0 | 1.614564E−21 |
| x**6*y**2 | 1.085346E−19 |
| x**4*y**4 | 1.794844E−18 |
| x**2*y**6 | 1.047896E−17 |
| x**0*y**8 | −6.095830E−17 |
| x**8*y**1 | 3.259604E−23 |
| x**6*y**3 | 1.285736E−21 |
| x**4*y**5 | 2.003890E−20 |
| x**2*y**7 | 4.583675E−20 |
| x**0*y**9 | −9.149449E−19 |
| x**10*y**0 | −9.094991E−27 |
| x**8*y**2 | −1.432838E−24 |
| x**6*y**4 | −3.747964E−23 |
| x**4*y**6 | −3.762988E−22 |
| x**2*y**8 | −4.157581E−21 |
| x**0*y**10 | 1.648453E−20 |
| x**10*y**1 | −7.711568E−28 |
| x**8*y**3 | −3.687595E−26 |
| x**6*y**5 | −7.594520E−25 |
| x**4*y**7 | −1.410642E−23 |
| x**2*y**9 | −7.547652E−23 |
| x**0*y**11 | 2.115484E−22 |
| x**12*y**0 | 3.187339E−31 |
| x**10*y**2 | 6.216100E−29 |
| x**8*y**4 | 2.408679E−27 |
| x**6*y**6 | 3.306732E−26 |
| x**4*y**8 | 1.618681E−25 |
| x**2*y**10 | 1.441826E−24 |
| x**0*y**12 | 5.015223E−25 |
| x**12*y**1 | 2.841468E−32 |
| x**10*y**3 | 1.914993E−30 |
| x**8*y**5 | 4.896347E−29 |
| x**6*y**7 | 6.892343E−28 |
| x**4*y**9 | 8.100046E−27 |
| x**2*y**11 | 5.201076E−26 |
| x**0*y**13 | 2.082479E−25 |
| x**14*y**0 | −2.896175E−36 |
| x**12*y**2 | −7.410966E−34 |
| x**10*y**4 | −3.976574E−32 |
| x**8*y**6 | −8.493235E−31 |
| x**6*y**8 | 6.308386E−30 |
| x**4*y**10 | 2.426479E−29 |
| x**2*y**12 | 5.818111E−28 |
| x**0*y**14 | 2.994636E−27 |
| x**14*y**1 | −3.267134E−37 |
| x**12*y**3 | −2.915883E−35 |
| x**10*y**5 | −1.022996E−33 |
| x**8*y**7 | −1.742803E−32 |
| x**6*y**9 | −1.593683E−31 |
| x**4*y**11 | −5.681950E−31 |
| x**2*y**13 | 1.657006E−30 |
| x**0*y**15 | 5.865852E−30 |
| M8 | |
| RDX | −1016.247822 |
| RDY | −559.401569 |
| CCX | 0 |
| CCY | 0 |
| x**2*y**1 | −5.767649E−08 |
| x**0*y**3 | −1.924696E−08 |
| x**4*y**0 | −1.003362E−10 |
| x**2*y**2 | −2.510302E−10 |
| x**0*y**4 | −1.057559E−10 |
| x**4*y**1 | −7.237403E−14 |
| x**2*y**3 | −1.522567E−13 |
| x**0*y**5 | −2.604031E−15 |
| x**6*y**0 | −1.480775E−16 |
| x**4*y**2 | −7.506605E−16 |
| x**2*y**4 | −1.061367E−15 |
| x**0*y**6 | −3.208732E−16 |
| x**6*y**1 | −1.070730E−19 |
| x**4*y**3 | −4.243154E−19 |
| x**2*y**5 | −3.819521E−19 |
| x**0*y**7 | 1.645406E−19 |
| x**8*y**0 | −2.477435E−22 |
| x**6*y**2 | −1.669803E−21 |
| x**4*y**4 | −3.824078E−21 |
| x**2*y**6 | −3.461637E−21 |
| x**0*y**8 | 4.850147E−22 |
| x**8*y**1 | −7.487523E−25 |
| x**6*y**3 | −2.558018E−24 |
| x**4*y**5 | −4.000846E−24 |
| x**2*y**7 | −2.593407E−24 |
| x**0*y**9 | −9.089245E−24 |
| x**10*y**0 | 6.662856E−28 |
| x**8*y**2 | 3.486745E−27 |
| x**6*y**4 | −1.046204E−26 |
| x**4*y**6 | −4.248937E−26 |
| x**2*y**8 | −4.099969E−26 |
| x**0*y**10 | −5.813158E−26 |
| x**10*y**1 | 3.402707E−29 |
| x**8*y**3 | 1.041387E−28 |
| x**6*y**5 | 1.826434E−28 |
| x**4*y**7 | 1.683081E−28 |
| x**2*y**9 | 8.389606E−29 |
| x**0*y**11 | 1.688905E−28 |
| x**12*y**0 | −1.612612E−32 |
| x**10*y**2 | −1.839073E−31 |
| x**8*y**4 | −2.642780E−31 |
| x**6*y**6 | 3.537379E−31 |
| x**4*y**8 | 1.111782E−30 |
| x**2*y**10 | 8.401901E−31 |
| x**0*y**12 | 8.018283E−31 |
| x**12*y**1 | −8.212925E−34 |
| x**10*y**3 | −3.232202E−33 |
| x**8*y**5 | −6.424512E−33 |
| x**6*y**7 | −9.624637E−33 |
| x**4*y**9 | −5.995400E−33 |
| x**2*y**11 | −3.605966E−33 |
| x**0*y**13 | −4.784435E−33 |
| x**14*y**0 | 1.012163E−37 |
| x**12*y**2 | 1.650280E−36 |
| x**10*y**4 | 4.056357E−36 |
| x**8*y**6 | −1.712794E−37 |
| x**6*y**8 | −1.369156E−35 |
| x**4*y**10 | −1.843762E−35 |
| x**2*y**12 | −1.369701E−35 |
| x**0*y**14 | −5.907409E−36 |
| x**14*y**1 | 7.014427E−39 |
| x**12*y**3 | 3.455844E−38 |
| x**10*y**5 | 8.165041E−38 |
| x**8*y**7 | 1.368567E−37 |
| x**6*y**9 | 1.618136E−37 |
| x**4*y**11 | 7.069689E−38 |
| x**2*y**13 | 4.891906E−38 |
| x**0*y**15 | 3.446812E−38 |

Table 5 for FIG. 2

| Mirrors | Reflectivity [%] |
|---|---|
| M1 | 65.5 |
| M2 | 82.0 |
| M3 | 90.4 |
| M4 | 63.5 |
| M5 | 85.1 |
| M6 | 90.1 |
| M7 | 64.9 |
| M8 | 66.8 |
| Overall transmission | 10.2 |

Mirrors with different signs for the values RDX and RDY have a saddle point-type or minimax basic shape.

In the case of the projection optical unit 10, the GI mirror M6 is located spatially next to the last mirror M8.

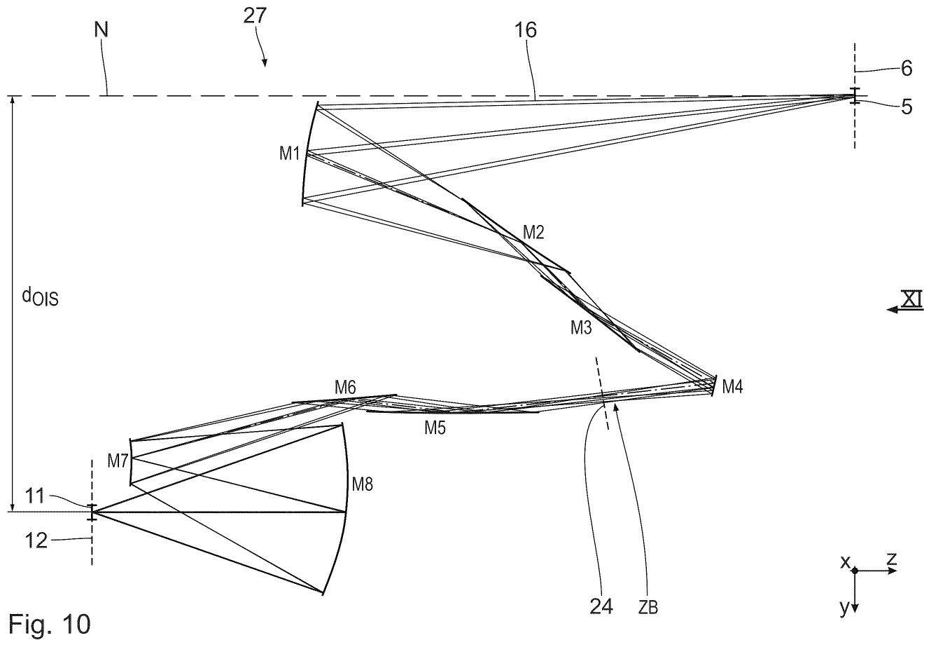

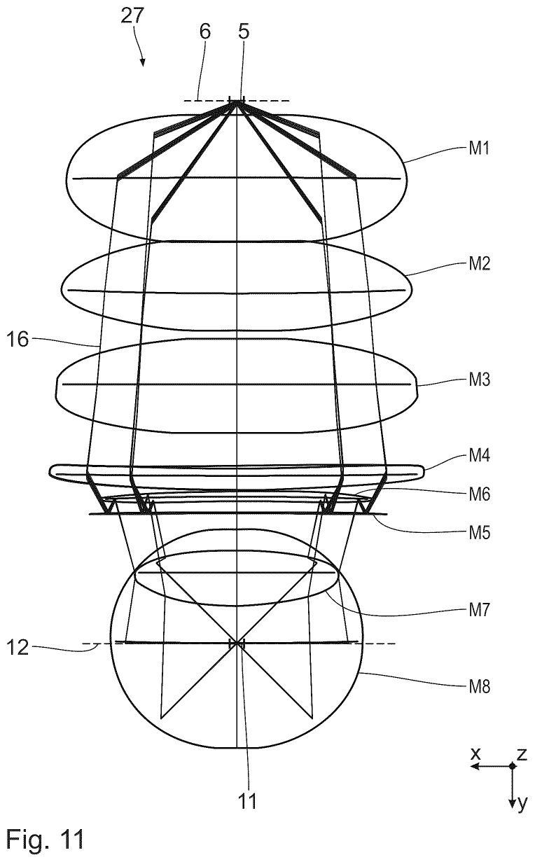

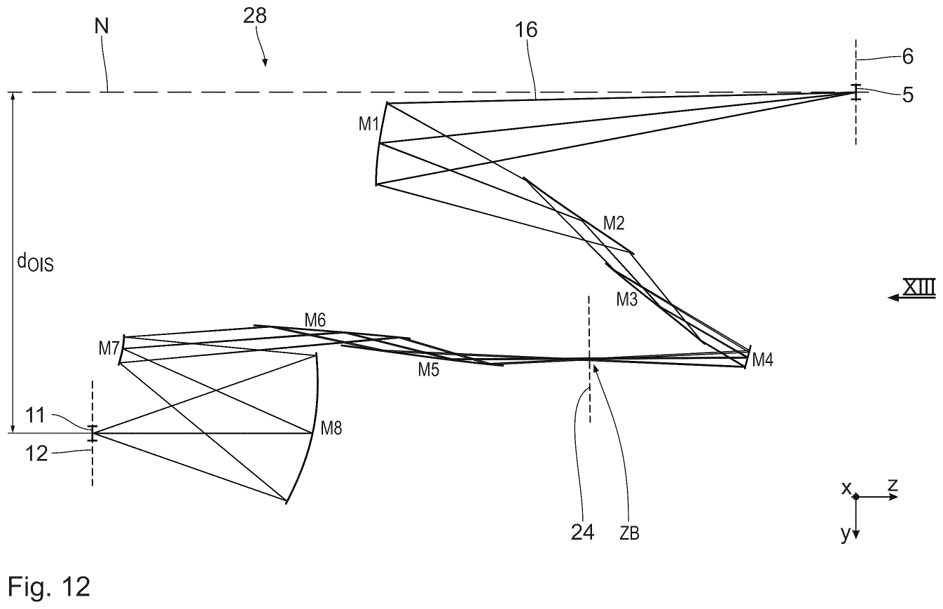

FIGS. 10 and 11 show a further embodiment of a projection optical unit or imaging optical unit 27, which can be used in the projection exposure apparatus 1 instead of the projection optical unit 10 of the embodiment according to FIG. 2. Components and functions corresponding to those which have already been explained above in conjunction with FIGS. 1 to 9, and in particular in conjunction with FIGS. 1 to 3, are denoted by the same reference signs and are not discussed in detail again.

The basic structure of the projection optical unit 27 corresponds to that of the projection optical unit 10.

In the case of the projection optical unit 27, the two GI mirror pairs M2, M3 on the one hand and M5, M6 on the other hand in each case have a subtractive deflection effect in relation to one another.

The last GI mirror M6 is spatially adjacent to the last mirror M8, determining the image-side numerical aperture, of the projection optical unit 27.

In the projection optical unit 27, an intermediate image ZB, once again in the form of a caustic, is located in the imaging beam path between the mirrors M4 and M5.

The projection optical unit 27 has an accessible entrance pupil in the imaging beam path upstream of the object field 5.

In the projection optical unit 27, an exit pupil is located in the region of the reflection at the mirror M7. Then, the aperture stop can be arranged on this mirror and can also, if desired, specify an inner obscuration of the projection optical unit 27.

A distance between the object plane 6 and the image plane 12 is 1650 mm in the case of the projection optical unit 27.

The overall transmission of the projection optical unit 27 is 10.4%.

The following tables summarize parameters and the optical design of the projection optical unit 27. In terms of their structure, these tables correspond to those already explained above in conjunction with FIG. 2.

Table 6 tabulates opening data for an aperture stop AS of the projection optical unit 27 arranged in the region of the mirror M7. This aperture opening is defined by a polygon, the x- and y-values of which are specified in Table 6.

Table 1 for FIG. 10

| Wavelength | 13.5 | nm |
|---|---|---|
| Image-side numerical aperture | 0.33 | |
| Image field size in the x- and y- | 52 mm x 1.7 mm | |
| directions | | |
| βₓ | −2.00 (without intermediate | |
| | image) | |
| β_{y} | 4.00 (with intermediate image) | |
| Chief ray angle | 6° | |
| Étendue | 9.63 | mm² |
| Mean wavefront aberration RMS | 5.7 m2 | mλ |
| Overall transmission | 10.4% | |
| Position of the entrance pupil (x) | −1819 | |
| Position of the entrance pupil (y) | −6897 | |
| Object-image offset in the y-direction | 902 | mm |
| Distance between M7 and image plane | 80 | mm |
| Distance between the object plane and | 1650 | mm |
| image plane | | |
| Tilt between the object and | 0 | mm |

| | |
|---|---|
| Image plane | |
| Installation space cuboid | (626 × 1057 × 1268) mm |

TABLE 2a for FIG. 10

| | M1 | M2 | M3 | M4 |
|---|---|---|---|---|
| Maximum angle of incidence [°] | 17.2 | 85.4 | 84.9 | 20.1 |
| Minimum angle of incidence [°] | 12.7 | 73.2 | 80.1 | 16.4 |
| Extent of the reflection surface | 569.6 | 586.8 | 605.5 | 626.2 |
| in the x-direction [mm] | | | | |
| Extent of the reflection surface | 212.3 | 262.7 | 260.6 | 41.0 |
| in the y-direction [mm] | | | | |
| Maximum mirror diameter [mm] | 569.6 | 586.9 | 606.1 | 626.4 |

TABLE 2b for FIG. 10

| | M5 | M6 | M7 | M8 |
|---|---|---|---|---|
| Maximum angle of incidence [°] | 85.7 | 81.7 | 24.6 | 12.3 |
| Minimum angle of incidence [°] | 81.2 | 76.2 | 3.6 | 5.1 |
| Extent of the reflection surface | 502.4 | 456.2 | 337.8 | 418.6 |
| in the x-direction [mm] | | | | |
| Extent of the reflection surface | 355.4 | 215.9 | 91.9 | 371.7 |
| in the y-direction [mm] | | | | |
| Maximum mirror diameter [mm] | 505.8 | 456.3 | 337.8 | 418.6 |

TABLE 3a for FIG. 10

| | x-distance [mm] | y-distance [mm] | z-distance [mm] |
|---|---|---|---|
| Object field | 0 | 901.61 | 1649.96 |
| M1 | 0 | 777.06 | 464.95 |
| M2 | 0 | 583.51 | 928.15 |
| M3 | 0 | 431.86 | 1077.44 |
| M4 | 0 | 279.30 | 1345.40 |
| M5 | 0 | 216.02 | 788.75 |
| M6 | 0 | 244.55 | 553.25 |
| Stop (AS) | 0 | 117.33 | 80.92 |
| M7 | 0 | 117.36 | 84.50 |
| M8 | 0 | 0 | 548.68 |
| Image field | 0 | 0 | 0 |

The stop AS is arranged on the mirror M7. The position and the tilt of the stop surface of the stop AS consider a sag of the mirror M7 at the edge of its aperture.

TABLE 3b for FIG. 10

| | Tilt about the x- | Tilt about the y- | Tilt about the z- |
|---|---|---|---|
| | axis [degrees] | axis [degrees] | axis [degrees] |
| Object field | 0 | 0 | 0 |
| M1 | 8.34 | 180 | 0 |
| M2 | −55.94 | 0 | 0 |
| M3 | −52.45 | 180 | 0 |
| M4 | 11.58 | 0 | 0 |
| M5 | −89.79 | 180 | 0 |
| M6 | 265.86 | 0 | 0 |
| Stop (AS) | −0.28 | 180 | 0 |
| M7 | −0.50 | 180 | 0 |
| M8 | 7.09 | 0 | 0 |
| Image field | 0 | 0 | 0 |

Table 4 for FIG. 10

| x**i * y**j | Coefficient |
|---|---|
| M1 | |
| RDX | −3151.463813 |
| RDY | −861.720690 |
| CCX | 0 |
| CCY | 0 |
| x**2*y**1 | 4.608415E−08 |
| x**0*y**3 | −2.549388E−07 |
| x**4*y**0 | −8.592248E−12 |
| x**2*y**2 | 2.189097E−11 |
| x**0*y**4 | 1.856170E−11 |
| x**4*y**1 | −8.152359E−15 |
| x**2*y**3 | −5.571227E−14 |
| x**0*y**5 | −2.877416E−12 |
| x**6*y**0 | −1.530606E−18 |
| x**4*y**2 | −1.978361E−17 |
| x**2*y**4 | 7.645096E−16 |
| x**0*y**6 | 1.681742E−15 |
| x**6*y**1 | 1.736230E−20 |
| x**4*y**3 | −1.118932E−19 |
| x**2*y**5 | −1.517594E−18 |
| x**0*y**7 | −4.456532E−17 |
| x**8*y**0 | −2.478263E−23 |
| x**6*y**2 | −1.030916E−22 |
| x**4*y**4 | 9.790631E−22 |
| x**2*y**6 | 1.778233E−20 |
| x**0*y**8 | 5.182528E−20 |
| x**8*y**1 | −3.778406E−25 |
| x**6*y**3 | −7.432391E−24 |
| x**4*y**5 | −3.656728E−23 |
| x**2*y**7 | −1.462859E−22 |
| x**0*y**9 | −4.165548E−21 |
| x**10*y**0 | 6.062642E−28 |
| x**8*y**2 | 4.078770E−27 |
| x**6*y**4 | −1.367459E−26 |
| x**4*y**6 | 9.371296E−27 |
| x**2*y**8 | 2.566792E−24 |
| x**0*y**10 | 1.254626E−23 |
| x**10*y**1 | 6.640515E−30 |
| x**8*y**3 | 1.619571E−28 |
| x**6*y**5 | 9.082426E−28 |
| x**4*y**7 | 1.902060E−27 |
| x**2*y**9 | −2.852519E−27 |
| x**0*y**11 | 2.293820E−25 |
| x**12*y**0 | −5.647276E−33 |
| x**10*y**2 | −5.190486E−32 |
| x**8*y**4 | 1.919234E−31 |
| x**6*y**6 | 1.543800E−30 |
| x**4*y**8 | 8.995400E−31 |
| x**2*y**10 | −8.856316E−29 |
| x**0*y**12 | −2.113862E−28 |
| x**12*y**1 | −5.372392E−35 |
| x**10*y**3 | −1.699027E−33 |
| x**8*y**5 | −1.434335E−32 |
| x**6*y**7 | −5.289987E−32 |
| x**4*y**9 | −1.392677E−31 |
| x**2*y**11 | −3.531306E−31 |
| x**0*y**13 | −1.573286E−29 |
| x**14*y**0 | 2.104927E−38 |
| x**12*y**2 | 2.946229E−37 |
| x**10*y**4 | −5.994931E−38 |
| x**8*y**6 | −1.657173E−35 |
| x**6*y**8 | 9.266964E−36 |
| x**4*y**10 | −4.361945E−35 |
| x**2*y**12 | 3.083307E−33 |
| x**0*y**14 | 1.796508E−33 |
| x**14*y**1 | 1.060888E−40 |
| x**12*y**3 | 6.217852E−39 |
| x**10*y**5 | 7.938247E−38 |
| x**8*y**7 | 3.671030E−37 |
| x**6*y**9 | 1.347802E−36 |
| x**4*y**11 | 4.198819E−36 |
| x**2*y**13 | 1.554751E−35 |
| x**0*y**15 | 3.443530E−34 |
| M2 | |
| RDX | 5628.573875 |
| RDY | 1905.181165 |
| CCX | 0 |
| CCY | 0 |
| x**2*y**1 | 6.464536E−08 |
| x**0*y**3 | −5.667694E−08 |
| x**4*y**0 | −4.029902E−11 |
| x**2*y**2 | 3.936683E−11 |
| x**0*y**4 | −1.418381E−09 |
| x**4*y**1 | 4.460377E−14 |
| x**2*y**3 | −2.926871E−13 |
| x**0*y**5 | 6.179438E−12 |
| x**6*y**0 | 1.044993E−17 |
| x**4*y**2 | −4.786755E−17 |
| x**2*y**4 | 8.203728E−16 |
| x**0*y**6 | −7.459193E−15 |
| x**6*y**1 | −1.654164E−19 |
| x**4*y**3 | 4.589039E−19 |
| x**2*y**5 | −3.124403E−18 |
| x**0*y**7 | −2.174835E−17 |
| x**8*y**0 | 2.009410E−23 |
| x**6*y**2 | 9.517659E−22 |
| x**4*y**4 | −5.179618E−21 |
| x**2*y**6 | 7.750352E−21 |
| x**0*y**8 | −8.792333E−19 |
| x**8*y**1 | 1.246556E−24 |
| x**6*y**3 | 2.104172E−23 |
| x**4*y**5 | 8.211077E−23 |
| x**2*y**7 | 7.179399E−22 |
| x**0*y**9 | 8.338199E−21 |
| x**10*y**0 | −2.325379E−27 |
| x**8*y**2 | −3.721663E−26 |
| x**6*y**4 | 3.240790E−26 |
| x**4*y**6 | −3.456950E−25 |
| x**2*y**8 | −7.961231E−24 |
| x**0*y**10 | 2.946257E−23 |
| x**10*y**1 | −1.704789E−29 |
| x**8*y**3 | −3.910165E−28 |
| x**6*y**5 | −2.073628E−27 |
| x**4*y**7 | −1.670652E−27 |
| x**2*y**9 | −2.114617E−26 |
| x**0*y**11 | −5.125942E−25 |
| x**12*y**0 | 2.029827E−32 |
| x**10*y**2 | 4.303822E−31 |
| x**8*y**4 | −1.103095E−31 |
| x**6*y**6 | −2.643930E−30 |
| x**4*y**8 | 4.267756E−29 |
| x**2*y**10 | 5.511728E−28 |
| x**0*y**12 | 6.117038E−28 |
| x**12*y**1 | 8.072233E−35 |
| x**10*y**3 | 3.141924E−33 |
| x**8*y**5 | 2.896681E−32 |
| x**6*y**7 | 8.636792E−32 |
| x**4*y**9 | −1.876794E−31 |
| x**2*y**11 | −8.354879E−31 |
| x**0*y**13 | 8.805651E−30 |
| x**14*y**0 | −1.367215E−37 |
| x**12*y**2 | −2.361088E−36 |
| x**10*y**4 | −4.611223E−36 |
| x**8*y**6 | 2.715979E−35 |
| x**6*y**8 | −1.115620E−34 |
| x**4*y**10 | −1.015090E−33 |
| x**2*y**12 | −1.151843E−32 |
| x**0*y**14 | −2.630242E−32 |
| x**14*y**1 | 7.181781E−40 |
| x**12*y**3 | −5.448361E−39 |
| x**10*y**5 | −1.206963E−37 |
| x**8*y**7 | −6.486602E−37 |
| x**6*y**9 | −3.899697E−37 |
| x**4*y**11 | 6.418806E−36 |
| x**2*y**13 | 3.676821E−35 |
| x**0*y**15 | 3.785422E−36 |
| M3 | |
| RDX | −130720.57574 |
| RDY | 11912.418164 |
| CCX | 0 |
| CCY | 0 |
| x**2*y**1 | −3.504506E−08 |
| x**0*y**3 | −1.109590E−07 |
| x**4*y**0 | 4.396374E−11 |
| x**2*y**2 | 2.259736E−11 |
| x**0*y**4 | 4.103165E−10 |
| x**4*y**1 | −6.839654E−14 |
| x**2*y**3 | 4.260238E−13 |
| x**0*y**5 | −1.324630E−12 |
| x**6*y**0 | −2.243496E−17 |
| x**4*y**2 | 4.174250E−16 |
| x**2*y**4 | −1.805562E−15 |
| x**0*y**6 | 5.028429E−15 |
| x**6*y**1 | 1.620735E−19 |
| x**4*y**3 | −1.662485E−18 |
| x**2*y**5 | 9.602751E−18 |
| x**0*y**7 | −2.224717E−17 |
| x**8*y**0 | 6.810086E−22 |
| x**6*y**2 | −1.605404E−21 |
| x**4*y**4 | 9.313506E−21 |
| x**2*y**6 | −4.872769E−20 |
| x**0*y**8 | 1.072180E−19 |
| x**8*y**1 | −1.041808E−24 |
| x**6*y**3 | 5.437404E−25 |
| x**4*y**5 | −1.188513E−22 |
| x**2*y**7 | 7.132885E−23 |
| x**0*y**9 | −1.269963E−22 |
| x**10*y**0 | −9.141100E−27 |
| x**8*y**2 | 3.225713E−26 |
| x**6*y**4 | −6.207534E−27 |
| x**4*y**6 | 4.923691E−25 |
| x**2*y**8 | 1.559757E−26 |
| x**0*y**10 | −4.861913E−25 |
| x**10*y**1 | 1.285491E−30 |
| x**8*y**3 | 1.404158E−29 |
| x**6*y**5 | 1.712942E−27 |
| x**4*y**7 | 5.200124E−27 |
| x**2*y**9 | 1.416522E−26 |
| x**0*y**11 | −2.957575E−26 |
| x**12*y**0 | 6.658353E−32 |
| x**10*y**2 | −3.158224E−31 |
| x**8*y**4 | −5.521935E−31 |
| x**6*y**6 | −3.881782E−30 |
| x**4*y**8 | −1.247349E−29 |
| x**2*y**10 | −7.519078E−29 |
| x**0*y**12 | 7.335453E−29 |
| x**12*y**1 | 5.258203E−35 |
| x**10*y**3 | 2.754225E−34 |
| x**8*y**5 | −1.374143E−32 |
| x**6*y**7 | −1.090129E−31 |
| x**4*y**9 | −3.244240E−31 |
| x**2*y**11 | −2.712712E−31 |
| x**0*y**13 | 1.440292E−30 |
| x**14*y**0 | −7.292945E−38 |
| x**12*y**2 | 1.643766E−36 |
| x**10*y**4 | 4.479440E−36 |
| x**8*y**6 | 2.112553E−35 |
| x**6*y**8 | 7.035760E−35 |
| x**4*y**10 | 8.790724E−34 |
| x**2*y**12 | 7.997805E−35 |
| x**0*y**14 | 2.094617E−34 |
| x**14*y**1 | −1.161816E−39 |
| x**12*y**3 | −3.438777E−39 |
| x**10*y**5 | 2.471990E−38 |
| x**8*y**7 | 5.762160E−37 |
| x**6*y**9 | 2.847568E−36 |
| x**4*y**11 | 2.464492E−36 |
| x**2*y**13 | 1.145485E−35 |
| x**0*y**15 | −3.843826E−35 |
| M4 | |
| RDX | −3996.623626 |
| RDY | −864.408712 |
| CCX | 0 |
| CCY | 0 |
| x**2*y**1 | 1.393941E−08 |
| x**0*y**3 | 6.663533E−07 |
| x**4*y**0 | 9.321792E−12 |
| x**2*y**2 | −5.883791E−10 |
| x**0*y**4 | −1.138792E−08 |
| x**4*y**1 | −3.985747E−14 |
| x**2*y**3 | 6.752366E−12 |
| x**0*y**5 | 2.290344E−10 |
| x**6*y**0 | −5.736139E−18 |
| x**4*y**2 | 7.245523E−16 |
| x**2*y**4 | −7.839676E−14 |
| x**0*y**6 | −2.890630E−12 |
| x**6*y**1 | 9.123364E−20 |
| x**4*y**3 | −1.903578E−17 |
| x**2*y**5 | 5.769169E−16 |
| x**0*y**7 | −2.086663E−14 |
| x**8*y**0 | −7.299994E−23 |
| x**6*y**2 | −8.568825E−22 |
| x**4*y**4 | 3.378575E−19 |
| x**2*y**6 | −5.465077E−17 |
| x**0*y**8 | −1.447868E−15 |
| x**8*y**1 | 2.988697E−25 |
| x**6*y**3 | 4.268082E−23 |
| x**4*y**5 | −2.911220E−21 |
| x**2*y**7 | 4.234066E−18 |
| x**0*y**9 | 2.413356E−16 |
| x**10*y**0 | 9.813823E−28 |
| x**8*y**2 | −6.417005E−26 |
| x**6*y**4 | −3.315948E−24 |
| x**4*y**6 | 2.502348E−22 |
| x**2*y**8 | 2.044081E−19 |
| x**0*y**10 | −4.315803E−18 |
| x**10*y**1 | 1.683664E−31 |
| x**8*y**3 | 1.107841E−27 |
| x**6*y**5 | 4.129095E−26 |
| x**4*y**7 | −5.213475E−23 |
| x**2*y**9 | −9.932083E−21 |
| x**0*y**11 | −8.731481E−19 |
| x**12*y**0 | −4.983105E−33 |
| x**10*y**2 | 7.946143E−31 |
| x**8*y**4 | 7.758564E−29 |
| x**6*y**6 | −1.725277E−26 |
| x**4*y**8 | 3.609249E−24 |
| x**2*y**10 | −8.809821E−22 |
| x**0*y**12 | 3.531461E−20 |
| x**12*y**1 | −2.274202E−35 |
| x**10*y**3 | −2.338748E−32 |
| x**8*y**5 | 2.876409E−30 |
| x**6*y**7 | −1.079240E−27 |
| x**4*y**9 | 4.390541E−25 |
| x**2*y**11 | −3.868264E−23 |
| x**0*y**13 | 3.890779E−21 |
| x**14*y**0 | −3.505297E−39 |
| x**12*y**2 | −4.156107E−36 |
| x**10*y**4 | −8.439023E−34 |
| x**8*y**6 | 2.481846E−31 |
| x**6*y**8 | −7.582818E−29 |
| x**4*y**10 | 1.450101E−26 |
| x**2*y**12 | −1.358362E−24 |
| x**0*y**14 | 8.483961E−23 |
| x**14*y**1 | 4.105754E−40 |
| x**12*y**3 | 1.666210E−37 |
| x**10*y**5 | −1.785536E−35 |
| x**8*y**7 | 6.640052E−33 |
| x**6*y**9 | −1.828159E−30 |
| x**4*y**11 | 1.962449E−28 |
| x**2*y**13 | −2.031924E−26 |
| x**0*y**15 | 4.047319E−25 |
| M5 | |
| RDX | 21407.349223 |
| RDY | −12873.644088 |
| CCX | 0 |
| CCY | 0 |
| x**2*y**1 | 2.815444E−08 |
| x**0*y**3 | −9.386271E−09 |
| x**4*y**0 | −1.208753E−10 |
| x**2*y**2 | 6.663307E−11 |
| x**0*y**4 | 1.660554E−11 |
| x**4*y**1 | 6.871261E−14 |
| x**2*y**3 | −8.111599E−14 |
| x**0*y**5 | −4.629842E−14 |
| x**6*y**0 | −9.798528E−17 |
| x**4*y**2 | 1.798306E−16 |
| x**2*y**4 | 3.259047E−16 |
| x**0*y**6 | 6.653905E−17 |
| x**6*y**1 | 3.223692E−19 |
| x**4*y**3 | 3.551242E−19 |
| x**2*y**5 | −4.719340E−19 |
| x**0*y**7 | −4.313088E−19 |
| x**8*y**0 | 1.887920E−21 |
| x**6*y**2 | 1.598865E−22 |
| x**4*y**4 | 1.872627E−22 |
| x**2*y**6 | 2.519107E−21 |
| x**0*y**8 | 1.403922E−21 |
| x**8*y**1 | −5.656182E−24 |
| x**6*y**3 | −8.155962E−24 |
| x**4*y**5 | −1.442335E−23 |
| x**2*y**7 | 4.194793E−24 |
| x**0*y**9 | 2.170055E−23 |
| x**10*y**0 | −1.634814E−26 |
| x**8*y**2 | −1.417806E−26 |
| x**6*y**4 | 3.371331E−26 |
| x**4*y**6 | 6.748407E−26 |
| x**2*y**8 | −1.505204E−25 |
| x**0*y**10 | −5.376905E−26 |
| x**10*y**1 | 8.748621E−29 |
| x**8*y**3 | 3.455882E−28 |
| x**6*y**5 | 3.771204E−28 |
| x**4*y**7 | 3.199118E−28 |
| x**2*y**9 | −4.493191E−28 |
| x**0*y**11 | −6.997161E−28 |
| x**12*y**0 | −3.625801E−32 |
| x**10*y**2 | 1.433199E−31 |
| x**8*y**4 | −7.195875E−31 |
| x**6*y**6 | −3.662208E−30 |
| x**4*y**8 | 8.267670E−31 |
| x**2*y**10 | 7.446525E−30 |
| x**0*y**12 | 1.948039E−30 |
| x**12*y**1 | −1.376095E−33 |
| x**10*y**3 | −5.908394E−33 |
| x**8*y**5 | −1.432476E−33 |
| x**6*y**7 | −5.476005E−33 |
| x**4*y**9 | −3.324862E−33 |
| x**2*y**11 | −2.789725E−33 |
| x**0*y**13 | 9.513929E−33 |
| x**14*y**0 | 1.907951E−36 |
| x**12*y**2 | −4.723787E−37 |
| x**10*y**4 | 6.753879E−36 |
| x**8*y**6 | 5.400736E−35 |
| x**6*y**8 | 4.215158E−35 |
| x**4*y**10 | −4.779846E−35 |
| x**2*y**12 | −1.323329E−34 |
| x**0*y**14 | −2.575066E−35 |
| x**14*y**1 | 8.972764E−39 |
| x**12*y**3 | 4.013209E−38 |
| x**10*y**5 | −4.359824E−38 |
| x**8*y**7 | −9.636736E−38 |
| x**6*y**9 | −6.342059E−38 |
| x**4*y**11 | 2.015648E−37 |
| x**2*y**13 | 2.653444E−37 |
| x**0*y**15 | −1.340603E−38 |
| M6 | |
| RDX | −5857.308288 |
| RDY | 6781.540094 |
| CCX | 0 |
| CCY | 0 |
| x**2*y**1 | −5.987404E−08 |
| x**0*y**3 | −3.080395E−07 |
| x**4*y**0 | 1.095814E−10 |
| x**2*y**2 | −6.438697E−11 |
| x**0*y**4 | 6.807974E−10 |
| x**4*y**1 | −1.361438E−13 |
| x**2*y**3 | −2.808850E−13 |
| x**0*y**5 | −2.730023E−12 |
| x**6*y**0 | 7.099960E−17 |
| x**4*y**2 | −7.776862E−16 |
| x**2*y**4 | 3.906430E−16 |
| x**0*y**6 | 1.075761E−14 |
| x**6*y**1 | −4.794319E−19 |
| x**4*y**3 | −1.450837E−18 |
| x**2*y**5 | −4.070212E−18 |
| x**0*y**7 | −4.179254E−17 |
| x**8*y**0 | −1.201376E−21 |
| x**6*y**2 | −3.796957E−21 |
| x**4*y**4 | −5.877280E−21 |
| x**2*y**6 | −1.707683E−20 |
| x**0*y**8 | 1.945889E−19 |
| x**8*y**1 | 9.234450E−24 |
| x**6*y**3 | 2.066008E−23 |
| x**4*y**5 | 9.295828E−23 |
| x**2*y**7 | −1.266196E−22 |
| x**0*y**9 | −4.012301E−21 |
| x**10*y**0 | 4.470752E−28 |
| x**8*y**2 | 6.909233E−26 |
| x**6*y**4 | 1.323181E−25 |
| x**4*y**6 | 3.904273E−25 |
| x**2*y**8 | 6.202481E−24 |
| x**0*y**10 | 2.629529E−23 |
| x**10*y**1 | −1.418620E−28 |
| x**8*y**3 | −5.667802E−28 |
| x**6*y**5 | −3.445787E−27 |
| x**4*y**7 | −8.039749E−27 |
| x**2*y**9 | −4.130868E−27 |
| x**0*y**11 | 1.572565E−25 |
| x**12*y**0 | 2.503855E−31 |
| x**10*y**2 | −8.519779E−31 |
| x**8*y**4 | −5.246375E−30 |
| x**6*y**6 | 7.917437E−30 |
| x**4*y**8 | −1.218878E−28 |
| x**2*y**10 | −5.753031E−28 |
| x**0*y**12 | −1.845835E−27 |
| x**12*y**1 | 2.005056E−33 |
| x**10*y**3 | 4.974733E−33 |
| x**8*y**5 | 2.207878E−32 |
| x**6*y**7 | 1.837995E−31 |
| x**4*y**9 | 6.058331E−31 |
| x**2*y**11 | 1.874757E−30 |
| x**0*y**13 | −7.305970E−30 |
| x**14*y**0 | −3.246867E−36 |
| x**12*y**2 | 2.333889E−36 |
| x**10*y**4 | 5.653276E−35 |
| x**8*y**6 | −1.549161E−34 |
| x**6*y**8 | −4.660729E−35 |
| x**4*y**10 | 5.771682E−33 |
| x**2*y**12 | 2.589420E−32 |
| x**0*y**14 | 1.148787E−31 |
| x**14*y**1 | −1.151414E−38 |
| x**12*y**3 | −2.443551E−38 |
| x**10*y**5 | 3.431877E−37 |
| x**8*y**7 | 9.664019E−37 |
| x**6*y**9 | −2.141205E−36 |
| x**4*y**11 | −2.892628E−35 |
| x**2*y**13 | −1.375454E−34 |
| x**0*y**15 | −2.854443E−34 |
| M7 | |
| RDX | 3333.850665 |
| RDY | 363.969324 |
| CCX | 0 |
| CCY | 0 |
| x**2*y**1 | 4.382777E−07 |
| x**0*y**3 | 7.798747E−06 |
| x**4*y**0 | 2.342442E−10 |
| x**2*y**2 | 6.344771E−09 |
| x**0*y**4 | 4.952348E−08 |
| x**4*y**1 | 1.624993E−12 |
| x**2*y**3 | 5.534816E−11 |
| x**0*y**5 | 3.844247E−10 |
| x**6*y**0 | 4.540587E−16 |
| x**4*y**2 | 2.823436E−14 |
| x**2*y**4 | 5.704802E−13 |
| x**0*y**6 | 2.091225E−12 |
| x**6*y**1 | 6.151555E−18 |
| x**4*y**3 | 3.664583E−16 |
| x**2*y**5 | 5.185459E−15 |
| x**0*y**7 | −1.207016E−14 |
| x**8*y**0 | 1.306301E−21 |
| x**6*y**2 | 1.565391E−19 |
| x**4*y**4 | 4.604477E−18 |
| x**2*y**6 | 1.250647E−17 |
| x**0*y**8 | −9.375152E−16 |
| x**8*y**1 | 1.157606E−23 |
| x**6*y**3 | 1.767429E−21 |
| x**4*y**5 | 1.268368E−20 |
| x**2*y**7 | −1.316620E−18 |
| x**0*y**9 | −3.318991E−17 |
| x**10*y**0 | 4.189743E−27 |
| x**8*y**2 | −8.887754E−25 |
| x**6*y**4 | −1.208333E−23 |
| x**4*y**6 | −1.424656E−22 |
| x**2*y**8 | −3.765495E−20 |
| x**0*y**10 | −8.887032E−19 |
| x**10*y**1 | 3.162136E−28 |
| x**8*y**3 | 1.501537E−26 |
| x**6*y**5 | 1.179639E−24 |
| x**4*y**7 | 3.054847E−23 |
| x**2*y**9 | −9.424103E−22 |
| x**0*y**11 | −1.829740E−20 |
| x**12*y**0 | −9.486955E−32 |
| x**10*y**2 | 4.759173E−29 |
| x**8*y**4 | 2.418404E−27 |
| x**6*y**6 | 4.584116E−26 |
| x**4*y**8 | −6.421922E−25 |
| x**2*y**10 | −3.949413E−23 |
| x**0*y**12 | −3.100345E−22 |
| x**12*y**1 | −7.007218E−34 |
| x**10*y**3 | 4.078300E−31 |
| x**8*y**5 | 1.081748E−29 |
| x**6*y**7 | −1.501275E−27 |
| x**4*y**9 | −7.815036E−26 |
| x**2*y**11 | −1.115903E−24 |
| x**0*y**13 | −4.030494E−24 |
| x**14*y**0 | 1.545298E−36 |
| x**12*y**2 | −4.722933E−34 |
| x**10*y**4 | −3.493306E−32 |
| x**8*y**6 | −1.555520E−30 |
| x**6*y**8 | −6.812617E−29 |
| x**4*y**10 | −1.630151E−27 |
| x**2*y**12 | −1.500622E−26 |
| x**0*y**14 | −3.225898E−26 |
| x**14*y**1 | −1.649094E−38 |
| x**12*y**3 | −7.636317E−36 |
| x**10*y**5 | −6.002348E−34 |
| x**8*y**7 | −2.216021E−32 |
| x**6*y**9 | −6.339111E−31 |
| x**4*y**11 | −1.063992E−29 |
| x**2*y**13 | −7.604930E−29 |
| x**0*y**15 | −1.110998E−28 |
| M8 | |
| RDX | −1006.784809 |
| RDY | −589.178151 |
| CCX | 0 |
| CCY | 0 |
| x**2*y**1 | −2.801200E−08 |
| x**0*y**3 | −7.213070E−08 |
| x**4*y**0 | −7.914956E−11 |
| x**2*y**2 | −2.067568E−10 |
| x**0*y**4 | −1.458374E−11 |
| x**4*y**1 | −3.534338E−14 |
| x**2*y**3 | −1.554700E−13 |
| x**0*y**5 | −2.006214E−13 |
| x**6*y**0 | −1.122240E−16 |
| x**4*y**2 | −5.741110E−16 |
| x**2*y**4 | −7.062086E−16 |
| x**0*y**6 | −4.184801E−17 |
| x**6*y**1 | −6.869228E−20 |
| x**4*y**3 | −3.480489E−19 |
| x**2*y**5 | −7.041259E−19 |
| x**0*y**7 | −2.086212E−19 |
| x**8*y**0 | −1.711354E−22 |
| x**6*y**2 | −1.251584E−21 |
| x**4*y**4 | −2.621032E−21 |
| x**2*y**6 | −2.098770E−21 |
| x**0*y**8 | 4.745233E−21 |
| x**8*y**1 | 1.092872E−24 |
| x**6*y**3 | 2.088437E−24 |
| x**4*y**5 | 2.063307E−24 |
| x**2*y**7 | 1.363157E−24 |
| x**0*y**9 | 3.374262E−24 |
| x**10*y**0 | −1.719114E−28 |
| x**8*y**2 | 2.778519E−27 |
| x**6*y**4 | −3.963836E−27 |
| x**4*y**6 | −1.599098E−26 |
| x**2*y**8 | 1.064921E−26 |
| x**0*y**10 | −4.100983E−26 |
| x**10*y**1 | −3.385441E−29 |
| x**8*y**3 | −1.235529E−28 |
| x**6*y**5 | −2.258265E−28 |
| x**4*y**7 | −2.627752E−28 |
| x**2*y**9 | 2.516814E−29 |
| x**0*y**11 | 4.003434E−28 |
| x**12*y**0 | 2.444003E−33 |
| x**10*y**2 | −1.108703E−31 |
| x**8*y**4 | −2.143734E−31 |
| x**6*y**6 | 1.888292E−32 |
| x**4*y**8 | 2.599661E−31 |
| x**2*y**10 | −1.773508E−31 |
| x**0*y**12 | 6.259595E−31 |
| x**12*y**1 | 5.264778E−34 |
| x**10*y**3 | 5.264778E−34 |
| x**8*y**5 | 2.654339E−33 |
| x**6*y**7 | 6.129724E−33 |
| x**4*y**9 | 8.255049E−33 |
| x**2*y**11 | 7.737604E−33 |
| x**0*y**13 | −1.102294E−33 |
| x**14*y**0 | −1.129348E−32 |
| x**12*y**2 | −3.307168E−38 |
| x**10*y**4 | 8.381159E−37 |
| x**8*y**6 | 2.903885E−36 |
| x**6*y**8 | 1.696342E−36 |
| x**4*y**10 | −1.807185E−36 |
| x**2*y**12 | −2.521238E−36 |
| x**0*y**14 | 5.435613E−36 |
| x**14*y**1 | 5.017989E−36 |
| x**12*y**3 | −3.280846E−39 |
| x**10*y**5 | −2.152451E−38 |
| x**8*y**7 | −6.388841E−38 |
| x**6*y**9 | −1.009875E−37 |
| x**4*y**11 | −1.104647E−37 |
| x**2*y**13 | −7.992530E−38 |
| x**0*y**15 | 3.062602E−38 |
| x**0*y**15 | 1.239634E−37 |

Table 5 for FIG. 10

| Mirrors | Reflectivity [%] |
|---|---|
| M1 | 65.6 |
| M2 | 83.6 |
| M3 | 88.8 |
| M4 | 64.3 |
| M5 | 90.7 |
| M6 | 84.0 |
| M7 | 65.1 |
| M8 | 67.2 |
| Overall transmission | 10.4 |

Table 6 for FIG. 10

| x [mm] | y [mm] |
|---|---|
| −160.36675 | 9.33103589 |
| −136.00417 | 20.3547194 |
| −98.501041 | 28.7812213 |
| −51.66331 | 34.2063377 |
| 0 | 36.1177983 |
| 51.6633105 | 34.2063377 |
| 98.5010406 | 28.7812213 |
| 136.004167 | 20.3547194 |
| 160.366753 | 9.33103589 |
| 168.953026 | −3.757828 |
| 160.742355 | −18.019322 |
| 136.569772 | −32.095816 |
| 99.0142281 | −44.210865 |
| 51.953903 | −52.482642 |

Without giving consideration to the polishing overrun edge yet again, the projection optical unit 27 has an overall mirror surface of 0.76 m². When the polishing overrun edge is taken into account, the overall mirror surface is 0.97 m².

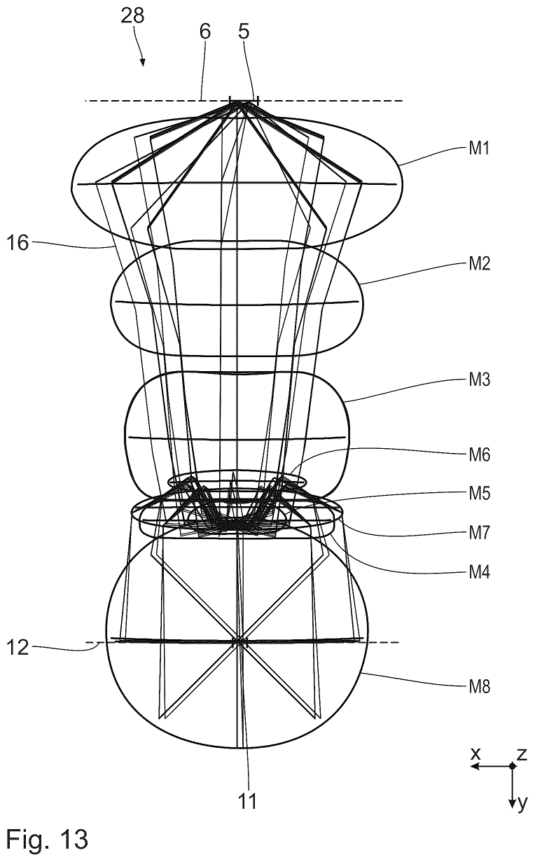

FIGS. 12 and 13 show a further embodiment of a projection optical unit or imaging optical unit 28, which can be used in the projection exposure apparatus 1 instead of the projection optical unit 10 of the embodiment according to FIG. 2. Components and functions corresponding to those which have already been explained above in conjunction with FIGS. 1 to 11, and in particular in conjunction with FIGS. 1 to 3, are denoted by the same reference signs and are not discussed in detail again.

In terms of basic structure, the projection optical unit 28 according to FIGS. 12 and 13 is similar to the projection optical unit 27 according to FIG. 10. A difference is that an intermediate image is also present in the plane perpendicular to the meridional plane in the projection optical unit 28, as may be gathered from the view according to FIG. 13. The intermediate image ZB is located in the imaging beam path between the mirrors M4 and M5, both in the meridional plane according to FIG. 12 and in the plane perpendicular thereto.

The projection optical unit 28 is telecentric on the object side. Once again, an exit pupil is located in the region of the reflection of the imaging beam path in the vicinity of the mirror M7. An aperture stop and optionally, an obscuration stop as well can be attached there and in the imaging beam path between the mirrors M7 and M8, once again in portions. What was explained above in relation to the projection optical unit 10 applies here accordingly.

A distance between the object plane 6 and the image plane 12 is 2151 mm in the case of the projection optical unit 28.

The following tables summarize parameters and the optical design of the projection optical unit 28. In terms of their structure, these tables correspond to those already explained above in conjunction with FIG. 2.

Table 1 for FIG. 12

| Wavelength | 13.5 | nm |
|---|---|---|
| Image-side numerical aperture | 0.33 | |
| Image field size in the x- and y- | 52 mm x 1.7 mm | |
| directions | | |
| βₓ | 2.00 (with intermediate image) | |
| β_{y} | 4.00 (with intermediate image) | |
| Chief ray angle | 6° | |
| Étendue | 9.63 | mm |
| Mean wavefront aberration RMS | 20 | mλ |
| Overall transmission | 10.4% | |
| Position of the entrance pupil (x) | 572 | mm |
| Position of the entrance pupil (y) | 1992 | mm |
| Object-image offset in the y-direction | 959 | mm |
| Distance between M7 and image plane | 74 | mm |
| Distance between the object plane and | 2151 | mm |

| | |
|---|---|
| image plane | |
| Tilt between the object and | 0.0° |
| Image plane | |
| Installation space cuboid | (601 × 1155 × 1780) mm |

Table 2a for FIG. 12

| | M1 | M2 | M3 | M4 |
|---|---|---|---|---|
| Maximum angle of incidence [°] | 15.6 | 82.1 | 83.2 | 18.2 |
| Minimum angle of incidence [°] | 12.8 | 71.8 | 79.2 | 13.5 |
| Extent of the reflection surface | 600.0 | 455.0 | 404.1 | 352.0 |
| in the x-direction [mm] | | | | |
| Extent of the reflection surface | 242.4 | 367.8 | 364.1 | 67.4 |
| in the y-direction [mm] | | | | |
| Maximum mirror diameter [mm] | 600.0 | 458.8 | 458.1 | 352.0 |

Table 2b for FIG. 12

| | M5 | M6 | M7 | M8 |
|---|---|---|---|---|
| Maximum angle of incidence [°] | 85.3 | 82.4 | 23.2 | 15.4 |
| Minimum angle of incidence [°] | 80.1 | 78.6 | 4.3 | 10.1 |
| Extent of the reflection surface | 175.2 | 247.6 | 384.8 | 475.0 |
| in the x-direction [mm] | | | | |
| Extent of the reflection surface | 470.4 | 447.9 | 76.5 | 428.5 |
| in the y-direction [mm] | | | | |
| Maximum mirror diameter [mm] | 624.7 | 505.0 | 385.2 | 476.2 |

Table 3a for FIG. 12

| | x-distance [mm] | y-distance [mm] | z-distance [mm] |
|---|---|---|---|
| Object field | 0 | 961.96 | 2150.90 |
| M1 | 0 | 819.11 | 807.68 |
| M2 | 0 | 600.30 | 1378.62 |
| M3 | 0 | 359.46 | 1597.25 |
| M4 | 0 | 214.74 | 1846.97 |
| M5 | 0 | 209.98 | 1001.58 |
| M6 | 0 | 286.08 | 701.63 |
| Stop (AS) | 0 | 239.06 | 83.98 |
| M7 | 0 | 234.18 | 94.86 |
| M8 | 0 | 0.00 | 617.81 |
| Image field | 0 | 0.00 | 0.00 |

Table 3b for FIG. 12

| | Tilt about the x- | Tilt about the y- | Tilt about the z- |
|---|---|---|---|
| | axis [degrees] | axis [degrees] | axis [degrees] |
| Object field | −0.07 | 0 | 0 |
| M1 | 7.45 | 180 | 0 |
| M2 | −55.63 | 0 | 0 |
| M3 | −51.07 | 180 | 0 |
| M4 | 14.89 | 0 | 0 |
| M5 | −83.04 | 180 | 0 |
| M6 | −85.06 | 0 | 0 |
| Stop (AS) | 9.89 | 180 | 0 |
| M7 | 15.68 | 180 | 0 |
| M8 | 12.06 | 0 | 0 |
| Image field | 0.00 | 0 | 0 |

Table 4 for FIG. 12

| x**i * y**j | Coefficient |
|---|---|
| M1 | |
| RDX | −1537.338442 |
| RDY | −1155.825797 |
| CCX | 0 |
| CCY | 0 |
| x**2*y**1 | −7.729738E−08 |
| x**0*y**3 | −2.604637E−07 |
| x**4*y**0 | 2.083150E−11 |
| x**2*y**2 | 1.540367E−10 |
| x**0*y**4 | −4.227151E−10 |
| x**4*y**1 | 3.991524E−14 |
| x**2*y**3 | 1.421117E−13 |
| x**0*y**5 | 3.047896E−13 |
| x**6*y**0 | −2.392581E−17 |
| x**4*y**2 | 2.139460E−16 |
| x**2*y**4 | 1.046728E−15 |
| x**0*y**6 | −2.919704E−15 |
| x**6*y**1 | −2.893848E−20 |
| x**4*y**3 | −3.530648E−19 |
| x**2*y**5 | 5.031187E−18 |
| x**0*y**7 | −8.921434E−18 |
| x**8*y**0 | 6.235233E−23 |
| x**6*y**2 | −6.899316E−22 |
| x**4*y**4 | −9.175928E−21 |
| x**2*y**6 | −1.554346E−20 |
| x**0*y**8 | −1.030159E−20 |
| x**8*y**1 | −3.827357E−25 |
| x**6*y**3 | −7.873774E−24 |
| x**4*y**5 | −3.997948E−23 |
| x**2*y**7 | 1.229909E−22 |
| x**0*y**9 | 2.115659E−22 |
| x**10*y**0 | 5.051836E−29 |
| x**8*y**2 | 1.318889E−26 |
| x**6*y**4 | 1.706616E−25 |
| x**4*y**6 | 4.020006E−25 |
| x**2*y**8 | 2.580852E−24 |
| x**0*y**10 | −2.141520E−24 |
| x**10*y**1 | 8.300530E−30 |
| x**8*y**3 | 1.409137E−28 |
| x**6*y**5 | 1.022194E−27 |
| x**4*y**7 | 1.450077E−27 |
| x**2*y**9 | −9.769463E−27 |
| x**0*y**11 | −1.214049E−26 |
| x**12*y**0 | −9.271602E−34 |
| x**10*y**2 | −1.511423E−31 |
| x**8*y**4 | −2.367457E−30 |
| x**6*y**6 | −1.041674E−29 |
| x**4*y**8 | −2.278732E−29 |
| x**2*y**10 | −8.737288E−29 |
| x**0*y**12 | 7.997058E−29 |
| x**12*y**1 | −3.638828E−35 |
| x**10*y**3 | −8.295628E−34 |
| x**8*y**5 | −1.062285E−32 |
| x**6*y**7 | −5.982153E−32 |
| x**4*y**9 | −1.882962E−32 |
| x**2*y**11 | 5.499058E−31 |
| x**0*y**13 | 4.489702E−31 |
| x**14*y**0 | 3.033230E−39 |
| x**12*y**2 | 6.880797E−37 |
| x**10*y**4 | 1.244633E−35 |
| x**8*y**6 | 7.882715E−35 |
| x**6*y**8 | 2.307120E−34 |
| x**4*y**10 | 1.658278E−34 |
| x**2*y**12 | 1.732798E−33 |
| x**0*y**14 | −1.372766E−33 |
| x**14*y**1 | −1.461035E−40 |
| x**12*y**3 | −5.705223E−40 |
| x**10*y**5 | 2.417750E−38 |
| x**8*y**7 | 3.311914E−37 |
| x**6*y**9 | 1.296482E−36 |
| x**4*y**11 | −2.758881E−36 |
| x**2*y**13 | −1.017663E−35 |
| x**0*y**15 | −1.410438E−35 |
| M2 | |
| RDX | 3396.248101 |
| RDY | 4815.067225 |
| CCX | 0 |
| CCY | 0 |
| x**2*y**1 | 2.118196E−07 |
| x**0*y**3 | 1.476627E−07 |
| x**4*y**0 | 3.659911E−10 |
| x**2*y**2 | 2.279301E−10 |
| x**0*y**4 | −5.904293E−11 |
| x**4*y**1 | 4.537811E−13 |
| x**2*y**3 | 5.646069E−13 |
| x**0*y**5 | −6.199162E−13 |
| x**6*y**0 | −1.940105E−17 |
| x**4*y**2 | −6.757222E−16 |
| x**2*y**4 | −2.029438E−15 |
| x**0*y**6 | −9.669867E−17 |
| x**6*y**1 | −1.931626E−18 |
| x**4*y**3 | −3.211592E−18 |
| x**2*y**5 | 1.444479E−18 |
| x**0*y**7 | −3.172017E−18 |
| x**8*y**0 | −8.084393E−22 |
| x**6*y**2 | 4.423529E−21 |
| x**4*y**4 | 1.131750E−20 |
| x**2*y**6 | 1.251811E−20 |
| x**0*y**8 | 1.244029E−20 |
| x**8*y**1 | 1.435357E−23 |
| x**6*y**3 | 6.409927E−23 |
| x**4*y**5 | 2.240521E−23 |
| x**2*y**7 | 2.098708E−23 |
| x**0*y**9 | 2.771397E−23 |
| x**10*y**0 | −5.957370E−27 |
| x**8*y**2 | −1.169501E−25 |
| x**6*y**4 | −5.325966E−25 |
| x**4*y**6 | −4.804722E−25 |
| x**2*y**8 | −5.354670E−25 |
| x**0*y**10 | 1.690956E−25 |
| x**10*y**1 | −4.577651E−28 |
| x**8*y**3 | −1.747339E−27 |
| x**6*y**5 | −7.269702E−28 |
| x**4*y**7 | −2.003809E−27 |
| x**2*y**9 | 1.567073E−27 |
| x**0*y**11 | −1.102872E−27 |
| x**12*y**0 | −2.348025E−31 |
| x**10*y**2 | 3.199094E−30 |
| x**8*y**4 | 1.417695E−29 |
| x**6*y**6 | 1.067071E−29 |
| x**4*y**8 | 1.396296E−29 |
| x**2*y**10 | 1.843229E−30 |
| x**0*y**12 | −3.449634E−30 |
| x**12*y**1 | 5.233350E−33 |
| x**10*y**3 | 2.235342E−32 |
| x**8*y**5 | 9.532797E−33 |
| x**6*y**7 | 2.489436E−32 |
| x**4*y**9 | 1.863241E−32 |
| x**2*y**11 | −7.606126E−33 |
| x**0*y**13 | 1.290931E−32 |
| x**14*y**0 | 3.350796E−36 |
| x**12*y**2 | −3.137280E−35 |
| x**10*y**4 | −1.374831E−34 |
| x**8*y**6 | −1.441210E−34 |
| x**6*y**8 | −9.226409E−35 |
| x**4*y**10 | −6.823853E−35 |
| x**2*y**12 | −2.023992E−35 |
| x**0*y**14 | 6.336739E−35 |
| x**14*y**1 | 1.729306E−39 |
| x**12*y**3 | −3.086326E−38 |
| x**10*y**5 | −7.257760E−39 |
| x**8*y**7 | 1.016507E−37 |
| x**6*y**9 | −2.030102E−37 |
| x**4*y**11 | −2.276839E−37 |
| x**2*y**13 | 5.889045E−38 |
| x**0*y**15 | −2.052119E−37 |
| M3 | |
| RDX | −3643.13369 |
| RDY | 8633.988783 |
| CCX | 0 |
| CCY | 0 |
| x**2*y**1 | −3.196669E−08 |
| x**0*y**3 | −1.250163E−07 |
| x**4*y**0 | −2.529197E−10 |
| x**2*y**2 | 2.457823E−10 |
| x**0*y**4 | 2.923677E−10 |
| x**4*y**1 | −2.791965E−13 |
| x**2*y**3 | −9.039031E−13 |
| x**0*y**5 | −5.536890E−13 |
| x**6*y**0 | 2.030432E−16 |
| x**4*y**2 | 7.978385E−16 |
| x**2*y**4 | 2.744646E−15 |
| x**0*y**6 | 1.211870E−15 |
| x**6*y**1 | 1.883131E−18 |
| x**4*y**3 | −7.349282E−20 |
| x**2*y**5 | −7.297859E−18 |
| x**0*y**7 | −1.992179E−18 |
| x**8*y**0 | 5.940550E−22 |
| x**6*y**2 | −4.935799E−21 |
| x**4*y**4 | −1.729039E−20 |
| x**2*y**6 | 1.021441E−20 |
| x**0*y**8 | 1.599678E−21 |
| x**8*y**1 | −2.550279E−23 |
| x**6*y**3 | −8.733321E−23 |
| x**4*y**5 | 6.321353E−23 |
| x**2*y**7 | −8.831117E−24 |
| x**0*y**9 | 1.264860E−23 |
| x**10*y**0 | 7.460887E−27 |
| x**8*y**2 | 1.322554E−25 |
| x**6*y**4 | 1.333328E−24 |
| x**4*y**6 | 5.600132E−25 |
| x**2*y**8 | 2.484911E−25 |
| x**0*y**10 | −8.709758E−26 |
| x**10*y**1 | 1.009191E−27 |
| x**8*y**3 | 3.596692E−27 |
| x**6*y**5 | −4.050352E−27 |
| x**4*y**7 | −2.125663E−28 |
| x**2*y**9 | −1.337303E−27 |
| x**0*y**11 | 2.395318E−28 |
| x**12*y**0 | 1.183420E−30 |
| x**10*y**2 | −7.768783E−30 |
| x**8*y**4 | −4.621088E−29 |
| x**6*y**6 | −1.997781E−29 |
| x**4*y**8 | −1.402307E−29 |
| x**2*y**10 | 6.533307E−30 |
| x**0*y**12 | 1.033225E−30 |
| x**12*y**1 | −1.834929E−32 |
| x**10*y**3 | −4.124811E−32 |
| x**8*y**5 | 1.278055E−31 |
| x**6*y**7 | 5.066074E−32 |
| x**4*y**9 | 1.011261E−32 |
| x**2*y**11 | −2.324204E−32 |
| x**0*y**13 | −5.266234E−33 |
| x**14*y**0 | −1.791953E−35 |
| x**12*y**2 | 1.345132E−34 |
| x**10*y**4 | 6.241909E−34 |
| x**8*y**6 | 3.562715E−34 |
| x**6*y**8 | 2.240101E−34 |
| x**4*y**10 | −3.251554E−35 |
| x**2*y**12 | −3.386673E−35 |
| x**0*y**14 | −1.756091E−35 |
| x**14*y**1 | 3.136452E−38 |
| x**12*y**3 | −3.488981E−37 |
| x**10*y**5 | −1.666343E−36 |
| x**8*y**7 | −1.528813E−36 |
| x**6*y**9 | −3.220934E−37 |
| x**4*y**11 | 4.894354E−37 |
| x**2*y**13 | 2.238030E−37 |
| x**0*y**15 | 7.722539E−38 |
| M4 | |
| RDX | −3089.258857 |
| RDY | −1161.538842 |
| CCX | 0 |
| CCY | 0 |
| x**2*y**1 | 1.490722E−07 |
| x**0*y**3 | 1.532398E−06 |
| x**4*y**0 | 5.103593E−11 |
| x**2*y**2 | −1.911781E−09 |
| x**0*y**4 | −1.808921E−08 |
| x**4*y**1 | 6.897838E−13 |
| x**2*y**3 | 2.411451E−11 |
| x**0*y**5 | 1.811074E−10 |
| x**6*y**0 | −9.641744E−17 |
| x**4*y**2 | −9.239997E−15 |
| x**2*y**4 | −2.718636E−13 |
| x**0*y**6 | −1.583559E−12 |
| x**6*y**1 | 1.663633E−18 |
| x**4*y**3 | 1.164559E−16 |
| x**2*y**5 | 3.222634E−15 |
| x**0*y**7 | 1.837557E−14 |
| x**8*y**0 | −4.900293E−23 |
| x**6*y**2 | −5.889729E−20 |
| x**4*y**4 | 8.153941E−20 |
| x**2*y**6 | −1.112514E−17 |
| x**0*y**8 | 7.487684E−17 |
| x**8*y**1 | 1.629909E−23 |
| x**6*y**3 | 1.715282E−21 |
| x**4*y**5 | −6.259390E−20 |
| x**2*y**7 | −2.023772E−18 |
| x**0*y**9 | −8.597053E−18 |
| x**10*y**0 | 8.836592E−27 |
| x**8*y**2 | 1.947115E−24 |
| x**6*y**4 | −4.661043E−23 |
| x**4*y**6 | −7.135251E−22 |
| x**2*y**8 | −2.413996E−21 |
| x**0*y**10 | −1.945210E−19 |
| x**10*y**1 | −8.003066E−28 |
| x**8*y**3 | −1.330893E−25 |
| x**6*y**5 | 2.222173E−24 |
| x**4*y**7 | 7.205647E−23 |
| x**2*y**9 | 2.737405E−21 |
| x**0*y**11 | 5.637483E−22 |
| x**12*y**0 | −5.468960E−31 |
| x**10*y**2 | −3.073409E−29 |
| x**8*y**4 | 9.300718E−28 |
| x**6*y**6 | 4.461565E−26 |
| x**4*y**8 | −8.429630E−26 |
| x**2*y**10 | −5.358626E−24 |
| x**0*y**12 | 1.307883E−22 |
| x**12*y**1 | 3.495501E−33 |
| x**10*y**3 | 3.570217E−30 |
| x**8*y**5 | −2.645180E−29 |
| x**6*y**7 | −1.054975E−27 |
| x**4*y**9 | −5.611120E−26 |
| x**2*y**11 | −1.384637E−24 |
| x**0*y**13 | 4.195019E−24 |
| x**14*y**0 | 6.368733E−36 |
| x**12*y**2 | −2.323490E−34 |
| x**10*y**4 | −8.308254E−33 |
| x**8*y**6 | −8.266944E−31 |
| x**6*y**8 | −9.495560E−30 |
| x**4*y**10 | 2.862330E−28 |
| x**2*y**12 | −1.212557E−27 |
| x**0*y**14 | −2.719849E−26 |
| x**14*y**1 | 3.562606E−37 |
| x**12*y**3 | −2.063814E−35 |
| x**10*y**5 | 1.072064E−34 |
| x**8*y**7 | 5.820938E−33 |
| x**6*y**9 | 3.368203E−31 |
| x**4*y**11 | 1.576901E−29 |
| x**2*y**13 | 2.731033E−28 |
| x**0*y**15 | −1.685652E−27 |
| M5 | |
| RDX | 30213.384285 |
| RDY | −35382.026051 |
| CCX | 0 |
| CCY | 0 |
| x**2*y**1 | −1.892463E−07 |
| x**0*y**3 | −1.762648E−08 |
| x**4*y**0 | 4.173712E−10 |
| x**2*y**2 | 1.718578E−10 |
| x**0*y**4 | −3.330903E−12 |
| x**4*y**1 | −1.498337E−12 |
| x**2*y**3 | −3.845162E−13 |
| x**0*y**5 | −1.081438E−14 |
| x**6*y**0 | −1.156166E−15 |
| x**4*y**2 | 3.856179E−15 |
| x**2*y**4 | 6.948279E−16 |
| x**0*y**6 | −3.335968E−17 |
| x**6*y**1 | −7.776145E−18 |
| x**4*y**3 | −1.492134E−17 |
| x**2*y**5 | −1.254635E−18 |
| x**0*y**7 | −9.357921E−20 |
| x**8*y**0 | 7.099707E−19 |
| x**6*y**2 | −6.753746E−20 |
| x**4*y**4 | −1.822493E−20 |
| x**2*y**6 | −1.563358E−21 |
| x**0*y**8 | 3.049404E−21 |
| x**8*y**1 | −5.334402E−21 |
| x**6*y**3 | 3.280940E−21 |
| x**4*y**5 | 2.792803E−22 |
| x**2*y**7 | −7.370858E−23 |
| x**0*y**9 | −1.438500E−23 |
| x**10*y**0 | −1.584887E−22 |
| x**8*y**2 | 1.094413E−23 |
| x**6*y**4 | −1.150533E−24 |
| x**4*y**6 | 1.047986E−24 |
| x**2*y**8 | 1.871042E−25 |
| x**0*y**10 | −2.702386E−26 |
| x**10*y**1 | 1.905113E−24 |
| x**8*y**3 | −4.282575E−25 |
| x**6*y**5 | −1.899611E−25 |
| x**4*y**7 | 2.364037E−27 |
| x**2*y**9 | 3.549572E−27 |
| x**0*y**11 | 3.738026E−28 |
| x**12*y**0 | 1.703192E−26 |
| x**10*y**2 | −6.126240E−28 |
| x**8*y**4 | 3.464218E−28 |
| x**6*y**6 | 8.349475E−28 |
| x**4*y**8 | −9.339039E−29 |
| x**2*y**10 | −1.204664E−29 |
| x**0*y**12 | −7.729723E−31 |
| x**12*y**1 | −2.553750E−28 |
| x**10*y**3 | 1.236338E−29 |
| x**8*y**5 | 1.824091E−29 |
| x**6*y**7 | 2.135363E−31 |
| x**4*y**9 | 1.659378E−31 |
| x**2*y**11 | −5.577182E−32 |
| x**0*y**13 | −8.286955E−34 |
| x**14*y**0 | −6.824278E−31 |
| x**12*y**2 | −3.256082E−32 |
| x**10*y**4 | 3.190208E−32 |
| x**8*y**6 | −9.340921E−32 |
| x**6*y**8 | −6.365995E−33 |
| x**4*y**10 | 7.958444E−34 |
| x**2*y**12 | 3.206583E−34 |
| x**0*y**14 | 4.182201E−36 |
| x**14*y**1 | 1.189018E−32 |
| x**12*y**3 | 7.462182E−34 |
| x**10*y**5 | −4.698642E−34 |
| x**8*y**7 | 1.685843E−34 |
| x**6*y**9 | 6.436653E−36 |
| x**4*y**11 | −1.914763E−36 |
| x**2*y**13 | −4.136473E−37 |
| x**0*y**15 | −3.180652E−39 |
| M6 | |
| RDX | −2269.256456 |
| RDY | −12599.733760 |
| CCX | 0 |
| CCY | 0 |
| x**2*y**1 | 2.132032E−07 |
| x**0*y**3 | −1.130397E−08 |
| x**4*y**0 | −1.589615E−10 |
| x**2*y**2 | 9.729821E−12 |
| x**0*y**4 | 2.610494E−11 |
| x**4*y**1 | 1.021456E−12 |
| x**2*y**3 | 4.055923E−13 |
| x**0*y**5 | 2.055263E−14 |
| x**6*y**0 | −1.826232E−16 |
| x**4*y**2 | −3.919311E−16 |
| x**2*y**4 | 3.355324E−16 |
| x**0*y**6 | 1.445858E−16 |
| x**6*y**1 | 9.743411E−18 |
| x**4*y**3 | 7.566353E−18 |
| x**2*y**5 | 2.892971E−18 |
| x**0*y**7 | 1.516332E−19 |
| x**8*y**0 | −1.680882E−21 |
| x**6*y**2 | −4.513634E−21 |
| x**4*y**4 | 6.045637E−22 |
| x**2*y**6 | −2.429538E−21 |
| x**0*y**8 | 1.745315E−22 |
| x**8*y**1 | −8.256852E−22 |
| x**6*y**3 | −5.818782E−22 |
| x**4*y**5 | −2.027992E−22 |
| x**2*y**7 | −7.986045E−24 |
| x**0*y**9 | 7.228171E−24 |
| x**10*y**0 | 6.136778E−25 |
| x**8*y**2 | 4.246155E−25 |
| x**6*y**4 | 1.243661E−24 |
| x**4*y**6 | 4.634518E−25 |
| x**2*y**8 | 2.719151E−25 |
| x**0*y**10 | −3.545343E−27 |
| x**10*y**1 | 6.871746E−26 |
| x**8*y**3 | 5.861033E−26 |
| x**6*y**5 | 2.942543E−26 |
| x**4*y**7 | 8.201539E−27 |
| x**2*y**9 | −2.510259E−28 |
| x**0*y**11 | −8.121629E−29 |
| x**12*y**0 | −3.618314E−29 |
| x**10*y**2 | 2.741136E−29 |
| x**8*y**4 | −6.776370E−29 |
| x**6*y**6 | −4.473617E−29 |
| x**4*y**8 | −1.156909E−29 |
| x**2*y**10 | −3.811190E−30 |
| x**0*y**12 | 1.034120E−31 |
| x**12*y**1 | −2.743824E−30 |
| x**10*y**3 | −2.612245E−30 |
| x**8*y**5 | −1.600461E−30 |
| x**6*y**7 | −6.188669E−31 |
| x**4*y**9 | −1.225862E−31 |
| x**2*y**11 | 1.328671E−32 |
| x**0*y**13 | 8.207595E−34 |
| x**14*y**0 | 7.350514E−34 |
| x**12*y**2 | −1.093804E−33 |
| x**10*y**4 | 8.180084E−35 |
| x**8*y**6 | 2.650445E−33 |
| x**6*y**8 | 8.837876E−35 |
| x**4*y**10 | 2.220217E−34 |
| x**2*y**12 | 1.993275E−35 |
| x**0*y**14 | 1.132018E−36 |
| x**14*y**1 | 4.268468E−35 |
| x**12*y**3 | 4.513992E−35 |
| x**10*y**5 | 2.829593E−35 |
| x**8*y**7 | 1.409037E−35 |
| x**6*y**9 | 6.224093E−36 |
| x**4*y**11 | 2.733835E−37 |
| x**2*y**13 | −9.137216E−38 |
| x**0*y**15 | −6.932315E−39 |
| M7 | |
| RDX | −2943.636522 |
| RDY | 284.830821 |
| CCX | 0 |
| CCY | 0 |
| x**2*y**1 | 8.158686E−07 |
| x**0*y**3 | 6.582988E−06 |
| x**4*y**0 | 3.312146E−10 |
| x**2*y**2 | 4.582675E−09 |
| x**0*y**4 | 9.565208E−08 |
| x**4*y**1 | 1.455251E−12 |
| x**2*y**3 | 6.838734E−11 |
| x**0*y**5 | 1.047473E−09 |
| x**6*y**0 | 6.166405E−16 |
| x**4*y**2 | 3.015255E−14 |
| x**2*y**4 | 7.986421E−13 |
| x**0*y**6 | 1.118060E−11 |
| x**6*y**1 | 6.981842E−18 |
| x**4*y**3 | 3.286949E−16 |
| x**2*y**5 | 7.587138E−15 |
| x**0*y**7 | 1.203387E−13 |
| x**8*y**0 | 1.342107E−21 |
| x**6*y**2 | 8.432764E−20 |
| x**4*y**4 | 2.300626E−18 |
| x**2*y**6 | 6.893491E−17 |
| x**0*y**8 | 8.955976E−16 |
| x**8*y**1 | 4.014759E−23 |
| x**6*y**3 | 2.163716E−21 |
| x**4*y**5 | 7.919594E−20 |
| x**2*y**7 | 1.258722E−18 |
| x**0*y**9 | 1.138446E−17 |
| x**10*y**0 | 5.325301E−27 |
| x**8*y**2 | 1.093055E−24 |
| x**6*y**4 | 1.045493E−22 |
| x**4*y**6 | 3.828015E−21 |
| x**2*y**8 | 4.861790E−20 |
| x**0*y**10 | 4.975164E−19 |
| x**10*y**1 | −5.742837E−28 |
| x**8*y**3 | −1.930515E−26 |
| x**6*y**5 | 2.722829E−25 |
| x**4*y**7 | −2.095991E−23 |
| x**2*y**9 | 8.334409E−23 |
| x**0*y**11 | 6.627850E−21 |
| x**12*y**0 | −2.781881E−32 |
| x**10*y**2 | −1.075785E−29 |
| x**8*y**4 | −1.560066E−27 |
| x**6*y**6 | −1.306847E−25 |
| x**4*y**8 | −3.582309E−24 |
| x**2*y**10 | −3.792613E−23 |
| x**0*y**12 | 3.561648E−23 |
| x**12*y**1 | 1.139665E−32 |
| x**10*y**3 | 6.398200E−31 |
| x**8*y**5 | −1.281254E−29 |
| x**6*y**7 | −1.233694E−27 |
| x**4*y**9 | −1.148890E−26 |
| x**2*y**11 | −6.692361E−26 |
| x**0*y**13 | 2.600754E−24 |
| x**14*y**0 | 3.887718E−37 |
| x**12*y**2 | 1.149504E−34 |
| x**10*y**4 | 1.268379E−32 |
| x**8*y**6 | 1.389409E−30 |
| x**6*y**8 | 7.706987E−29 |
| x**4*y**10 | 1.864407E−27 |
| x**2*y**12 | 2.339914E−26 |
| x**0*y**14 | 5.672222E−26 |
| x**14*y**1 | −6.760612E−38 |
| x**12*y**3 | −5.228901E−36 |
| x**10*y**5 | 1.032278E−34 |
| x**8*y**7 | 2.895147E−32 |
| x**6*y**9 | 1.240256E−30 |
| x**4*y**11 | 2.444922E−29 |
| x**2*y**13 | 2.880548E−28 |
| x**0*y**15 | 2.856693E−28 |
| M8 | |
| RDX | −1128.303139 |
| RDY | −678.343714 |
| CCX | 0 |
| CCY | 0 |
| x**2*y**1 | 5.792643E−09 |
| x**0*y**3 | −7.479925E−09 |
| x**4*y**0 | −1.582488E−10 |
| x**2*y**2 | −2.326841E−10 |
| x**0*y**4 | −9.529152E−11 |
| x**4*y**1 | 9.587007E−14 |
| x**2*y**3 | 1.522227E−13 |
| x**0*y**5 | −4.425495E−14 |
| x**6*y**0 | 7.852465E−17 |
| x**4*y**2 | −4.789028E−16 |
| x**2*y**4 | −8.050883E−16 |
| x**0*y**6 | 2.889988E−17 |
| x**6*y**1 | −3.290128E−19 |
| x**4*y**3 | −2.747116E−19 |
| x**2*y**5 | 6.068308E−19 |
| x**0*y**7 | −1.800623E−19 |
| x**8*y**0 | −6.547155E−22 |
| x**6*y**2 | 1.765926E−22 |
| x**4*y**4 | 9.197688E−22 |
| x**2*y**6 | −2.785777E−21 |
| x**0*y**8 | −1.120423E−22 |
| x**8*y**1 | 2.927884E−25 |
| x**6*y**3 | −3.812522E−24 |
| x**4*y**5 | −7.961125E−24 |
| x**2*y**7 | 2.377463E−24 |
| x**0*y**9 | 1.659872E−24 |
| x**10*y**0 | 9.529899E−28 |
| x**8*y**2 | −1.899207E−26 |
| x**6*y**4 | −6.104700E−26 |
| x**4*y**6 | −3.734957E−26 |
| x**2*y**8 | 5.040684E−27 |
| x**0*y**10 | −1.760691E−26 |
| x**10*y**1 | 1.929482E−29 |
| x**8*y**3 | 1.549949E−28 |
| x**6*y**5 | 2.624883E−28 |
| x**4*y**7 | 9.199933E−29 |
| x**2*y**9 | −7.992841E−29 |
| x**0*y**11 | −1.589393E−29 |
| x**12*y**0 | 1.197080E−33 |
| x**10*y**2 | 2.435154E−31 |
| x**8*y**4 | 1.062180E−30 |
| x**6*y**6 | 1.404793E−30 |
| x**4*y**8 | 6.597669E−31 |
| x**2*y**10 | −6.238994E−32 |
| x**0*y**12 | 2.440009E−31 |
| x**12*y**1 | −1.845992E−34 |
| x**10*y**3 | −2.279384E−33 |
| x**8*y**5 | −5.683209E−33 |
| x**6*y**7 | −4.950798E−33 |
| x**4*y**9 | −1.594395E−34 |
| x**2*y**11 | 1.986515E−33 |
| x**0*y**13 | −1.314699E−35 |
| x**14*y**0 | −6.963196E−39 |
| x**12*y**2 | −1.332635E−36 |
| x**10*y**4 | −7.539202E−36 |
| x**8*y**6 | −1.501158E−35 |
| x**6*y**8 | −1.372762E−35 |
| x**4*y**10 | −3.651220E−36 |
| x**2*y**12 | −7.031295E−37 |
| x**0*y**14 | −1.393799E−36 |
| x**14*y**1 | −3.677437E−41 |
| x**12*y**3 | 1.120391E−38 |
| x**10*y**5 | 4.262181E−38 |
| x**8*y**7 | 6.079154E−38 |
| x**6*y**9 | 3.187953E−38 |
| x**4*y**11 | −1.639027E−38 |
| x**2*y**13 | −1.623794E−38 |
| x**0*y**15 | 7.628596E−40 |

Table 5 for FIG. 12

| Mirrors | Reflectivity |
|---|---|
| M1 | 65.9 |
| M2 | 80.9 |
| M3 | 87.6 |
| M4 | 65.2 |
| M5 | 89.7 |
| M6 | 86.7 |
| M7 | 65.3 |
| M8 | 66.3 |
| Overall transmission | 10.2 |

Without including the polishing overrun edge, the projection optical unit 28 has an overall mirror surface of 0.69 m².

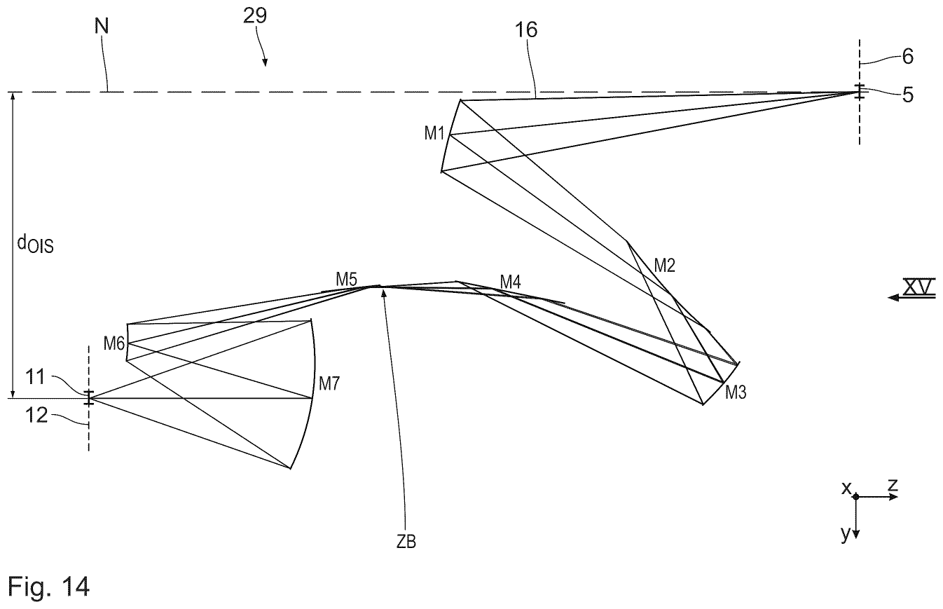

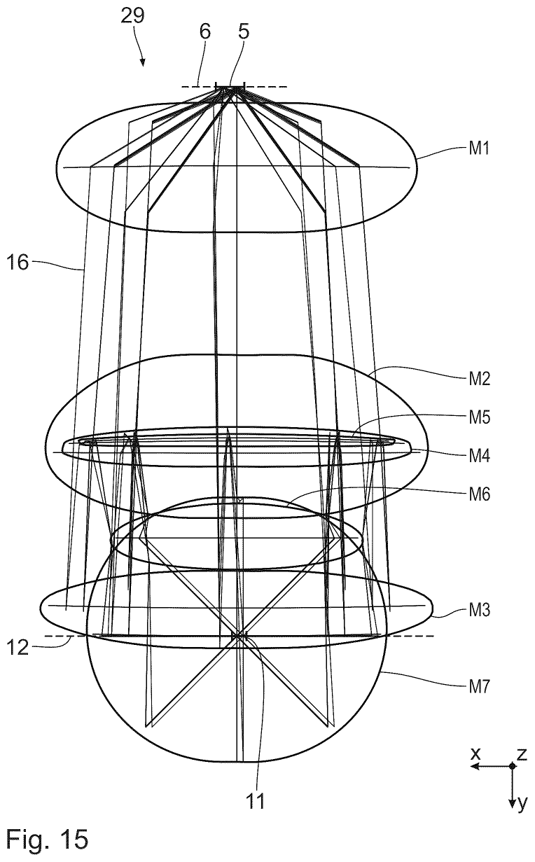

FIGS. 14 and 15 show a further embodiment of a projection optical unit or imaging optical unit 29, which can be used in the projection exposure apparatus 1 instead of the projection optical unit 10 of the embodiment according to FIG. 2. Components and functions corresponding to those which have already been explained above in conjunction with FIGS. 1 to 13, and in particular in conjunction with FIGS. 1 to 3, are denoted by the same reference numeral and are not discussed in detail again.

In terms of basic structure, the projection optical unit 29 according to FIGS. 14 and 15 is similar to the projection optical unit 10 according to FIGS. 2 and 3. A difference is that exactly one GI mirror, namely the mirror M2, is present in the projection optical unit 29 in place of the two successively arranged GI mirrors M2 and M3. In principle, this GI mirror M2 of the projection optical unit 29 satisfies a comparable function as the GI mirror pair M2, M3 of the projection optical unit 10.

The projection optical unit 29 has exactly three GI mirrors, namely the mirrors M2, M4 and M5. The projection optical unit 29 has exactly seven mirrors M1 to M7 in the beam path between the object field 5 and the image field 11.

An angle of incidence sequence of the first three mirrors M1, M2, M3 in the beam path of the projection optical unit 29 is NI (M1), GI (M2), NI (M3).

An angle of incidence sequence of the seven mirrors M1 to M7 of the projection optical unit 29 in the beam path between the object field 5 and the image field 11 is NI, GI, NI, GI, GI, NI, NI.

The subject field 5 and the image field 11 are rectangular in the projection optical unit 29.

The intermediate image ZB in the yz-plane (meridional plane) is located in the region of a reflection of the imaging light 16 at the mirror M5.

There is no intermediate image between the object field 5 and the image field 11 in the xy-plane perpendicular thereto. In the case of the projection optical unit 29, the image plane 12 is the first field plane downstream of the object plane 6 of the imaging optical unit 29 in the imaging beam path in the imaging light plane containing the image field extension direction x. An image flip occurs in this imaging light plane. By contrast, there is no image flip in the meridional imaging plane on account of the intermediate image ZB present there.

A mean wavefront aberration is approximately 13 mλ in the projection optical unit 29.

The projection optical unit 29 has an overall transmission of 11.1%. An overall mirror surface without inclusion of the polishing overrun edge is 0.83 m² in the case of the projection optical unit 29. An overall installation height, i.e. a distance between the object plane and the image plane, is 2255 mm. An object-image offset d_{OIS} is 899 mm.

In the projection optical unit 29, an aperture stop or obscuration stop is arranged in the imaging beam path between the mirrors M5 and M6. This stop is located in the vicinity of the mirror M6 and is passed multiple times by the imaging light. The stop can be designed in a manner subdivided into a plurality of partial stops.

The following tables summarize parameters and the optical design of the projection optical unit 29. In terms of their structure, these tables correspond to those already explained above in conjunction with FIG. 2.

Table 1 for FIG. 14

| | |
|---|---|
| Wavelength [nm] | 13.5 |
| Image-side numerical | 0.33 |
| aperture | |
| Image field size in the x- and | 52 × 1.7 |
| y-directions [mm × mm] | |
| Ring field radius [mm] | — |
| βx | 2 |
| βy | 4 |
| Chief ray angle [°] | 6 |
| Étendue | 9.63 |
| Mean wavefront aberration | 13.15 |
| RMS [mλ] | |
| Overall transmission [%] | 11.1 |
| Position of the entrance pupil | −1529.86 |
| (x) | |
| Position of the entrance pupil | 1468.68 |
| (y) | |
| Object-image offset in the | 898.94 |
| y-direction [mm] | |
| Distance between M7 and | 109 |
| image plane [mm] | |
| Distance between object | 2254.93 |
| plane and image plane | |
| Tilt between object plane and | 0 |
| image plane [°] | |
| Installation space cuboid | 639 × 1086 × 1797 |
| [mm × mm × mm] | |

Table 2a for FIG. 14

| | M1 | M2 | M3 | M4 |
|---|---|---|---|---|
| Maximum angle of incidence [°] | 22.1 | 83.3 | 19.5 | 83.2 |
| Minimum angle of incidence [°] | 20.6 | 77.4 | 13.2 | 74.7 |
| Extent of the reflection surface | 588.4 | 624.0 | 639.2 | 569.6 |
| in the x-direction [mm] | | | | |
| Extent of the reflection surface | 216.5 | 369.7 | 169.4 | 332.5 |
| in the y-direction [mm] | | | | |
| Maximum mirror diameter [mm] | 588.4 | 624.2 | 639.4 | 571.5 |
| Mean transmission [%] | 62.7 | 83.6 | 64.3 | 84.3 |
| Minimum transmission [%] | 62.5 | 82.6 | 64.1 | 84.2 |
| Maximum transmission [%] | 62.8 | 84.6 | 64.5 | 84.5 |

Table 2b for FIG. 14

| | M5 | M6 | M7 |
|---|---|---|---|
| Maximum angle of incidence [°] | 87.4 | 25.7 | 12.9 |
| Minimum angle of incidence [°] | 79.0 | 3.8 | 7.0 |
| Extent of the reflection surface | 515.9 | 416.4 | 494.1 |
| in the x-direction [mm] | | | |
| Extent of the reflection surface | 171.5 | 108.5 | 446.2 |
| in the y-direction [mm] | | | |
| Maximum mirror diameter [mm] | 516.9 | 416.4 | 495.2 |
| Mean transmission [%] | 90.0 | 64.9 | 64.8 |
| Minimum transmission [%] | 89.7 | 64.8 | 65.1 |
| Maximum transmission [%] | 90.3 | 65.1 | 0.0 |

Table 3a for FIG. 14

| | x-distance [mm] | y-distance [mm] | z-distance [mm] |
|---|---|---|---|
| Object field | 0.00 | 898.94 | 2254.93 |
| M1 | 0.00 | 772.80 | 1054.80 |
| M2 | 0.00 | 300.63 | 1705.60 |
| M3 | 0.00 | 46.09 | 1858.33 |
| M4 | 0.00 | 320.75 | 1184.89 |
| M5 | 0.00 | 325.72 | 798.74 |
| Aperture stop | 0.00 | 176.62 | 176.88 |
| M6 | 0.00 | 161.32 | 113.07 |
| M7 | 0.00 | 0.00 | 653.23 |
| Image field | 0.00 | 0.00 | 0.00 |

Table 3b for FIG. 14

| | Tilt about the | Tilt about the | Tilt about the |
|---|---|---|---|
| | x-axis [°] | y-axis [°] | z-axis [°] |
| Object field | 0.00 | 0.00 | 180.00 |
| M1 | 194.98 | 0.00 | 0.00 |
| M2 | −42.50 | 0.00 | 180.00 |
| M3 | 40.61 | 0.00 | 0.00 |
| M4 | −78.54 | 0.00 | 180.00 |
| M5 | 263.63 | 0.00 | 0.00 |
| Aperture stop | −13.48 | 0.00 | 0.00 |
| M6 | 1.57 | 180.00 | 0.00 |
| M7 | 8.31 | 0.00 | 0.00 |
| Image field | 0.00 | 0.00 | 0.00 |

Table 4a for FIG. 14

| | M1 | M2 | M3 |
|---|---|---|---|
| RDX | −3128.128698 | 37085.509306 | −7434.884222 |
| RDY | −1276.288097 | 1543.528113 | −778.031712 |
| CCX | 0.000000 | 0.000000 | 0.000000 |
| CCY | 0.000000 | 0.000000 | 0.000000 |
| x**i * y**j | Coefficient | Coefficient | Coefficient |
| x**2 * y**0 | 0.000000E+00 | 0.000000E+00 | 0.000000E+00 |
| x**0 * y**2 | 0.000000E+00 | 0.000000E+00 | 0.000000E+00 |
| x**2 * y**1 | 2.609049E−08 | −3.277422E−08 | 6.436533E−08 |
| x**0 * y**3 | −3.322867E−08 | 5.162759E−07 | −1.630850E−06 |
| x**4 * y**0 | −9.879990E−12 | 3.968426E−12 | 1.145676E−11 |
| x**2 * y**2 | −3.323250E−11 | −2.625163E−11 | 1.950639E−10 |
| x**0 * y**4 | 2.179657E−10 | 8.908626E−10 | −7.571489E−09 |
| x**4 * y**1 | 4.299755E−15 | −1.406073E−14 | 2.771787E−14 |
| x**2 * y**3 | 8.093367E−14 | −3.105798E−13 | 7.426613E−13 |
| x**0 * y**5 | −1.477552E−12 | 2.367774E−12 | −3.984445E−11 |
| x**6 * y**0 | −1.931938E−18 | 1.823437E−19 | 3.659929E−18 |
| x**4 * y**2 | −1.545279E−17 | −1.217507E−16 | 2.733069E−16 |
| x**2 * y**4 | −2.174073E−16 | −8.008498E−16 | 7.869062E−16 |
| x**0 * y**6 | 3.567003E−15 | 6.814513E−15 | −2.527614E−13 |
| x**6 * y**1 | −6.924269E−21 | 4.493949E−20 | 4.457840E−21 |
| x**4 * y**3 | 5.237563E−20 | −6.121083E−19 | 2.343776E−18 |
| x**2 * y**5 | 8.617883E−19 | −2.824295E−18 | −4.132350E−18 |
| x**0 * y**7 | 6.834948E−17 | 1.572632E−17 | −1.363290E−15 |
| x**8 * y**0 | −7.217672E−24 | 1.858984E−23 | 1.213710E−24 |
| x**6 * y**2 | −1.074058E−22 | 1.954339E−22 | 7.046128E−23 |
| x**4 * y**4 | −1.785168E−21 | −6.041394E−22 | 1.154230E−20 |
| x**2 * y**6 | 9.938042E−21 | −5.689055E−21 | −2.639051E−19 |
| x**0 * y**8 | −3.119468E−19 | 7.063413E−20 | −1.060127E−17 |
| x**8 * y**1 | 1.126085E−25 | −6.203052E−25 | 2.242560E−25 |
| x**6 * y**3 | −7.230125E−25 | 3.808813E−24 | −3.286297E−24 |
| x**4 * y**5 | −8.891370E−24 | 2.055595E−23 | −1.677755E−22 |
| x**2 * y**7 | −1.139002E−22 | 6.508880E−23 | −6.080565E−21 |
| x**0 * y**9 | −6.452480E−21 | 3.416666E−22 | −9.813033E−20 |
| x**10 * y**0 | 7.196771E−29 | −8.735863E−29 | −7.480210E−31 |
| x**8 * y**2 | 1.836694E−27 | −3.150927E−27 | 2.999053E−27 |
| x**6 * y**4 | 4.147882E−26 | −2.312142E−26 | 9.887113E−26 |
| x**4 * y**6 | 3.800917E−25 | −1.460707E−25 | 2.085170E−24 |
| x**2 * y**8 | −1.211718E−24 | 1.499372E−25 | −2.683912E−23 |
| x**0 * y**10 | 4.327194E−23 | 4.027679E−27 | −2.127573E−22 |
| x**10 * y**1 | −1.145681E−30 | 4.558780E−30 | −1.486621E−30 |
| x**8 * y**3 | 8.551768E−30 | −6.713465E−29 | 1.125569E−28 |
| x**6 * y**5 | 2.011408E−28 | −6.085145E−28 | 4.990824E−27 |
| ***4 * y**7 | −3.690762E−28 | −1.721318E−27 | 6.391258E−26 |
| x**2 * y**9 | 1.513772E−26 | −2.443412E−27 | 4.313855E−25 |
| x**0 * y**11 | 9.702032E−26 | −3.874968E−27 | 4.250677E−24 |
| x**12 * y**0 | −3.369966E−34 | −2.690644E−34 | 7.466444E−35 |
| x**10 * y**2 | −9.717229E−33 | −2.496797E−32 | 2.034393E−32 |
| x**8 * y**4 | −4.656388E−31 | 1.829333E−32 | −6.576272E−32 |
| x**6 * y**6 | −5.173964E−30 | −4.985271E−31 | 1.732546E−29 |
| x**4 * y**8 | −1.952233E−29 | −1.012143E−30 | 3.822006E−30 |
| x**2 * y**10 | 3.317965E−30 | −5.869881E−30 | 1.243420E−27 |
| x**0 * y**12 | −8.876992E−28 | −1.230387E−30 | −2.199249E−26 |
| x**12 * y**1 | 5.202668E−36 | −1.778487E−35 | 5.675948E−36 |
| x**10 * y**3 | −1.280019E−35 | 2.403769E−34 | −3.269567E−34 |
| x**8 * y**5 | −6.921187E−34 | 3.001248E−33 | −2.045812E−32 |
| x**6 * y**7 | −4.178696E−33 | 1.537510E−32 | −5.728001E−31 |
| x**4 * y**9 | 3.511797E−32 | 2.530285E−32 | −5.812290E−30 |
| x**2 * y**11 | −3.870779E−31 | 3.548286E−32 | −5.354062E−29 |
| x**0 * y**13 | −5.949504E−31 | 3.404592E−32 | −6.380831E−28 |
| x**14 * y**0 | 4.257880E−40 | 3.936529E−39 | −7.605698E−40 |
| x**12 * y**2 | −1.995445E−39 | 2.406315E−37 | −1.696055E−37 |
| x**10 * y**4 | 1.579748E−36 | 9.639352E−37 | −3.065647E−36 |
| x**8 * y**6 | 2.225949E−35 | 1.084988E−35 | −2.017793E−34 |
| x**6 * y**8 | 1.620914E−34 | 4.195339E−35 | −3.917012E−33 |
| x**4 * y**10 | 2.470700E−34 | 6.086002E−35 | −2.957419E−32 |
| x**2 * y**12 | 5.740168E−34 | 1.095532E−34 | −3.365407E−31 |
| x**0 * y**14 | 1.530654E−33 | 5.440839E−35 | −2.451435E−30 |
| x**14 * y**1 | 0.000000E+00 | 0.000000E+00 | 0.000000E+00 |
| x**12 * y**3 | 0.000000E+00 | 0.000000E+00 | 0.000000E+00 |
| x**10 * y**5 | 0.000000E+00 | 0.000000E+00 | 0.000000E+00 |
| x**8 * y**7 | 0.000000E+00 | 0.000000E+00 | 0.000000E+00 |
| x**6 * y**9 | 0.000000E+00 | 0.000000E+00 | 0.000000E+00 |
| x**4 * y**11 | 0.000000E+00 | 0.000000E+00 | 0.000000E+00 |
| x**2 * y**13 | 0.000000E+00 | 0.000000E+00 | 0.000000E+00 |
| x**0 * y**15 | 0.000000E+00 | 0.000000E+00 | 0.000000E+00 |
| x**16 * y**0 | 0.000000E+00 | 0.000000E+00 | 0.000000E+00 |
| x**14 * y**2 | 0.000000E+00 | 0.000000E+00 | 0.000000E+00 |
| x**12 * y**4 | 0.000000E+00 | 0.000000E+00 | 0.000000E+00 |
| x**10 * y**6 | 0.000000E+00 | 0.000000E+00 | 0.000000E+00 |
| x**8 * y**8 | 0.000000E+00 | 0.000000E+00 | 0.000000E+00 |
| x**6 * y**10 | 0.000000E+00 | 0.000000E+00 | 0.000000E+00 |
| x**4 * y**12 | 0.000000E+00 | 0.000000E+00 | 0.000000E+00 |
| x**2 * y**14 | 0.000000E+00 | 0.000000E+00 | 0.000000E+00 |
| x**0 * y**16 | 0.000000E+00 | 0.000000E+00 | 0.000000E+00 |
| x**16 * y**1 | 0.000000E+00 | 0.000000E+00 | 0.000000E+00 |
| x**14 * y**3 | 0.000000E+00 | 0.000000E+00 | 0.000000E+00 |
| x**12 * y**5 | 0.000000E+00 | 0.000000E+00 | 0.000000E+00 |
| x**10 * y**7 | 0.000000E+00 | 0.000000E+00 | 0.000000E+00 |
| x**8 * y**9 | 0.000000E+00 | 0.000000E+00 | 0.000000E+00 |
| x**6 * y**11 | 0.000000E+00 | 0.000000E+00 | 0.000000E+00 |
| x**4 * y**13 | 0.000000E+00 | 0.000000E+00 | 0.000000E+00 |
| x**2 * y**15 | 0.000000E+00 | 0.000000E+00 | 0.000000E+00 |
| x**0 * y**17 | 0.000000E+00 | 0.000000E+00 | 0.000000E+00 |
| x**18 * y**0 | 0.000000E+00 | 0.000000E+00 | 0.000000E+00 |
| x**16 * y**2 | 0.000000E+00 | 0.000000E+00 | 0.000000E+00 |
| x**14 * y**4 | 0.000000E+00 | 0.000000E+00 | 0.000000E+00 |
| x**12 * y**6 | 0.000000E+00 | 0.000000E+00 | 0.000000E+00 |
| x**10 * y**8 | 0.000000E+00 | 0.000000E+00 | 0.000000E+00 |
| x**8 * y**10 | 0.000000E+00 | 0.000000E+00 | 0.000000E+00 |
| x**6 * y**12 | 0.000000E+00 | 0.000000E+00 | 0.000000E+00 |
| x**4 * y**14 | 0.000000E+00 | 0.000000E+00 | 0.000000E+00 |
| x**2 * y**16 | 0.000000E+00 | 0.000000E+00 | 0.000000E+00 |
| x**0 * y**18 | 0.000000E+00 | 0.000000E+00 | 0.000000E+00 |

Table 4b for FIG. 14

| | M4 | M5 | M6 |
|---|---|---|---|
| RDX | −8738.519553 | −5514.516053 | 7111.966727 |
| RDY | −47146.633588 | −25256.066937 | 448.683308 |
| CCX | 0.000000 | 0.000000 | 0.000000 |
| CCY | 0.000000 | 0.000000 | 0.000000 |
| x**i * y**j | Coefficient | Coefficient | Coefficient |
| x**2 * y**0 | 0.000000E+00 | 0.000000E+00 | 0.000000E+00 |
| x**0 * y**2 | 0.000000E+00 | 0.000000E+00 | 0.000000E+00 |
| x**2 * y**1 | −4.861270E−08 | −2.146046E−09 | 2.605651E−07 |
| x**0 * y**3 | 3.401245E−09 | 1.838587E−08 | −7.562388E−08 |
| x**4 * y**0 | 6.588700E−12 | −7.198466E−12 | 1.474952E−10 |
| x**2 * y**2 | −5.782239E−11 | −2.722748E−11 | 1.488490E−09 |
| x**0 * y**4 | 1.286897E−10 | −3.604970E−11 | −5.620853E−09 |
| x**4 * y**1 | 4.631532E−14 | 7.749669E−15 | 3.754288E−13 |
| x**2 * y**3 | −2.742387E−13 | −9.676910E−15 | −3.279821E−13 |
| x**0 * y**5 | −4.851481E−13 | −1.772859E−13 | −9.635659E−11 |
| x**6 * y**0 | −1.773819E−17 | −1.673518E−17 | 1.752279E−16 |
| x**4 * y**2 | 2.711922E−16 | −2.745465E−17 | 3.112078E−15 |
| x**2 * y**4 | 3.523806E−16 | −2.530336E−16 | −3.405078E−14 |
| x**0 * y**6 | 3.006491E−15 | −3.196178E−15 | −6.596462E−14 |
| x**6 * y**1 | −1.325906E−19 | 4.931395E−20 | 7.194801E−19 |
| x**4 * y**3 | 2.353519E−19 | 5.740019E−19 | −2.391184E−18 |
| x**2 * y**5 | −5.384218E−18 | 5.128482E−18 | −1.242118E−16 |
| x**0 * y**7 | −1.844173E−17 | 1.503644E−16 | 2.977015E−14 |
| x**8 * y**0 | −2.937873E−23 | 1.741734E−22 | 2.300657E−22 |
| x**6 * y**2 | −2.263675E−22 | −5.478703E−23 | 7.756422E−21 |
| x**4 * y**4 | 6.337792E−21 | −2.029148E−21 | −4.152918E−20 |
| x**2 * y**6 | 2.738289E−20 | 1.114785E−19 | 2.196441E−17 |
| x**0 * y**8 | 7.992113E−20 | 4.781766E−19 | 2.345911E−16 |
| x**8 * y**1 | −5.887539E−25 | 4.572410E−25 | 2.372857E−24 |
| x**6 * y**3 | −4.363908E−24 | 5.622379E−24 | 4.803236E−23 |
| x**4 * y**5 | 3.875314E−24 | −1.953239E−22 | 8.555322E−21 |
| x**2 * y**7 | −3.107862E−23 | −3.454196E−21 | 2.366556E−19 |
| x**0 * y**9 | 1.492060E−23 | −6.544894E−20 | −9.958889E−18 |
| x**10 * y**0 | 8.901093E−28 | −3.594328E−27 | 1.018122E−27 |
| x**8 * y**2 | −1.980688E−27 | −7.564954E−27 | −5.880985E−26 |
| x**6 * y**4 | −7.036494E−26 | 2.065403E−25 | 3.016960E−25 |
| x**4 * y**6 | −3.159180E−25 | 2.337306E−24 | 1.214511E−22 |
| x**2 * y**8 | −4.420158E−25 | 7.918147E−24 | −8.650320E−21 |
| x**0 * y**10 | 2.706347E−25 | 6.190922E−22 | −1.110069E−19 |
| x**10 * y**1 | 1.229459E−29 | −6.506287E−30 | −7.925859E−30 |
| x**8 * y**3 | 6.121374E−29 | −4.381243E−28 | −9.935768E−28 |
| x**6 * y**5 | 3.435243E−28 | −2.275499E−28 | −3.013991E−26 |
| ***4 * y**7 | 5.436035E−28 | 4.761147E−26 | −4.595837E−24 |
| x**2 * y**9 | −5.984542E−27 | 7.145150E−25 | −1.259914E−22 |
| x**0 * y**11 | −2.901602E−26 | 4.963125E−24 | 1.218708E−21 |
| x**12 * y**0 | −8.769563E−33 | 3.789988E−32 | −7.751115E−33 |
| x**10 * y**2 | −1.026529E−32 | 2.711229E−31 | 1.787373E−30 |
| x**8 * y**4 | 5.295233E−31 | 7.845374E−31 | 5.234586E−29 |
| x**6 * y**6 | 2.660563E−30 | −8.025827E−29 | −7.521783E−28 |
| x**4 * y**8 | 2.057135E−29 | −6.334076E−28 | −7.556706E−26 |
| x**2 * y**10 | 8.728757E−29 | −1.059003E−26 | 1.019218E−24 |
| x**0 * y**12 | 2.359634E−28 | −1.216016E−25 | 1.377018E−23 |
| x**12 * y**1 | −6.909736E−35 | 2.872809E−36 | 9.314230E−35 |
| x**10 * y**3 | −7.714405E−34 | 3.644301E−33 | 1.189525E−32 |
| x**8 * y**5 | −5.801343E−33 | 5.019636E−32 | 5.233225E−31 |
| x**6 * y**7 | −2.922990E−32 | 2.000592E−31 | 3.435941E−30 |
| x**4 * y**9 | −1.235193E−31 | −9.381898E−31 | 6.403684E−28 |
| x**2 * y**11 | −3.701816E−31 | 6.210621E−29 | 1.672532E−26 |
| x**0 * y**13 | −7.556128E−31 | 7.718917E−28 | −5.120397E−26 |
| x**14 * y**0 | 4.363482E−38 | −1.826010E−37 | 5.923664E−38 |
| x**12 * y**2 | 4.476541E−37 | −1.919065E−36 | −1.353078E−35 |
| x**10 * y**4 | 2.148413E−36 | −3.742051E−35 | −5.678754E−34 |
| x**8 * y**6 | 1.769978E−35 | −5.778500E−35 | −5.813493E−33 |
| x**6 * y**8 | 5.793253E−35 | 3.279275E−33 | 1.574199E−31 |
| x**4 * y**10 | 2.211463E−34 | 1.947421E−32 | 1.181216E−29 |
| x**2 * y**12 | 5.338932E−34 | −1.382979E−31 | −1.739128E−29 |
| x**0 * y**14 | 8.887466E−34 | −1.691201E−30 | −1.844237E−28 |
| x**14 * y**1 | 0.000000E+00 | 0.000000E+00 | 0.000000E+00 |
| x**12 * y**3 | 0.000000E+00 | 0.000000E+00 | 0.000000E+00 |
| x**10 * y**5 | 0.000000E+00 | 0.000000E+00 | 0.000000E+00 |
| x**8 * y**7 | 0.000000E+00 | 0.000000E+00 | 0.000000E+00 |
| x**6 * y**9 | 0.000000E+00 | 0.000000E+00 | 0.000000E+00 |
| x**4 * y**11 | 0.000000E+00 | 0.000000E+00 | 0.000000E+00 |
| x**2 * y**13 | 0.000000E+00 | 0.000000E+00 | 0.000000E+00 |
| x**0 * y**15 | 0.000000E+00 | 0.000000E+00 | 0.000000E+00 |
| x**16 * y**0 | 0.000000E+00 | 0.000000E+00 | 0.000000E+00 |
| x**14 * y**2 | 0.000000E+00 | 0.000000E+00 | 0.000000E+00 |
| x**12 * y**4 | 0.000000E+00 | 0.000000E+00 | 0.000000E+00 |
| x**10 * y**6 | 0.000000E+00 | 0.000000E+00 | 0.000000E+00 |
| x**8 * y**8 | 0.000000E+00 | 0.000000E+00 | 0.000000E+00 |
| x**6 * y**10 | 0.000000E+00 | 0.000000E+00 | 0.000000E+00 |
| x**4 * y**12 | 0.000000E+00 | 0.000000E+00 | 0.000000E+00 |
| x**2 * y**14 | 0.000000E+00 | 0.000000E+00 | 0.000000E+00 |
| x**0 * y**16 | 0.000000E+00 | 0.000000E+00 | 0.000000E+00 |
| x**16 * y**1 | 0.000000E+00 | 0.000000E+00 | 0.000000E+00 |
| x**14 * y**3 | 0.000000E+00 | 0.000000E+00 | 0.000000E+00 |
| x**12 * y**5 | 0.000000E+00 | 0.000000E+00 | 0.000000E+00 |
| x**10 * y**7 | 0.000000E+00 | 0.000000E+00 | 0.000000E+00 |
| x**8 * y**9 | 0.000000E+00 | 0.000000E+00 | 0.000000E+00 |
| x**6 * y**11 | 0.000000E+00 | 0.000000E+00 | 0.000000E+00 |
| x**4 * y**13 | 0.000000E+00 | 0.000000E+00 | 0.000000E+00 |
| x**2 * y**15 | 0.000000E+00 | 0.000000E+00 | 0.000000E+00 |
| x**0 * y**17 | 0.000000E+00 | 0.000000E+00 | 0.000000E+00 |
| x**18 * y**0 | 0.000000E+00 | 0.000000E+00 | 0.000000E+00 |
| x**16 * y**2 | 0.000000E+00 | 0.000000E+00 | 0.000000E+00 |
| x**14 * y**4 | 0.000000E+00 | 0.000000E+00 | 0.000000E+00 |
| x**12 * y**6 | 0.000000E+00 | 0.000000E+00 | 0.000000E+00 |
| x**10 * y**8 | 0.000000E+00 | 0.000000E+00 | 0.000000E+00 |
| x**8 * y**10 | 0.000000E+00 | 0.000000E+00 | 0.000000E+00 |
| x**6 * y**12 | 0.000000E+00 | 0.000000E+00 | 0.000000E+00 |
| x**4 * y**14 | 0.000000E+00 | 0.000000E+00 | 0.000000E+00 |
| x**2 * y**16 | 0.000000E+00 | 0.000000E+00 | 0.000000E+00 |
| x**0 * y**18 | 0.000000E+00 | 0.000000E+00 | 0.000000E+00 |

Table 4c for FIG. 14

| | M7 |
|---|---|
| RDX | −8738.519553 |
| RDY | −47146.633588 |
| CCX | 0.000000 |
| CCY | 0.000000 |
| x**i * y**j | Coefficient |
| x**2 * y**0 | 0.000000E+00 |
| x**0 * y**2 | 0.000000E+00 |
| x**2 * y**1 | −4.861270E−08 |
| x**0 * y**3 | 3.401245E−09 |
| x**4 * y**0 | 6.588700E−12 |
| x**2 * y**2 | −5.782239E−11 |
| x**0 * y**4 | 1.286897E−10 |
| x**4 * y**1 | 4.631532E−14 |
| x**2 * y**3 | −2.742387E−13 |
| x**0 * y**5 | −4.851481E−13 |
| x**6 * y**0 | −1.773819E−17 |
| x**4 * y**2 | 2.711922E−16 |
| x**2 * y**4 | 3.523806E−16 |
| x**0 * y**6 | 3.006491E−15 |
| x**6 * y**1 | −1.325906E−19 |
| x**4 * y**3 | 2.353519E−19 |
| x**2 * y**5 | −5.384218E−18 |
| x**0 * y**7 | −1.844173E−17 |
| x**8 * y**0 | −2.937873E−23 |
| x**6 * y**2 | −2.263675E−22 |
| x**4 * y**4 | 6.337792E−21 |
| x**2 * y**6 | 2.738289E−20 |
| x**0 * y**8 | 7.992113E−20 |
| x**8 * y**1 | −5.887539E−25 |
| x**6 * y**3 | −4.363908E−24 |
| x**4 * y**5 | 3.875314E−24 |
| x**2 * y**7 | −3.107862E−23 |
| x**0 * y**9 | 1.492060E−23 |
| x**10 * y**0 | 8.901093E−28 |
| x**8 * y**2 | −1.980688E−27 |
| x**6 * y**4 | −7.036494E−26 |
| x**4 * y**6 | −3.159180E−25 |
| x**2 * y**8 | −4.420158E−25 |
| x**0 * y**10 | 2.706347E−25 |
| x**10 * y**1 | 1.229459E−29 |
| x**8 * y**3 | 6.121374E−29 |
| x**6 * y**5 | 3.435243E−28 |
| ***4 * y**7 | 5.436035E−28 |
| x**2 * y**9 | −5.984542E−27 |
| x**0 * y**11 | −2.901602E−26 |
| x**12 * y**0 | −8.769563E−33 |
| x**10 * y**2 | −1.026529E−32 |
| x**8 * y**4 | 5.295233E−31 |
| x**6 * y**6 | 2.660563E−30 |
| x**4 * y**8 | 2.057135E−29 |
| x**2 * y**10 | 8.728757E−29 |
| x**0 * y**12 | 2.359634E−28 |
| x**12 * y**1 | −6.909736E−35 |
| x**10 * y**3 | −7.714405E−34 |
| x**8 * y**5 | −5.801343E−33 |
| x**6 * y**7 | −2.922990E−32 |
| x**4 * y**9 | −1.235193E−31 |
| x**2 * y**11 | −3.701816E−31 |
| x**0 * y**13 | −7.556128E−31 |
| x**14 * y**0 | 4.363482E−38 |
| x**12 * y**2 | 4.476541E−37 |
| x**10 * y**4 | 2.148413E−36 |
| x**8 * y**6 | 1.769978E−35 |
| x**6 * y**8 | 5.793253E−35 |
| x**4 * y**10 | 2.211463E−34 |
| x**2 * y**12 | 5.338932E−34 |
| x**0 * y**14 | 8.887466E−34 |
| x**14 * y**1 | 0.000000E+00 |
| x**12 * y**3 | 0.000000E+00 |
| x**10 * y**5 | 0.000000E+00 |
| x**8 * y**7 | 0.000000E+00 |
| x**6 * y**9 | 0.000000E+00 |
| x**4 * y**11 | 0.000000E+00 |
| x**2 * y**13 | 0.000000E+00 |
| x**0 * y**15 | 0.000000E+00 |
| x**16 * y**0 | 0.000000E+00 |
| x**14 * y**2 | 0.000000E+00 |
| x**12 * y**4 | 0.000000E+00 |
| x**10 * y**6 | 0.000000E+00 |
| x**8 * y**8 | 0.000000E+00 |
| x**6 * y**10 | 0.000000E+00 |
| x**4 * y**12 | 0.000000E+00 |
| x**2 * y**14 | 0.000000E+00 |
| x**0 * y**16 | 0.000000E+00 |
| x**16 * y**1 | 0.000000E+00 |
| x**14 * y**3 | 0.000000E+00 |
| x**12 * y**5 | 0.000000E+00 |
| x**10 * y**7 | 0.000000E+00 |
| x**8 * y**9 | 0.000000E+00 |
| x**6 * y**11 | 0.000000E+00 |
| x**4 * y**13 | 0.000000E+00 |
| x**2 * y**15 | 0.000000E+00 |
| x**0 * y**17 | 0.000000E+00 |
| x**18 * y**0 | 0.000000E+00 |
| x**16 * y**2 | 0.000000E+00 |
| x**14 * y**4 | 0.000000E+00 |
| x**12 * y**6 | 0.000000E+00 |
| x**10 * y**8 | 0.000000E+00 |
| x**8 * y**10 | 0.000000E+00 |
| x**6 * y**12 | 0.000000E+00 |
| x**4 * y**14 | 0.000000E+00 |
| x**2 * y**16 | 0.000000E+00 |
| x**0 * y**18 | 0.000000E+00 |

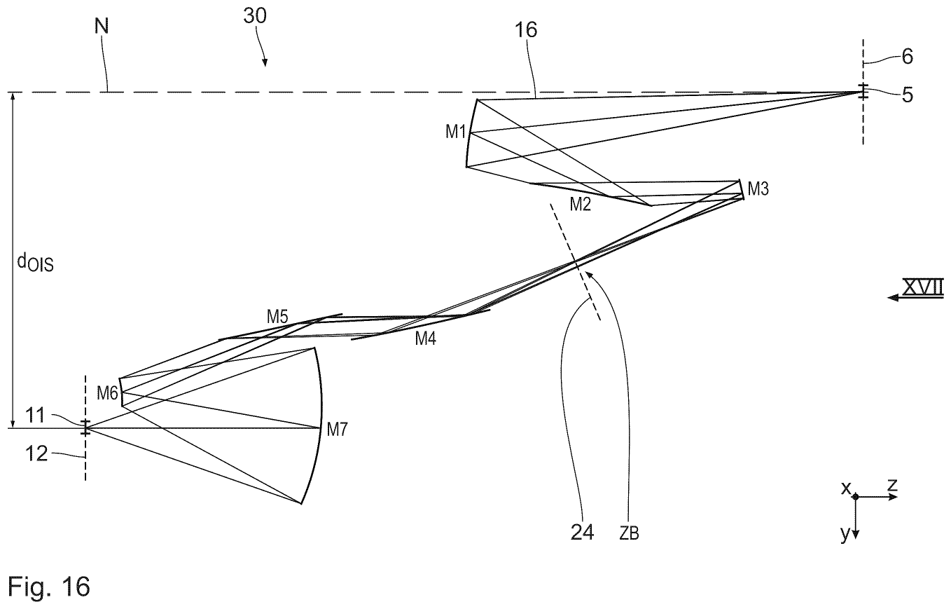

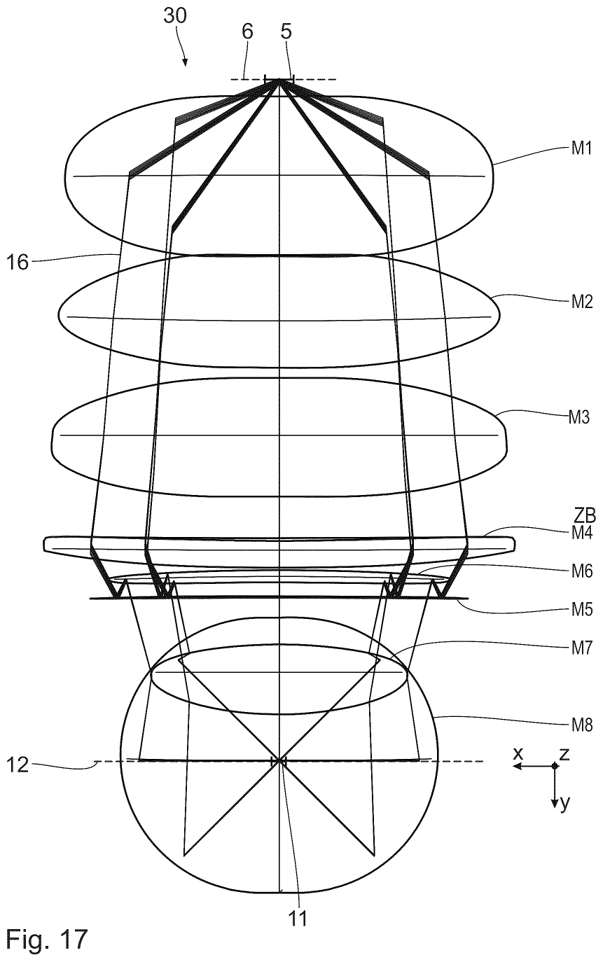

FIGS. 16 and 17 show a further embodiment of a projection optical unit or imaging optical unit 30, which can be used in the projection exposure apparatus 1 instead of the projection optical unit 10 of the embodiment according to FIG. 2. Components and functions corresponding to those which have already been explained above in conjunction with FIGS. 1 to 15, and in particular in conjunction with FIGS. 1 to 3, are denoted by the same reference numeral and are not discussed in detail again.

In terms of basic structure, the projection optical unit 30 according to FIGS. 16 and 17 is similar to the projection optical unit 27 according to FIG. 10. A difference is that exactly one GI mirror, namely the GI mirror M2, is now used in the projection optical unit 30 in place two GI mirrors M2 and M3 of the projection optical unit 27. In the meridional beam path according to FIG. 16, this GI mirror M2 has an anticlockwise deflecting effect.

The mirrors M1 and M3 to M7 of the projection optical unit 30 corresponds in terms of their deflecting effect to the mirrors M1 and M4 to M8 of the projection optical unit 27.

Like the projection optical unit 29, the projection optical unit 30 according to FIGS. 16 and 17 also has an angle of incidence sequence NI, GI, NI of the first three mirrors M1 to M3 in the imaging beam path between the object field 5 and the image field 11.

Once again, the projection optical unit 30 has exactly 3 GI mirrors, namely the mirrors M2, M4 and M5. The projection optical unit 30 has exactly seven mirrors in the beam path between the object field 5 and the image field 11. Like the projection optical unit 29, the projection optical unit 30 also has the angle of incidence sequence NI, GI, NI, GI, GI, NI, NI.

The object field 5 and the image field 11 are rectangular in the projection optical unit 30.

Like the projection optical unit 27, the projection optical unit 30 also has a meridional intermediate image ZB present in the form of a caustic and no intermediate image in the plane perpendicular thereto (FIG. 17). The meridional intermediate image ZB (FIG. 16) is located in the region of the imaging beam path of the projection optical unit 30 between the mirrors M3 and M4.

In the case of the projection optical unit 30, an aperture or obscuration stop is located in the vicinity of the penultimate mirror M6. A mean wavefront aberration rms is approximately 8 mλ. An overall transmission of the projection optical unit 30 is approximately 11.2%. An overall mirror surface without inclusion of the polishing overrun edge is 0.89 m² in the case of the projection optical unit 30. A distance between the object plane 6 and the image plane 12 is 2278 mm. An object-image offset d_{OIS} is 987 mm in the projection optical unit 30.

The following tables summarize parameters and the optical design of the projection optical unit 30. In terms of their structure, these tables correspond to those already explained above in conjunction with FIG. 2.

Table 1 for FIG. 16

| | |
|---|---|
| Wavelength [nm] | 13.5 |
| Image-side numerical aperture | 0.33 |
| Image field size in the x- and | 52 × 1.7 |
| y-directions [mm × mm] | |
| Ring field radius [mm] | — |
| βx | 2 |
| βy | 4 |
| Chief ray angle [°] | 6 |
| Étendue | 9.63 |
| Mean wavefront aberration | 13.15 |
| RMS [mλ] | |
| Overall transmission [%] | 11.1 |
| Position of the entrance pupil (x) | −1529.86 |
| Position of the entrance pupil (y) | 1468.68 |
| Object-image offset in the | 898.94 |
| y-direction [mm] | |
| Distance between M7 and | 109 |
| image plane [mm] | |
| Distance between object plane | 2254.93 |
| and image plane | |
| Tilt between object plane and | 0 |
| image plane [°] | |
| Installation space cuboid | 639 × 1086 × 1797 |
| [mm × mm × mm] | |

Table 2a for FIG. 16

| | M1 | M2 | M3 | M4 |
|---|---|---|---|---|
| Maximum angle of incidence | 22.1 | 83.3 | 19.5 | 83.2 |
| [°] | | | | |
| Minimum angle of incidence | 20.6 | 77.4 | 13.2 | 74.7 |
| [°] | | | | |
| Extent of the reflection | 588.4 | 624.0 | 639.2 | 569.6 |
| surface | | | | |
| in the x-direction [mm] | | | | |
| Extent of the reflection | 216.5 | 369.7 | 169.4 | 332.5 |
| surface | | | | |
| in the y-direction [mm] | | | | |
| Maximum mirror diameter | 588.4 | 624.2 | 639.4 | 571.5 |
| [mm] | | | | |
| Mean transmission [%] | 65.4 | 81.2 | 66.7 | 84.5 |
| Minimum transmission [%] | 65.3 | 80.8 | 66.6 | 84.4 |
| Maximum transmission [%] | 65.5 | 81.7 | 66.8 | 84.7 |

Table 2b for FIG. 16

| | M5 | M6 | M7 |
|---|---|---|---|
| Maximum angle of incidence | 87.4 | 25.7 | 12.9 |
| [°] | | | |
| Minimum angle of incidence | 79.0 | 3.8 | 7.0 |
| [°] | | | |
| Extent of the reflection | 515.9 | 416.4 | 494.1 |
| surface | | | |
| in the x-direction [mm] | | | |
| Extent of the reflection | 171.5 | 108.5 | 446.2 |
| surface | | | |
| in the y-direction [mm] | | | |
| Maximum mirror diameter | 516.9 | 416.4 | 495.2 |
| [mm] | | | |
| Mean transmission [%] | 86.0 | 64.6 | 64.5 |
| Minimum transmission [%] | 85.4 | 64.5 | 64.8 |
| Maximum transmission [%] | 86.7 | 64.8 | 0.0 |

Table 3a for FIG. 16

| | x-distance [mm] | y-distance [mm] | z-distance [mm] |
|---|---|---|---|
| Object field | 0.00 | 986.59 | 2278.76 |
| M1 | 0.00 | 865.53 | 1126.98 |
| M2 | 0.00 | 677.89 | 1536.42 |
| M3 | 0.00 | 688.20 | 1924.65 |
| M4 | 0.00 | 329.52 | 1114.62 |
| M5 | 0.00 | 305.23 | 616.02 |
| Aperture stop | 0.00 | 107.52 | 112.78 |
| M6 | 0.00 | 105.34 | 107.23 |
| M7 | 0.00 | 0.00 | 690.22 |
| Image field | 0.00 | 0.00 | 0.00 |

Table 3b for FIG. 16

| | Tilt about the | Tilt about the | Tilt about the |
|---|---|---|---|
| | x-axis [°] | y-axis [°] | z-axis [°] |
| Object field | 0.00 | 0.00 | 180.00 |
| M1 | 189.31 | 0.00 | 0.00 |
| M2 | −78.45 | 180.00 | 0.00 |
| M3 | −12.70 | 0.00 | 0.00 |
| M4 | 76.66 | 0.00 | 180.00 |
| M5 | 257.88 | 0.00 | 0.00 |
| Aperture stop | −12.58 | 0.00 | 0.00 |
| M6 | −5.60 | 180.00 | 0.00 |
| M7 | 5.12 | 0.00 | 0.00 |
| Image field | 0.00 | 0.00 | 0.00 |

Table 4a for FIG. 16

| | M1 | M2 | M3 |
|---|---|---|---|
| RDX | −3128.128698 | 37085.509306 | −7434.884222 |
| RDY | −1276.288097 | 1543.528113 | −778.031712 |
| CCX | 0.000000 | 0.000000 | 0.000000 |
| CCY | 0.000000 | 0.000000 | 0.000000 |
| x**i * y**j | Coefficient | Coefficient | Coefficient |
| x**2 * y**0 | 0.000000E+00 | 0.000000E+00 | 0.000000E+00 |
| x**0 * y**2 | 0.000000E+00 | 0.000000E+00 | 0.000000E+00 |
| x**2 * y**1 | −3.651300E−08 | 8.818008E−08 | 2.454449E−09 |
| x**0 * y**3 | −2.941952E−07 | 4.065154E−08 | −3.154792E−07 |
| x**4 * y**0 | −1.128782E−11 | 2.555987E−12 | 1.264118E−11 |
| x**2 * y**2 | 2.449159E−11 | −7.884467E−11 | 7.199991E−11 |
| x**0 * y**4 | −2.289564E−09 | 5.250031E−10 | −7.504745E−09 |
| x**4 * y**1 | −8.119664E−16 | −1.536381E−14 | −2.557951E−15 |
| x**2 * y**3 | −4.854482E−13 | 4.220273E−13 | 1.597128E−12 |
| x**0 * y**5 | −6.282993E−12 | −1.164331E−12 | 1.274473E−10 |
| x**6 * y**0 | −2.264275E−18 | −4.256418E−18 | 3.995870E−18 |
| x**4 * y**2 | −3.017117E−17 | 1.083145E−16 | −1.336007E−16 |
| x**2 * y**4 | −2.356259E−15 | −1.225224E−15 | −4.068522E−14 |
| x**0 * y**6 | −2.293124E−15 | 3.752426E−15 | −5.904965E−13 |
| x**6 * y**1 | −1.166846E−20 | 4.509502E−20 | −1.196483E−20 |
| x**4 * y**3 | −4.218187E−19 | −4.391343E−19 | 4.556003E−18 |
| x**2 * y**5 | −6.916683E−18 | 5.647288E−18 | −2.656302E−16 |
| x**0 * y**7 | 1.962834E−17 | −2.706303E−17 | 6.420699E−14 |
| x**8 * y**0 | 7.095005E−24 | −1.467294E−22 | 3.809443E−23 |
| x**6 * y**2 | −1.341200E−22 | 9.957722E−23 | −1.644272E−22 |
| x**4 * y**4 | −1.900807E−21 | 3.100025E−21 | 5.456574E−20 |
| x**2 * y**6 | −5.479282E−20 | −3.064423E−20 | −1.784887E−18 |
| x**0 * y**8 | −2.609471E−18 | 1.526228E−19 | −3.092538E−15 |
| x**8 * y**1 | 8.518179E−26 | −3.727350E−25 | 6.815397E−26 |
| x**6 * y**3 | 1.241821E−24 | −1.277377E−25 | 4.219415E−23 |
| x**4 * y**5 | 1.758323E−23 | −2.400950E−23 | 4.012608E−21 |
| x**2 * y**7 | −5.793880E−22 | 2.095614E−22 | 7.489738E−19 |
| x**0 * y**9 | −2.435156E−20 | −4.228381E−22 | −1.372504E−17 |
| x**10 * y**0 | −1.381459E−28 | 2.062869E−27 | −4.492213E−28 |
| x**8 * y**2 | 8.970540E−28 | −9.718437E−28 | −2.011582E−26 |
| x**6 * y**4 | 7.860185E−28 | −1.106940E−26 | −1.109235E−24 |
| x**4 * y**6 | −4.935578E−26 | 1.606640E−25 | −2.056502E−22 |
| x**2 * y**8 | 4.901502E−25 | −1.096054E−24 | 9.531239E−22 |
| x**0 * y**10 | 1.397972E−22 | 1.036857E−24 | 3.985698E−18 |
| x**10 * y**1 | −4.308267E−31 | 4.402555E−30 | 1.516023E−30 |
| x**8 * y**3 | 2.477752E−30 | −6.034209E−30 | −1.786765E−28 |
| x**6 * y**5 | −3.845795E−28 | 1.438062E−28 | −7.246024E−26 |
| x**4 * y**7 | −2.752777E−27 | −7.945195E−28 | −3.751554E−24 |
| x**2 * y**9 | 2.630250E−26 | 3.748170E−27 | −7.692933E−22 |
| x**0 * y**11 | 1.264425E−24 | −4.242261E−27 | −1.139271E−19 |
| x**12 * y**0 | 8.216960E−34 | −9.313812E−33 | 1.669878E−33 |
| x**10 * y**2 | −5.150790E−33 | 1.860997E−33 | 1.557151E−31 |
| x**8 * y**4 | 6.843923E−33 | 4.504105E−32 | 3.331033E−29 |
| x**6 * y**6 | 4.379503E−31 | −5.387842E−31 | 3.261858E−27 |
| x**4 * y**8 | −1.016619E−29 | 2.729240E−30 | 2.354275E−25 |
| x**2 * y**10 | −3.247812E−28 | −6.651050E−30 | 1.564066E−23 |
| x**0 * y**12 | −7.016874E−27 | 1.262113E−29 | 1.433800E−21 |
| x**12 * y**1 | 3.183013E−36 | −2.894340E−35 | −5.637715E−36 |
| x**10 * y**3 | −1.352155E−34 | 9.076141E−35 | −4.232222E−33 |
| x**8 * y**5 | 1.082168E−33 | −3.063840E−34 | −4.574218E−31 |
| x**6 * y**7 | 2.164603E−32 | 5.702293E−34 | −3.417262E−29 |
| x**4 * y**9 | −9.664232E−33 | −4.118782E−33 | −2.481412E−27 |
| x**2 * y**11 | −2.948201E−30 | 4.241092E−33 | −9.627417E−26 |
| x**0 * y**13 | −5.047918E−29 | −1.449349E−32 | −7.138782E−24 |
| x**14 * y**0 | 0.000000E+00 | 0.000000E+00 | 0.000000E+00 |
| x**12 * y**2 | 0.000000E+00 | 0.000000E+00 | 0.000000E+00 |
| x**10 * y**4 | 0.000000E+00 | 0.000000E+00 | 0.000000E+00 |
| x**8 * y**6 | 0.000000E+00 | 0.000000E+00 | 0.000000E+00 |
| x**6 * y**8 | 0.000000E+00 | 0.000000E+00 | 0.000000E+00 |
| x**4 * y**10 | 0.000000E+00 | 0.000000E+00 | 0.000000E+00 |
| x**2 * y**12 | 0.000000E+00 | 0.000000E+00 | 0.000000E+00 |
| x**0 * y**14 | 0.000000E+00 | 0.000000E+00 | 0.000000E+00 |
| x**14 * y**1 | 0.000000E+00 | 0.000000E+00 | 0.000000E+00 |
| x**12 * y**3 | 0.000000E+00 | 0.000000E+00 | 0.000000E+00 |
| x**10 * y**5 | 0.000000E+00 | 0.000000E+00 | 0.000000E+00 |
| x**8 * y**7 | 0.000000E+00 | 0.000000E+00 | 0.000000E+00 |
| x**6 * y**9 | 0.000000E+00 | 0.000000E+00 | 0.000000E+00 |
| x**4 * y**11 | 0.000000E+00 | 0.000000E+00 | 0.000000E+00 |
| x**2 * y**13 | 0.000000E+00 | 0.000000E+00 | 0.000000E+00 |
| x**0 * y**15 | 0.000000E+00 | 0.000000E+00 | 0.000000E+00 |
| x**16 * y**0 | 0.000000E+00 | 0.000000E+00 | 0.000000E+00 |
| x**14 * y**2 | 0.000000E+00 | 0.000000E+00 | 0.000000E+00 |
| x**12 * y**4 | 0.000000E+00 | 0.000000E+00 | 0.000000E+00 |
| x**10 * y**6 | 0.000000E+00 | 0.000000E+00 | 0.000000E+00 |
| x**8 * y**8 | 0.000000E+00 | 0.000000E+00 | 0.000000E+00 |
| x**6 * y**10 | 0.000000E+00 | 0.000000E+00 | 0.000000E+00 |
| x**4 * y**12 | 0.000000E+00 | 0.000000E+00 | 0.000000E+00 |
| x**2 * y**14 | 0.000000E+00 | 0.000000E+00 | 0.000000E+00 |
| x**0 * y**16 | 0.000000E+00 | 0.000000E+00 | 0.000000E+00 |
| x**16 * y**1 | 0.000000E+00 | 0.000000E+00 | 0.000000E+00 |
| x**14 * y**3 | 0.000000E+00 | 0.000000E+00 | 0.000000E+00 |
| x**12 * y**5 | 0.000000E+00 | 0.000000E+00 | 0.000000E+00 |
| x**10 * y**7 | 0.000000E+00 | 0.000000E+00 | 0.000000E+00 |
| x**8 * y**9 | 0.000000E+00 | 0.000000E+00 | 0.000000E+00 |
| x**6 * y**11 | 0.000000E+00 | 0.000000E+00 | 0.000000E+00 |
| x**4 * y**13 | 0.000000E+00 | 0.000000E+00 | 0.000000E+00 |
| x**2 * y**15 | 0.000000E+00 | 0.000000E+00 | 0.000000E+00 |
| x**0 * y**17 | 0.000000E+00 | 0.000000E+00 | 0.000000E+00 |
| x**18 * y**0 | 0.000000E+00 | 0.000000E+00 | 0.000000E+00 |
| x**16 * y**2 | 0.000000E+00 | 0.000000E+00 | 0.000000E+00 |
| x**14 * y**4 | 0.000000E+00 | 0.000000E+00 | 0.000000E+00 |
| x**12 * y**6 | 0.000000E+00 | 0.000000E+00 | 0.000000E+00 |
| x**10 * y**8 | 0.000000E+00 | 0.000000E+00 | 0.000000E+00 |
| x**8 * y**10 | 0.000000E+00 | 0.000000E+00 | 0.000000E+00 |
| x**6 * y**12 | 0.000000E+00 | 0.000000E+00 | 0.000000E+00 |
| x**4 * y**14 | 0.000000E+00 | 0.000000E+00 | 0.000000E+00 |
| x**2 * y**16 | 0.000000E+00 | 0.000000E+00 | 0.000000E+00 |
| x**0 * y**18 | 0.000000E+00 | 0.000000E+00 | 0.000000E+00 |

Table 4b for FIG. 16

| | M4 | M5 | M6 |
|---|---|---|---|
| RDX | −8738.519553 | −5514.516053 | 7111.966727 |
| RDY | −47146.633588 | −25256.066937 | 448.683308 |
| CCX | 0.000000 | 0.000000 | 0.000000 |
| CCY | 0.000000 | 0.000000 | 0.000000 |
| x**i * y**j | Coefficient | Coefficient | Coefficient |
| x**2 * y**0 | 0.000000E+00 | 0.000000E+00 | 0.000000E+00 |
| x**0 * y**2 | 0.000000E+00 | 0.000000E+00 | 0.000000E+00 |
| x**2 * y**1 | −1.129328E−09 | 3.462718E−08 | 3.425602E−07 |
| x**0 * y**3 | −1.778427E−08 | 5.884827E−08 | 1.787671E−06 |
| x**4 * y**0 | −8.736916E−12 | 3.382387E−11 | 1.331147E−10 |
| x**2 * y**2 | −2.172180E−11 | 9.858213E−11 | 2.036278E−09 |
| x**0 * y**4 | −1.680521E−11 | 1.343968E−10 | 3.146926E−08 |
| x**4 * y**1 | 7.250786E−15 | 2.244892E−14 | 3.914026E−13 |
| x**2 * y**3 | −9.176017E−16 | 2.035710E−13 | 1.846664E−11 |
| x**0 * y**5 | −8.957730E−15 | 2.988552E−13 | 6.483121E−11 |
| x**6 * y**0 | −2.698972E−17 | 2.494134E−17 | 1.387342E−16 |
| x**4 * y**2 | −4.033346E−17 | 1.267940E−16 | 6.343714E−15 |
| x**2 * y**4 | −6.737752E−17 | 5.614913E−16 | 1.305894E−13 |
| x**0 * y**6 | −5.759363E−17 | 7.759290E−16 | −2.672750E−12 |
| x**6 * y**1 | 1.752313E−20 | 1.307352E−20 | 8.112521E−19 |
| x**4 * y**3 | 3.318723E−20 | 4.334417E−19 | 5.145990E−17 |
| x**2 * y**5 | 1.081504E−19 | 1.522073E−18 | −3.845515E−16 |
| x**0 * y**7 | 2.624653E−19 | 1.735226E−18 | 9.555519E−14 |
| x**8 * y**0 | −3.843673E−22 | 5.995907E−22 | 1.233699E−22 |
| x**6 * y**2 | 2.234078E−22 | −8.725327E−23 | 1.576826E−20 |
| x**4 * y**4 | 9.540113E−22 | 6.518221E−22 | 5.259396E−19 |
| x**2 * y**6 | 3.189100E−22 | 3.596391E−21 | 7.362905E−17 |
| x**0 * y**8 | −1.649883E−21 | 1.722206E−21 | 2.389270E−15 |
| x**8 * y**1 | −5.268983E−25 | 9.372427E−25 | 2.860737E−24 |
| x**6 * y**3 | −1.557102E−24 | −1.691611E−24 | 2.810923E−22 |
| x**4 * y**5 | −3.684727E−24 | 5.245055E−25 | 2.728048E−20 |
| x**2 * y**7 | 1.934630E−24 | 1.319338E−23 | 1.824197E−18 |
| x**0 * y**9 | 1.068639E−23 | 1.524994E−23 | −2.656069E−17 |
| x**10 * y**0 | 5.061724E−27 | −8.358691E−27 | 1.209814E−27 |
| x**8 * y**2 | −2.485143E−27 | 1.818267E−27 | 4.006856E−26 |
| x**6 * y**4 | −6.831871E−27 | −1.726018E−27 | 5.174209E−24 |
| x**4 * y**6 | −3.166412E−26 | 1.773054E−26 | 5.051019E−22 |
| x**2 * y**8 | −4.203448E−26 | 2.522522E−26 | −1.631643E−20 |
| x**0 * y**10 | −4.915715E−26 | 1.292855E−25 | −6.936900E−19 |
| x**10 * y**1 | 6.041870E−30 | −1.332906E−29 | −1.837879E−29 |
| x**8 * y**3 | 2.104595E−29 | 1.344005E−29 | −7.691647E−28 |
| x**6 * y**5 | 1.026014E−28 | 7.033856E−29 | 2.814263E−26 |
| x**4 * y**7 | 2.617396E−28 | 1.056811E−29 | −5.479609E−24 |
| x**2 * y**9 | 1.872929E−28 | −1.926878E−28 | −5.467505E−22 |
| x**0 * y**11 | 1.310238E−28 | −2.863323E−28 | 6.058267E−21 |
| x**12 * y**0 | −2.012860E−32 | 3.579987E−32 | −3.326715E−33 |
| x**10 * y**2 | 9.661586E−33 | −7.033364E−33 | 6.556929E−32 |
| x**8 * y**4 | −7.961592E−32 | 1.184345E−31 | 3.419992E−30 |
| x**6 * y**6 | −3.644611E−31 | 2.931648E−32 | 9.225820E−28 |
| x**4 * y**8 | −6.771102E−31 | 5.990753E−32 | −1.151560E−25 |
| x**2 * y**10 | −3.481664E−31 | 3.695549E−31 | 4.260507E−24 |
| x**0 * y**12 | −1.843908E−31 | −1.871911E−30 | 5.056976E−23 |
| x**12 * y**1 | −3.401333E−35 | 8.394593E−35 | 1.912019E−34 |
| x**10 * y**3 | −4.129431E−35 | 9.356906E−35 | 8.188843E−33 |
| x**8 * y**5 | 1.053650E−34 | −4.110950E−34 | 1.053425E−30 |
| x**6 * y**7 | 4.215056E−34 | −4.761553E−35 | 4.983546E−30 |
| x**4 * y**9 | 6.056607E−34 | 1.515834E−33 | 2.458545E−27 |
| x**2 * y**11 | 2.391268E−34 | 5.415682E−33 | 3.318578E−26 |
| x**0 * y**13 | 1.069285E−34 | 9.838743E−33 | −3.675706E−25 |
| x**14 * y**0 | 0.000000E+00 | 0.000000E+00 | 0.000000E+00 |
| x**12 * y**2 | 0.000000E+00 | 0.000000E+00 | 0.000000E+00 |
| x**10 * y**4 | 0.000000E+00 | 0.000000E+00 | 0.000000E+00 |
| x**8 * y**6 | 0.000000E+00 | 0.000000E+00 | 0.000000E+00 |
| x**6 * y**8 | 0.000000E+00 | 0.000000E+00 | 0.000000E+00 |
| x**4 * y**10 | 0.000000E+00 | 0.000000E+00 | 0.000000E+00 |
| x**2 * y**12 | 0.000000E+00 | 0.000000E+00 | 0.000000E+00 |
| x**0 * y**14 | 0.000000E+00 | 0.000000E+00 | 0.000000E+00 |
| x**14 * y**1 | 0.000000E+00 | 0.000000E+00 | 0.000000E+00 |
| x**12 * y**3 | 0.000000E+00 | 0.000000E+00 | 0.000000E+00 |
| x**10 * y**5 | 0.000000E+00 | 0.000000E+00 | 0.000000E+00 |
| x**8 * y**7 | 0.000000E+00 | 0.000000E+00 | 0.000000E+00 |
| x**6 * y**9 | 0.000000E+00 | 0.000000E+00 | 0.000000E+00 |
| x**4 * y**11 | 0.000000E+00 | 0.000000E+00 | 0.000000E+00 |
| x**2 * y**13 | 0.000000E+00 | 0.000000E+00 | 0.000000E+00 |
| x**0 * y**15 | 0.000000E+00 | 0.000000E+00 | 0.000000E+00 |
| x**16 * y**0 | 0.000000E+00 | 0.000000E+00 | 0.000000E+00 |
| x**14 * y**2 | 0.000000E+00 | 0.000000E+00 | 0.000000E+00 |
| x**12 * y**4 | 0.000000E+00 | 0.000000E+00 | 0.000000E+00 |
| x**10 * y**6 | 0.000000E+00 | 0.000000E+00 | 0.000000E+00 |
| x**8 * y**8 | 0.000000E+00 | 0.000000E+00 | 0.000000E+00 |
| x**6 * y**10 | 0.000000E+00 | 0.000000E+00 | 0.000000E+00 |
| x**4 * y**12 | 0.000000E+00 | 0.000000E+00 | 0.000000E+00 |
| x**2 * y**14 | 0.000000E+00 | 0.000000E+00 | 0.000000E+00 |
| x**0 * y**16 | 0.000000E+00 | 0.000000E+00 | 0.000000E+00 |
| x**16 * y**1 | 0.000000E+00 | 0.000000E+00 | 0.000000E+00 |
| x**14 * y**3 | 0.000000E+00 | 0.000000E+00 | 0.000000E+00 |
| x**12 * y**5 | 0.000000E+00 | 0.000000E+00 | 0.000000E+00 |
| x**10 * y**7 | 0.000000E+00 | 0.000000E+00 | 0.000000E+00 |
| x**8 * y**9 | 0.000000E+00 | 0.000000E+00 | 0.000000E+00 |
| x**6 * y**11 | 0.000000E+00 | 0.000000E+00 | 0.000000E+00 |
| x**4 * y**13 | 0.000000E+00 | 0.000000E+00 | 0.000000E+00 |
| x**2 * y**15 | 0.000000E+00 | 0.000000E+00 | 0.000000E+00 |
| x**0 * y**17 | 0.000000E+00 | 0.000000E+00 | 0.000000E+00 |
| x**18 * y**0 | 0.000000E+00 | 0.000000E+00 | 0.000000E+00 |
| x**16 * y**2 | 0.000000E+00 | 0.000000E+00 | 0.000000E+00 |
| x**14 * y**4 | 0.000000E+00 | 0.000000E+00 | 0.000000E+00 |
| x**12 * y**6 | 0.000000E+00 | 0.000000E+00 | 0.000000E+00 |
| x**10 * y**8 | 0.000000E+00 | 0.000000E+00 | 0.000000E+00 |
| x**8 * y**10 | 0.000000E+00 | 0.000000E+00 | 0.000000E+00 |
| x**6 * y**12 | 0.000000E+00 | 0.000000E+00 | 0.000000E+00 |
| x**4 * y**14 | 0.000000E+00 | 0.000000E+00 | 0.000000E+00 |
| x**2 * y**16 | 0.000000E+00 | 0.000000E+00 | 0.000000E+00 |
| x**0 * y**18 | 0.000000E+00 | 0.000000E+00 | 0.000000E+00 |

Table 4c for FIG. 16

| | M7 |
|---|---|
| RDX | −1219.841526 |
| RDY | −697.974894 |
| CCX | 0.000000 |
| CCY | 0.000000 |
| x**i * y**j | Coefficient |
| x**2 * y**0 | 0.000000E+00 |
| x**0 * y**2 | 0.000000E+00 |
| x**2 * y**1 | −1.499864E−08 |
| x**0 * y**3 | 7.681421E−09 |
| x**4 * y**0 | −4.549951E−11 |
| x**2 * y**2 | −1.074950E−10 |
| x**0 * y**4 | −6.668128E−11 |
| x**4 * y**1 | −1.079101E−14 |
| x**2 * y**3 | −2.135684E−14 |
| x**0 * y**5 | 3.666653E−14 |
| x**6 * y**0 | −4.055992E−17 |
| x**4 * y**2 | −1.982812E−16 |
| x**2 * y**4 | −2.865381E−16 |
| x**0 * y**6 | −4.480198E−17 |
| x**6 * y**1 | −8.159019E−21 |
| x**4 * y**3 | −3.699458E−20 |
| x**2 * y**5 | −4.858122E−20 |
| x**0 * y**7 | −6.784970E−19 |
| x**8 * y**0 | −2.842384E−23 |
| x**6 * y**2 | −2.577056E−22 |
| x**4 * y**4 | −6.929994E−22 |
| x**2 * y**6 | −7.055882E−22 |
| x**0 * y**8 | −1.240964E−21 |
| x**8 * y**1 | −4.314725E−26 |
| x**6 * y**3 | −1.259177E−25 |
| x**4 * y**5 | −5.190013E−26 |
| x**2 * y**7 | −4.689737E−25 |
| x**0 * y**9 | 1.184292E−23 |
| x**10 * y**0 | −1.086917E−28 |
| x**8 * y**2 | −4.163637E−28 |
| x**6 * y**4 | −1.299975E−27 |
| x**4 * y**6 | −1.103181E−27 |
| x**2 * y**8 | −7.619982E−28 |
| x**0 * y**10 | −3.366115E−27 |
| x**10 * y**1 | 5.674832E−31 |
| x**8 * y**3 | 1.446307E−30 |
| x**6 * y**5 | 2.174027E−30 |
| x**4 * y**7 | −2.059529E−30 |
| x**2 * y**9 | −5.532065E−31 |
| x**0 * y**11 | −5.340201E−29 |
| x**12 * y**0 | 2.448509E−34 |
| x**10 * y**2 | 4.981782E−34 |
| x**8 * y**4 | 2.826842E−33 |
| x**6 * y**6 | −4.114388E−33 |
| x**4 * y**8 | −1.502115E−32 |
| x**2 * y**10 | 7.315438E−33 |
| x**0 * y**12 | 6.137611E−33 |
| x**12 * y**1 | −3.055799E−36 |
| x**10 * y**3 | −8.641387E−36 |
| x**8 * y**5 | −3.088583E−35 |
| x**6 * y**7 | −1.605190E−35 |
| x**4 * y**9 | 8.378649E−36 |
| x**2 * y**11 | −2.168217E−36 |
| x**0 * y**13 | 1.393718E−34 |
| x**14 * y**0 | 0.000000E+00 |
| x**12 * y**2 | 0.000000E+00 |
| x**10 * y**4 | 0.000000E+00 |
| x**8 * y**6 | 0.000000E+00 |
| x**6 * y**8 | 0.000000E+00 |
| x**4 * y**10 | 0.000000E+00 |
| x**2 * y**12 | 0.000000E+00 |
| x**0 * y**14 | 0.000000E+00 |
| x**14 * y**1 | 0.000000E+00 |
| x**12 * y**3 | 0.000000E+00 |
| x**10 * y**5 | 0.000000E+00 |
| x**8 * y**7 | 0.000000E+00 |
| x**6 * y**9 | 0.000000E+00 |
| x**4 * y**11 | 0.000000E+00 |
| x**2 * y**13 | 0.000000E+00 |
| x**0 * y**15 | 0.000000E+00 |
| x**16 * y**0 | 0.000000E+00 |
| x**14 * y**2 | 0.000000E+00 |
| x**12 * y**4 | 0.000000E+00 |
| x**10 * y**6 | 0.000000E+00 |
| x**8 * y**8 | 0.000000E+00 |
| x**6 * y**10 | 0.000000E+00 |
| x**4 * y**12 | 0.000000E+00 |
| x**2 * y**14 | 0.000000E+00 |
| x**0 * y**16 | 0.000000E+00 |
| x**16 * y**1 | 0.000000E+00 |
| x**14 * y**3 | 0.000000E+00 |
| x**12 * y**5 | 0.000000E+00 |
| x**10 * y**7 | 0.000000E+00 |
| x**8 * y**9 | 0.000000E+00 |
| x**6 * y**11 | 0.000000E+00 |
| x**4 * y**13 | 0.000000E+00 |
| x**2 ** y*15 | 0.000000E+00 |
| x**0 * y**17 | 0.000000E+00 |
| x**18 * y**0 | 0.000000E+00 |
| x**16 * y**2 | 0.000000E+00 |
| x**14 * y**4 | 0.000000E+00 |
| x**12 * y**6 | 0.000000E+00 |
| x**10 * y**8 | 0.000000E+00 |
| x**8 * y**10 | 0.000000E+00 |
| x**6 * y**12 | 0.000000E+00 |
| x**4 * y**14 | 0.000000E+00 |
| x**2 * y**16 | 0.000000E+00 |
| x**0 * y**18 | 0.000000E+00 |

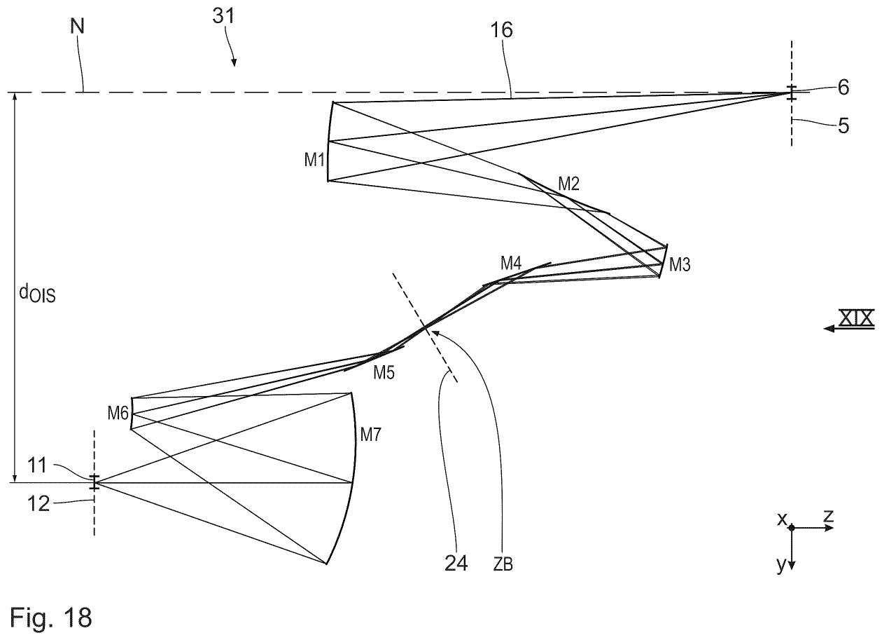

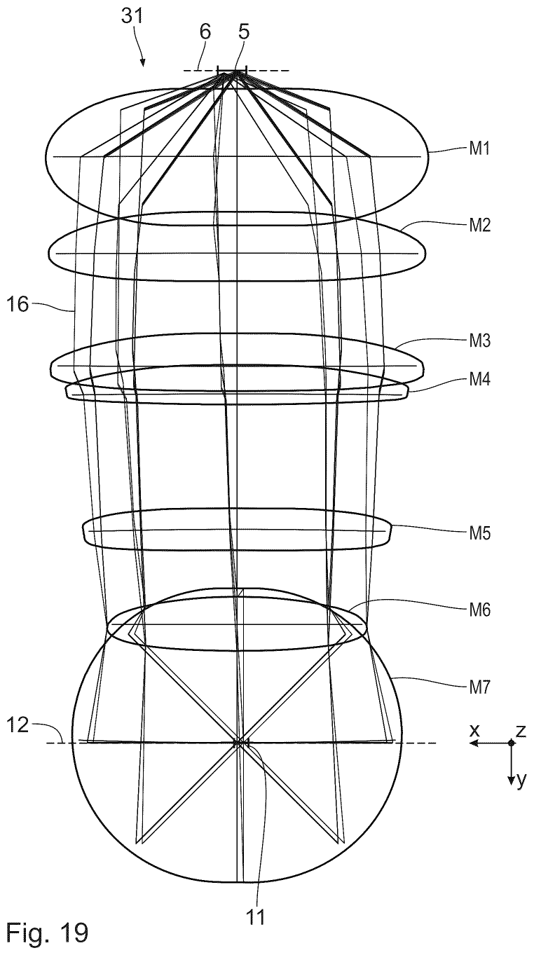

FIGS. 18 and 19 show a further embodiment of a projection optical unit or imaging optical unit 31, which can be used in the projection exposure apparatus 1 instead of the projection optical unit 10 of the embodiment according to FIG. 2. Components and functions corresponding to those which have already been explained above in conjunction with FIGS. 1 to 17, and in particular in conjunction with FIGS. 1 to 3, are denoted by the same reference numeral and are not discussed in detail again.

In terms of basic structure, the projection optical unit 31 according to FIGS. 18 and 19 is similar to the projection optical unit 30 according to FIGS. 16 and 17. Deflection effects of the three GI mirrors M2, M4 and M5 are just the opposite in the projection optical unit 31 in comparison with the projection optical unit 30. In the case of the projection optical unit 30, the mirror M2 has an anticlockwise deflection effect in the meridional section according to FIG. 16, the mirror M4 has a clockwise deflection effect and the mirror M5 once again has an anticlockwise deflection effect.

In the case of the projection optical unit 31, the mirror M2 has a clockwise deflection effect in the meridional section according to FIG. 18, the mirror M4 has an anticlockwise deflection effect and the mirror M5 once again has a clockwise deflection effect.

The object field 5 and the image field 11 are rectangular in the projection optical unit 31.

The projection optical unit 31 has a meridional intermediate image ZB in the imaging beam path between the two GI mirrors M4 and M5. In the plane perpendicular thereto (FIG. 19), there is no intermediate image in the imaging beam path between the object field 5 and the image field 11. In the case of the projection optical unit 31, an aperture or obscuration. Is located in the vicinity of the penultimate mirror M6. A mean wavefront aberration rms is approximately 10.4 mλ. An overall transmission is approximately 11% in the projection optical unit 31. An overall mirror surface without inclusion of the polishing overrun edge is 0.74 m² in the case of the projection optical unit 31. A distance between the object plane 6 and the image plane 12 is 1963 mm. An object-image offset d_{OIS} is 1,100 mm.

The following tables summarize parameters and the optical design of the projection optical unit 31. In terms of their structure, these tables correspond to those already explained above in conjunction with FIG. 2.

Table 1 for FIG. 18

| | |
|---|---|
| Wavelength [nm] | 13.5 |
| Image-side numerical aperture | 0.33 |
| Image field size in the x- and | 52 × 1.7 |
| y-directions [mm × mm] | |
| Ring field radius [mm] | — |
| βx | 2 |
| βy | 4 |
| Chief ray angle [°] | 6 |
| Étendue | 9.63 |
| Mean wavefront aberration | 10.4 |
| RMS [mλ] | |
| Overall transmission [%] | 10.98 |
| Position of the entrance pupil | −1598.88 |
| (x) | |
| Position of the entrance pupil | 1711.44 |
| (y) | |
| Object-image offset in the | 1099.99 |
| y-direction [mm] | |
| Distance between M7 and | 101 |
| image plane [mm] | |
| Distance between object plane | 1963.03 |
| and image plane | |
| Tilt between object plane and | 0 |
| image plane [°] | |
| Installation space cuboid | 626 × 1305 × 1512 |
| [mm × mm × mm] | |

Table 2a for FIG. 18

| | M1 | M2 | M3 | M4 |
|---|---|---|---|---|
| Maximum angle of | 11.6 | 83.1 | 20.8 | 80.2 |
| incidence [°] | | | | |
| Minimum angle of | 8.5 | 77.5 | 18.4 | 73.7 |
| incidence [°] | | | | |
| Extent of the reflection | 625.6 | 616.8 | 611.7 | 562.3 |
| surface | | | | |
| in the x-direction [mm] | | | | |
| Extent of the reflection | 221.8 | 283.7 | 98.9 | 204.1 |
| surface | | | | |
| in the y-direction [mm] | | | | |
| Maximum mirror diameter | 625.7 | 617.3 | 611.9 | 562.5 |
| [mm] | | | | |
| Mean transmission [%] | 66.9 | 85.2 | 63.4 | 80.9 |
| Minimum transmission | 66.8 | 84.3 | 63.2 | 80.8 |
| [%] | | | | |
| Maximum transmission | 66.9 | 86.1 | 63.7 | 81.1 |
| [%] | | | | |

Table 2b for FIG. 18

| | M5 | M6 | M7 |
|---|---|---|---|
| Maximum angle of incidence | 83.8 | 25.7 | 12.6 |
| [°] | | | |
| Minimum angle of incidence | 77.4 | 4.1 | 7.6 |
| [°] | | | |
| Extent of the reflection surface | 505.8 | 425.9 | 540.2 |
| in the x-direction [mm] | | | |
| Extent of the reflection surface | 179.7 | 87.7 | 494.7 |
| in the y-direction [mm] | | | |
| Maximum mirror diameter | 506.5 | 426.0 | 540.9 |
| [mm] | | | |
| Mean transmission [%] | 86.6 | 64.9 | 64.8 |
| Minimum transmission [%] | 86.2 | 64.8 | 65.0 |
| Maximum transmission [%] | 86.9 | 65.0 | 0.0 |

Table 3a for FIG. 18

| | x-distance [mm] | y-distance [mm] | z-distance [mm] |
|---|---|---|---|
| Object field | 0.00 | 986.59 | 2278.76 |
| M1 | 0.00 | 865.53 | 1126.98 |
| M2 | 0.00 | 677.89 | 1536.42 |
| M3 | 0.00 | 688.20 | 1924.65 |
| M4 | 0.00 | 329.52 | 1114.62 |
| M5 | 0.00 | 305.23 | 616.02 |
| M6 | 0.00 | 107.52 | 112.78 |
| Aperture stop | 0.00 | 105.34 | 107.23 |
| M7 | 0.00 | 0.00 | 690.22 |
| Image field | 0.00 | 0.00 | 0.00 |

Table 3b for FIG. 18

| | Tilt about the | Tilt about the | Tilt about the |
|---|---|---|---|
| | x-axis [°] | y-axis [°] | z-axis [°] |
| Object field | 0.00 | 0.00 | 180.00 |
| M1 | 189.31 | 0.00 | 0.00 |
| M2 | −78.45 | 180.00 | 0.00 |
| M3 | −12.70 | 0.00 | 0.00 |
| M4 | 76.66 | 0.00 | 180.00 |
| M5 | 257.88 | 0.00 | 0.00 |
| M6 | −12.58 | 0.00 | 0.00 |
| Aperture stop | −5.60 | 180.00 | 0.00 |
| M7 | 5.12 | 0.00 | 0.00 |
| Image field | 0.00 | 0.00 | 0.00 |

Table 4a for FIG. 18

| | M1 | M2 | M3 |
|---|---|---|---|
| RDX | −3031.047933 | −41028.433773 | −11343.951283 |
| RDY | −1069.105431 | 1490.750258 | −805.530399 |
| CCX | 0.000000 | 0.000000 | 0.000000 |
| CCY | 0.000000 | 0.000000 | 0.000000 |
| x**i * y**j | Coefficient | Coefficient | Coefficient |
| x**2 * y**0 | 0.000000E+00 | 0.000000E+00 | 0.000000E+00 |
| x**0 * y**2 | 0.000000E+00 | 0.000000E+00 | 0.000000E+00 |
| x**2 * y**1 | 3.182612E−08 | −1.373772E−07 | 1.012348E−07 |
| x**0 * y**3 | 1.383372E−07 | 4.081362E−07 | −1.478011E−06 |
| x**4 * y**0 | −6.512848E−12 | 2.360710E−11 | 1.201141E−12 |
| x**2 * y**2 | −2.174107E−11 | −2.104009E−10 | 3.243494E−11 |
| x**0 * y**4 | −1.967647E−10 | 7.561985E−10 | −5.448284E−09 |
| x**4 * y**1 | 5.291093E−15 | 2.381776E−14 | 5.151307E−14 |
| x**2 * y**3 | 8.004614E−14 | −4.794413E−13 | −7.921293E−13 |
| x**0 * y**5 | 1.751581E−13 | 1.327109E−12 | −2.721713E−11 |
| x**6 * y**0 | −1.090621E−18 | 1.041043E−17 | −7.028250E−18 |
| x**4 * y**2 | −6.501196E−18 | 3.990850E−17 | 3.353878E−16 |
| x**2 * y**4 | −1.856367E−16 | −5.693450E−16 | −1.061690E−14 |
| x**0 * y**6 | −1.069703E−15 | 2.831865E−15 | −9.683152E−14 |
| x**6 * y**1 | 6.062779E−21 | −5.520113E−21 | 6.582998E−21 |
| x**4 * y**3 | 1.239636E−19 | −3.216300E−19 | 7.612109E−19 |
| x**2 * y**5 | 5.082853E−19 | −3.937979E−20 | −6.499507E−17 |
| x**0 * y**7 | 1.061750E−17 | 4.459125E−18 | −4.572807E−16 |
| x**8 * y**0 | −4.590944E−24 | −6.880779E−23 | 8.715204E−24 |
| x**6 * y**2 | −1.448031E−22 | 8.555536E−22 | −6.403338E−22 |
| x**4 * y**4 | −1.173929E−21 | 3.602823E−21 | −5.910693E−20 |
| x**2 * y**6 | −4.204479E−21 | 1.111648E−20 | −9.941169E−19 |
| x**0 * y**8 | −1.332976E−19 | 1.721513E−19 | −5.096517E−17 |
| x**8 * y**1 | −1.059522E−25 | −7.746569E−26 | 2.884150E−25 |
| x**6 * y**3 | −2.331369E−24 | 1.048288E−23 | −3.417700E−23 |
| x**4 * y**5 | −2.234602E−23 | 9.101986E−23 | −1.621165E−21 |
| x**2 * y**7 | −3.326042E−23 | 1.713839E−22 | −3.967595E−20 |
| x**0 * y**9 | −1.623774E−21 | 2.107833E−22 | 4.318720E−19 |
| x**10 * y**0 | 3.238646E−29 | 3.692307E−28 | 4.023555E−28 |
| x**8 * y**2 | 2.968605E−27 | −2.033138E−26 | 1.813926E−26 |
| x**6 * y**4 | 2.090921E−26 | −3.982332E−26 | −3.033036E−25 |
| x**4 * y**6 | 9.909620E−26 | 3.266794E−25 | −2.198119E−23 |
| x**2 * y**8 | 2.475861E−25 | 1.125168E−24 | 5.226414E−22 |
| x**0 * y**10 | −4.782044E−25 | −5.313226E−24 | 1.710321E−20 |
| x**10 * y**1 | 6.904370E−31 | 7.049859E−30 | −2.568537E−30 |
| x**8 * y**3 | 2.447305E−29 | −6.748835E−29 | −3.614978E−29 |
| x**6 * y**5 | 3.824139E−28 | −1.117422E−27 | −7.557121E−27 |
| x**4 * y**7 | 2.125636E−27 | −3.153894E−27 | −1.282842E−25 |
| x**2 * y**9 | 1.186838E−27 | 5.667316E−27 | −2.901381E−24 |
| x**0 * y**11 | 4.760559E−26 | 3.933250E−26 | −3.900754E−22 |
| x**12 * y**0 | −1.912170E−35 | 2.883805E−33 | −7.088222E−33 |
| x**10 * y**2 | −2.986344E−32 | 2.076715E−31 | −2.308502E−31 |
| x**8 * y**4 | −2.347889E−31 | 7.189125E−31 | −1.641783E−30 |
| x**6 * y**6 | −1.215907E−30 | −4.817781E−30 | 5.627246E−28 |
| x**4 * y**8 | −6.181990E−30 | −2.345237E−29 | −8.721990E−28 |
| x**2 * y**10 | −1.279695E−29 | 1.592314E−29 | −5.361251E−25 |
| x**0 * y**12 | 4.194580E−28 | 5.066570E−28 | −5.284657E−24 |
| x**12 * y**1 | −1.924930E−37 | −8.613357E−35 | 2.910683E−36 |
| x**10 * y**3 | −1.054575E−34 | −2.169954E−34 | 1.546030E−33 |
| x**8 * y**5 | −2.775798E−33 | 6.085709E−33 | 3.271292E−31 |
| x**6 * y**7 | −2.698675E−32 | 1.724170E−32 | 1.122697E−29 |
| x**4 * y**9 | −9.041796E−32 | −3.009690E−32 | 1.753486E−28 |
| x**2 * y**11 | −3.336602E−32 | −1.539569E−31 | 4.252999E−27 |
| x**0 * y**13 | 1.351510E−31 | −2.367235E−31 | 1.098268E−25 |
| x**14 * y**0 | −6.536934E−40 | −2.074028E−38 | 3.143386E−38 |
| x**12 * y**2 | 1.017083E−37 | −6.203671E−37 | 1.098943E−36 |
| x**10 * y**4 | 1.344426E−36 | −7.337179E−36 | 6.738258E−35 |
| x**8 * y**6 | 5.013854E−36 | 1.794561E−35 | −3.576081E−33 |
| x**6 * y**8 | 4.177193E−35 | 1.620859E−34 | −7.771490E−32 |
| x**4 * y**10 | 1.705031E−34 | 2.299535E−34 | 1.800189E−30 |
| x**2 * y**12 | 2.890928E−34 | −1.125986E−33 | 1.235147E−28 |
| x**0 * y**14 | −1.119265E−32 | −1.380671E−32 | 7.793663E−28 |
| x**14 * y**1 | −8.311530E−42 | 2.661976E−40 | 7.364392E−41 |
| x**12 * y**3 | 2.593108E−40 | 1.220899E−39 | 1.717878E−38 |
| x**10 * y**5 | 5.429745E−39 | −1.635323E−38 | −1.826744E−36 |
| x**8 * y**7 | 1.196727E−37 | −1.835015E−38 | −1.067004E−34 |
| x**6 * y**9 | 5.891534E−37 | 4.380896E−37 | −2.458309E−33 |
| x**4 * y**11 | 1.573996E−36 | 1.029345E−36 | −3.157712E−32 |
| x**2 * y**13 | 6.538553E−37 | −1.463129E−36 | −1.089717E−30 |
| x**0 * y**15 | −1.474590E−35 | −3.426735E−35 | −1.269338E−29 |

Table 4b for FIG. 18

| | M4 | M5 | M6 |
|---|---|---|---|
| RDX | −15959.866279 | 7506.618844 | 7147.082614 |
| RDY | −117699.482329 | −14698.253003 | 361.381313 |
| CCX | 0.000000 | 0.000000 | 0.000000 |
| CCY | 0.000000 | 0.000000 | 0.000000 |
| x**i * y**j | Coefficient | Coefficient | Coefficient |
| x**2 * y**0 | 0.000000E+00 | 0.000000E+00 | 0.000000E+00 |
| x**0 * y**2 | 0.000000E+00 | 0.000000E+00 | 0.000000E+00 |
| x**2 * y**1 | −1.093278E−07 | −6.757391E−09 | 3.839161E−07 |
| x**0 * y**3 | 5.544264E−08 | 2.064988E−08 | 8.788632E−07 |
| x**4 * y**0 | 9.741795E−11 | −3.785458E−11 | 1.389358E−10 |
| x**2 * y**2 | −5.183012E−11 | −5.936087E−11 | 2.351490E−09 |
| x**0 * y**4 | −5.657396E−11 | 3.008392E−11 | 2.463231E−08 |
| x**4 * y**1 | −2.492581E−16 | 2.881277E−14 | 6.131598E−13 |
| x**2 * y**3 | 7.781481E−14 | −6.138601E−14 | 1.239630E−11 |
| x**0 * y**5 | 1.926243E−13 | 2.013319E−13 | −4.337249E−11 |
| x**6 * y**0 | −4.296131E−18 | 2.256754E−17 | 1.543902E−16 |
| x**4 * y**2 | −3.512349E−17 | 1.329867E−16 | 5.820529E−15 |
| x**2 * y**4 | 2.177249E−18 | 6.871661E−17 | 5.030813E−14 |
| x**0 * y**6 | −5.125912E−15 | 1.202356E−15 | 1.516765E−12 |
| x**6 * y**1 | −5.748691E−20 | −4.996668E−20 | 1.275466E−18 |
| x**4 * y**3 | −7.384373E−19 | −2.138474E−19 | 3.111290E−17 |
| x**2 * y**5 | 1.026241E−18 | −6.360190E−18 | 9.721749E−16 |
| x**0 * y**7 | 9.141776E−17 | 2.560058E−17 | 2.453795E−15 |
| x**8 * y**0 | 1.017192E−22 | −3.628976E−22 | 2.851830E−22 |
| x**6 * y**2 | 3.343590E−22 | −1.786181E−21 | 1.775398E−20 |
| x**4 * y**4 | 1.131470E−20 | −1.262771E−20 | 6.478273E−19 |
| x**2 * y**6 | 5.175912E−20 | 7.538933E−21 | 1.163057E−17 |
| x**0 * y**8 | 4.415915E−19 | −2.238775E−19 | 5.489212E−16 |
| x**8 * y**1 | −5.100163E−25 | 1.274496E−24 | 1.617756E−24 |
| x**6 * y**3 | 1.785860E−23 | 2.172860E−23 | 1.823686E−22 |
| x**4 * y**5 | 2.480358E−22 | 3.794966E−22 | 5.696139E−21 |
| x**2 * y**7 | −1.000077E−21 | 1.808270E−21 | 4.856622E−19 |
| x**0 * y**9 | −3.493543E−20 | −7.875341E−21 | −4.669186E−18 |
| x**10 * y**0 | −6.749178E−27 | 1.610362E−26 | −1.441476E−27 |
| x**8 * y**2 | −1.472076E−26 | 4.424923E−26 | −1.124550E−25 |
| x**6 * y**4 | −3.909366E−25 | 5.187552E−25 | −7.019744E−24 |
| x**4 * y**6 | −3.038354E−24 | 1.031893E−24 | 9.308229E−23 |
| x**2 * y**8 | 8.439445E−24 | −6.617586E−24 | −6.902044E−21 |
| x**0 * y**10 | 3.530373E−22 | 4.665148E−23 | 4.854417E−20 |
| x**10 * y**1 | 8.518138E−30 | −1.583806E−29 | 3.283316E−29 |
| x**8 * y**3 | −1.125090E−28 | −2.117314E−28 | −4.293830E−28 |
| x**6 * y**5 | −4.355772E−27 | −9.304437E−27 | 6.723095E−26 |
| x**4 * y**7 | −2.117025E−26 | −9.077711E−26 | 8.742899E−27 |
| x**2 * y**9 | 1.791663E−25 | −3.359536E−25 | 1.426998E−22 |
| x**0 * y**11 | 1.473471E−24 | 1.248439E−24 | −9.984996E−22 |
| x**12 * y**0 | 9.995983E−32 | −2.286324E−31 | 2.366333E−32 |
| x**10 * y**2 | 1.433742E−31 | −4.979303E−31 | 2.457156E−30 |
| x**8 * y**4 | 7.825369E−30 | −8.310481E−30 | 2.496336E−28 |
| x**6 * y**6 | 6.844466E−29 | −4.337487E−29 | 6.539363E−27 |
| x**4 * y**8 | 3.894396E−28 | 3.564082E−29 | 1.243747E−25 |
| x**2 * y**10 | −4.792767E−27 | 9.252356E−28 | −4.230729E−26 |
| x**0 * y**12 | −5.641511E−26 | −5.401019E−27 | −1.532636E−23 |
| x**12 * y**1 | −6.274171E−35 | 1.540286E−34 | −3.697285E−34 |
| x**10 * y**3 | −1.900025E−33 | −1.158602E−33 | 2.990939E−32 |
| x**8 * y**5 | 1.850337E−32 | 8.182088E−32 | 1.223947E−30 |
| x**6 * y**7 | 2.024113E−31 | 1.443296E−30 | −5.027830E−30 |
| x**4 * y**9 | −1.202007E−30 | 1.040682E−29 | −2.177189E−27 |
| x**2 * y**11 | 4.335005E−29 | 2.985344E−29 | −7.332548E−26 |
| x**0 * y**13 | 4.707827E−28 | −9.796195E−29 | 4.248146E−25 |
| x**14 * y**0 | −4.618058E−37 | 1.142590E−36 | −1.046469E−37 |
| x**12 * y**2 | 7.073542E−38 | 1.760059E−36 | −1.130459E−35 |
| x**10 * y**4 | −6.589435E−35 | 4.327747E−35 | −1.844824E−33 |
| x**8 * y**6 | −8.876444E−34 | 4.192552E−34 | −8.437497E−32 |
| x**6 * y**8 | −5.102481E−33 | 4.295394E−34 | −1.418433E−30 |
| x**4 * y**10 | −3.298816E−33 | −4.353403E−33 | −3.632998E−29 |
| x**2 * y**12 | −1.781173E−31 | −4.720080E−32 | 5.192931E−28 |
| x**0 * y**14 | −1.770760E−30 | 2.449096E−31 | −2.072168E−28 |
| x**14 * y**1 | −5.864600E−41 | −7.538235E−40 | 2.606785E−39 |
| x**12 * y**3 | 1.816006E−38 | 1.750614E−38 | −2.046448E−37 |
| x**10 * y**5 | 3.711256E−37 | −1.561075E−37 | −1.691726E−35 |
| x**8 * y**7 | 3.592380E−36 | −7.506554E−36 | −2.015017E−34 |
| x**6 * y**9 | 1.628741E−35 | −7.308353E−35 | 1.279148E−33 |
| x**4 * y**11 | 1.694087E−35 | −4.670659E−34 | 9.243518E−31 |
| x**2 * y**13 | 2.799885E−34 | −9.662889E−34 | 8.757222E−30 |
| x**0 * y**15 | 2.606925E−33 | 2.917253E−33 | −1.871487E−31 |

Table 4c for FIG. 18

| | M7 |
|---|---|
| RDX | −1271.528592 |
| RDY | −768.654147 |
| CCX | 0.000000 |
| CCY | 0.000000 |
| x**i * y**j | Coefficient |
| x**2 * y**0 | 0.000000E+00 |
| x**0 * y**2 | 0.000000E+00 |
| x**2 * y**1 | −6.490015E−09 |
| x**0 * y**3 | 1.293465E−08 |
| x**4 * y**0 | −3.600769E−11 |
| x**2 * y**2 | −9.073468E−11 |
| x**0 * y**4 | −4.309025E−11 |
| x**4 * y**1 | −3.664824E−15 |
| x**2 * y**3 | 1.278963E−14 |
| x**0 * y**5 | 2.456397E−14 |
| x**6 * y**0 | −3.140488E−17 |
| x**4 * y**2 | −1.509445E−16 |
| x**2 * y**4 | −2.046269E−16 |
| x**0 * y**6 | −8.905393E−17 |
| x**6 * y**1 | −4.539744E−21 |
| x**4 * y**3 | 1.115444E−20 |
| x**2 * y**5 | 3.627081E−20 |
| x**0 * y**7 | 2.000419E−21 |
| x**8 * y**0 | −3.532952E−23 |
| x**6 * y**2 | −2.210952E−22 |
| x**4 * y**4 | −5.358674E−22 |
| x**2 * y**6 | −5.340542E−22 |
| x**0 * y**8 | −7.525819E−22 |
| x**8 * y**1 | 2.698238E−26 |
| x**6 * y**3 | −6.133455E−27 |
| x**4 * y**5 | 1.652213E−25 |
| x**2 * y**7 | 4.955916E−26 |
| x**0 * y**9 | −2.419448E−25 |
| x**10 * y**0 | 1.694358E−28 |
| x**8 * y**2 | 8.244240E−28 |
| x**6 * y**4 | 2.755999E−27 |
| x**4 * y**6 | 3.867899E−27 |
| x**2 * y**8 | 2.622670E−27 |
| x**0 * y**10 | 3.596236E−27 |
| x**10 * y**1 | −7.199847E−31 |
| x**8 * y**3 | −7.528494E−31 |
| x**6 * y**5 | −5.307083E−30 |
| x**4 * y**7 | −1.270523E−29 |
| x**2 * y**9 | −9.919336E−30 |
| x**0 * y**11 | 1.153320E−29 |
| x**12 * y**0 | −1.757907E−33 |
| x**10 * y**2 | −1.129520E−32 |
| x**8 * y**4 | −5.091942E−32 |
| x**6 * y**6 | −1.056674E−31 |
| x**4 * y**8 | −1.077414E−31 |
| x**2 * y**10 | −5.266230E−32 |
| x**0 * y**12 | −2.191252E−33 |
| x**12 * y**1 | 7.777996E−36 |
| x**10 * y**3 | 1.627271E−35 |
| x**8 * y**5 | 8.800569E−35 |
| x**6 * y**7 | 2.632815E−34 |
| x**4 * y**9 | 3.102295E−34 |
| x**2 * y**11 | 1.932660E−34 |
| x**0 * y**13 | −1.794622E−34 |
| x**14 * y**0 | 6.079204E−39 |
| x**12 * y**2 | 4.402689E−38 |
| x**10 * y**4 | 2.566336E−37 |
| x**8 * y**6 | 6.882932E−37 |
| x**6 * y**8 | 9.935029E−37 |
| x**4 * y**10 | 7.586645E−37 |
| x**2 * y**12 | 2.595778E−37 |
| x**0 * y**14 | −2.818616E−38 |
| x**14 * y**1 | −3.102750E−41 |
| x**12 * y**3 | −1.009988E−40 |
| x**10 * y**5 | −4.978857E−40 |
| x**8 * y**7 | −1.821067E−39 |
| x**6 * y**9 | −2.951051E−39 |
| x**4 * y**11 | −2.375423E−39 |
| x**2 * y**13 | −1.157824E−39 |
| x**0 * y**15 | 7.559071E−40 |

Depending on the embodiment of the above-described projection optical units, these may also have a different number of NI mirrors and/or GI mirrors, for example fewer or more than four GI mirrors, for example precisely one GI mirror, precisely two GI mirrors or else precisely three GI mirrors. Fewer or more than four NI mirrors are also possible, for example two, three or five NI mirrors.

In order to produce a microstructured or nanostructured component, the projection exposure apparatus 1 is used as follows: First, the reflection mask 7 or the reticle and the substrate or the wafer 13 are provided. Subsequently, a structure on the reticle 7 is projected onto a light-sensitive layer of the wafer 13 with the aid of the projection exposure apparatus 1. Then, a microstructure or nanostructure on the wafer 13, and hence the microstructured component, is produced by developing the light-sensitive layer.

What is claimed is:

1. An imaging EUV optical unit configured to image an object field in an object plane into an image field in an image plane, the imaging EUV optical unit comprising:
a plurality of mirrors configured to guide EUV imaging light along an imaging beam path from the object field towards the image field,
wherein:
the plurality of mirrors has an overall transmission of greater than 5% for the EUV imaging light;
the image field has a maximum extent of more than 50 millimetres in the image plane; and
the wavelength is less than 30 nanometers.

2. The imaging EUV optical unit of claim 1, wherein an overall mirror surface is less than 1.5 square meters.

3. The imaging EUV optical unit of claim 1, wherein:
the imaging EUV optical unit has a first imaging light plane and a second imaging light plane perpendicular to the first imaging light plane;
the first imaging light plane has a first imaging scale; and
the second imaging light plane has a second imaging scale different from the first light imaging scale.

4. The imaging EUV optical unit of claim 1, wherein:
the imaging EUV optical unit has a first imaging light plane and a second imaging light plane perpendicular to the first imaging light plane;
the first imaging light plane has a displacement direction imaging scale along an object displacement direction; and
an absolute value of the displacement direction imaging scale is at least 1.1 times a cross dimension imaging scale in the second imaging light plane.

5. The imaging EUV optical unit of claim 1, wherein the imaging EUV optical unit comprises at least one intermediate image in at least one imaging light plane containing an image field extension direction.

6. The imaging EUV optical unit of claim 1, wherein an image plane in the imaging beam path in an imaging light plane contains an image field extension direction, and the image plane is a first field plane downstream of the object plane.

7. The imaging EUV optical unit of claim 1, wherein the image field is bent.

8. The imaging EUV optical unit of claim 1, wherein the image field is a double arch.

9. The imaging EUV optical unit of claim 1, wherein the plurality of mirrors comprises at least four normal incidence mirrors.

10. The imaging EUV optical unit of claim 1, wherein the plurality of mirrors comprises at least four GI mirrors.

11. The imaging EUV optical unit of claim 1, wherein the plurality of mirrors comprises at a pair of grazing incidence GI mirrors that are immediately consecutive along the beam path.

12. The imaging EUV optical unit of claim 1, wherein, along the beam path, a sequence of a first three mirrors of the plurality of mirrors is a first normal incidence mirror, a grazing incidence mirror, and a second normal incidence mirror.

13. The imaging EUV optical unit of claim 1, wherein the plurality of mirrors comprises at most three grazing incidence mirrors, and the plurality of mirrors comprises at most seven mirrors.

14. The imaging EUV optical unit of claim 1, wherein:
the imaging EUV optical unit has a first imaging light plane and a second imaging light plane perpendicular to the first imaging light plane;
the first imaging light plane has a first imaging scale;
the second imaging light plane has a second imaging scale different from the first light imaging scale;
the first imaging light plane has a displacement direction imaging scale along an object displacement direction; and
an absolute value of the displacement direction imaging scale is at least 1.1 times a cross dimension imaging scale in the second imaging light plane.

15. The imaging EUV optical unit of claim 14, wherein an overall mirror surface is less than 1.5 square meters.

16. The imaging EUV optical unit of claim 14, wherein an overall mirror surface is less than 1.5 square meters, and the imaging EUV optical unit comprises at least one intermediate image in at least one imaging light plane containing an image field extension direction.

17. The imaging EUV optical unit of claim 14, wherein an overall mirror surface is less than 1.5 square meters, an image plane in the imaging beam path in an imaging light plane contains an image field extension direction, and the image plane is a first field plane downstream of the object plane.

18. An optical system, comprising:
an illumination optical unit configured to illuminate an object field with imaging light; and
an imaging optical unit according to claim 1.

19. An apparatus, comprising:
an EUV light source;
an illumination optical unit configured to illuminate an object field with imaging light; and
an imaging optical unit according to claim 1,
wherein the apparatus is a projection exposure apparatus.

20. A method of using a projection exposure apparatus comprising an illumination optical unit and an imaging EUV optical unit, the method comprising:
using the illumination optical unit to illuminate an object field with light; and
using the imaging EUV optical unit to image the illuminated object field into an image plane,
wherein the imaging EUV optical unit is an imaging EUV optical unit according to claim 1.
